(19) United States
(12) Patent Application Publication
(10) Pub. No.: US 2023/0420909 A1
(43) Pub. Date: Dec. 28, 2023

(54) SEMICONDUCTOR LIGHT-EMITTING DEVICE

(71) Applicant: ROHM CO., LTD., Kyoto-shi, Kyoto (JP)

(72) Inventors: Koki SAKAMOTO, Kyoto-shi (JP); Kazunori FUJI, Kyoto-shi (JP); Atsushi YAMAGUCHI, Kyoto-shi (JP)

(21) Appl. No.: 18/252,291

(22) PCT Filed: Oct. 27, 2021
(86) PCT No.: PCT/JP2021/039707

§ 371 Date: May 9, 2023

(30) Foreign Application Priority Data
Nov. 13, 2020 (JP) 2020-189361

(51) Int. Cl. H01S 5/02234; H01S 5/02345

(52) U.S. Cl. CPC H01S 5/02234; H01S 5/02345

(57) ABSTRACT

This semiconductor light-emitting device includes a substrate having a substrate main surface, a semiconductor light-emitting element having a light-emitting element main surface mounted on the substrate main surface and facing the same side as the substrate main surface, and a light-emitting element side surface that is a light-emitting surface facing a direction intersecting the light-emitting element main surface, a switching element and a capacitor mounted on the substrate main surface and serving as drive elements used in driving the semiconductor light-emitting element, a translucent member formed from a material having a greater linear expansion coefficient than the substrate and transmitting light emitted from the light-emitting side surface, the translucent member covering the light-emitting element side surface, and a sealing resin formed from a material that has a smaller linear expansion coefficient than the translucent member, the sealing resin sealing the semiconductor light-emitting element, the switching element, and the capacitor.

### TECHNICAL FIELD

The present disclosure relates to a semiconductor light emitting device.

### BACKGROUND ART

A conventional semiconductor light emitting device includes a semiconductor light emitting element mounted on a substrate, a drive element used to drive the semiconductor light emitting element, and a transparent member encapsulating the semiconductor light emitting element and the drive element and being transmissive to the light of the semiconductor light emitting element (for example, refer to Patent Literature 1). The drive element includes a switching element electrically connected to the semiconductor light emitting element by, for example, a wire or a wiring line. The transparent member is in contact with the substrate.

### CITATION LIST

### Patent Literature

Patent Literature 1: Japanese Patent No. 6689363

### SUMMARY OF INVENTION

### Technical Problem

In the conventional semiconductor light emitting device, the substrate is, for example, a printed circuit board (PCB) or a ceramic substrate, and the transparent member is, for example, an epoxy resin or silicone. Since the substrate and the transparent member greatly differ in linear expansion coefficient, the difference may produce excessive stress in the semiconductor light emitting device.

### Solution to Problem

To solve the above problem, a semiconductor light emitting device includes a substrate including a substrate main surface, a semiconductor light emitting element, a drive element, a transparent member, and an encapsulation resin. The semiconductor light emitting element is mounted on the substrate main surface. The semiconductor light emitting element includes a light emitting element main surface facing the same direction as the substrate main surface and a light emitting surface facing a direction intersecting the light emitting element main surface. The drive element is mounted on the substrate main surface and used to drive the semiconductor light emitting element. The transparent member covers the light emitting surface. The transparent member is formed from a material having a greater linear expansion coefficient than a material of the substrate and being transmissive to light emitted from the light emitting surface. The encapsulation resin encapsulates the semiconductor light emitting element and the drive element. The encapsulation resin is formed of a material having a smaller linear expansion coefficient than the material of the transparent member.

In this structure, the encapsulation resin, which encapsulates the semiconductor light emitting element and the drive element, is formed from a material having a smaller linear expansion coefficient than the material of the transparent member. Thus, the difference in linear expansion coefficient between the encapsulation resin and the substrate is less than the difference in linear expansion coefficient between the transparent member and the substrate. This reduces the difference in thermal expansion amount and thermal contraction amount between the substrate and the encapsulation resin when the temperature of the semiconductor light emitting device changes. As a result, stress produced in the semiconductor light emitting device caused by the difference in linear expansion coefficient between the transparent member and the substrate is reduced.

### Advantageous Effects of Invention

The above semiconductor light emitting device reduces stress produced in the semiconductor light emitting device caused by the difference in linear expansion coefficient between the transparent member and the substrate.

### BRIEF DESCRIPTION OF DRAWINGS

FIG. 1 is a perspective view showing a first embodiment of a semiconductor light emitting device.

FIG. 2 is a plan view of the semiconductor light emitting device shown in FIG. 1 with an encapsulation resin omitted.

FIG. 3 is a bottom view of the semiconductor light emitting device shown in FIG. 1.

FIG. 4 is a cross-sectional view of the semiconductor light emitting device of FIG. 1 taken along line 4-4 in FIG. 2.

FIG. 5 is an enlarged partial view of the semiconductor light emitting device shown in FIG. 2.

FIG. 6 is a perspective view of a semiconductor light emitting element and a transparent member in the semiconductor light emitting device shown in FIG. 1.

FIG. 7 is a bottom view of the semiconductor light emitting element and the transparent member shown in FIG. 6.

FIG. 8 is a circuit diagram of the semiconductor light emitting device shown in FIG. 1.

FIG. 9 is a diagram showing an example of a manufacturing step in a method for manufacturing the semiconductor light emitting device of the first embodiment.

FIG. 10 is a diagram showing an example of a manufacturing step in the method for manufacturing the semiconductor device.

FIG. 11 is a diagram showing an example of a manufacturing step in the method for manufacturing the semiconductor device.

FIG. 12 is a diagram showing an example of a manufacturing step in the method for manufacturing the semiconductor device.

FIG. 13 is a diagram showing an example of a manufacturing step in the method for manufacturing the semiconductor device.

FIG. 14 is a diagram showing an example of a manufacturing step in the method for manufacturing the semiconductor device.

FIG. 15 is a diagram showing an example of a manufacturing step in the method for manufacturing the semiconductor device.

FIG. 16 is a diagram showing an example of a manufacturing step in the method for manufacturing the semiconductor device.

FIG. 17 is a diagram showing an example of a manufacturing step in the method for manufacturing the semiconductor device.

FIG. 18 is a perspective view showing a second embodiment of a semiconductor light emitting device.

FIG. 19 is a plan view of the semiconductor light emitting device shown in FIG. 18.

FIG. 20 is a cross-sectional view of the semiconductor light emitting device shown in FIG. 19 taken along line 20-20.

FIG. 21 is a diagram showing an example of a manufacturing step in a method for manufacturing the semiconductor light emitting device of the second embodiment.

FIG. 22 is a diagram showing an example of a manufacturing step in the method for manufacturing the semiconductor device.

FIG. 23 is a diagram showing an example of a manufacturing step in the method for manufacturing the semiconductor device.

FIG. 24 is a diagram showing an example of a manufacturing step in the method for manufacturing the semiconductor device.

FIG. 25 is a diagram showing an example of a manufacturing step in the method for manufacturing the semiconductor device.

FIG. 26 is a diagram showing an example of a manufacturing step in the method for manufacturing the semiconductor device.

FIG. 27 is a diagram showing an example of a manufacturing step in the method for manufacturing the semiconductor device.

FIG. 28 is a perspective view showing a third embodiment of a semiconductor light emitting device.

FIG. 29 is a plan view of the semiconductor light emitting device shown in FIG. 28.

FIG. 30 is a cross-sectional view of the semiconductor light emitting device shown in FIG. 29 taken along line 30-30.

FIG. 31 is a diagram showing an example of a manufacturing step in a method for manufacturing the semiconductor light emitting device of the third embodiment.

FIG. 32 is a diagram showing an example of a manufacturing step in the method for manufacturing the semiconductor device.

FIG. 33 is a diagram showing an example of a manufacturing step in the method for manufacturing the semiconductor device.

FIG. 34 is a diagram showing an example of a manufacturing step in the method for manufacturing the semiconductor device.

FIG. 35 is a cross-sectional view showing the semiconductor light emitting device in a modified example.

FIG. 36 is a cross-sectional view showing the semiconductor light emitting device in a modified example.

FIG. 37 is a plan view of the semiconductor light emitting device in a modified example with an encapsulation resin omitted.

FIG. 38 is a circuit diagram of the semiconductor light emitting device in a modified example.

FIG. 39 is a plan view of the semiconductor light emitting device in a modified example with an encapsulation resin omitted.

FIG. 40 is a plan view of the semiconductor light emitting device in a modified example with an encapsulation resin omitted.

FIG. 41 is a bottom view of the semiconductor light emitting device in a modified example.

### DESCRIPTION OF EMBODIMENTS

An embodiment of a semiconductor light emitting device will be described below with reference to the drawings. The embodiments described below exemplify configurations and methods for embodying a technical concept and are not intended to limit the material, shape, structure, layout, dimensions, and the like of each component to those described below. The embodiments described below may undergo various modifications.

In this specification, “at least one of A and B” should be understood to mean “only A, only B, or both A and B.”

### First Embodiment

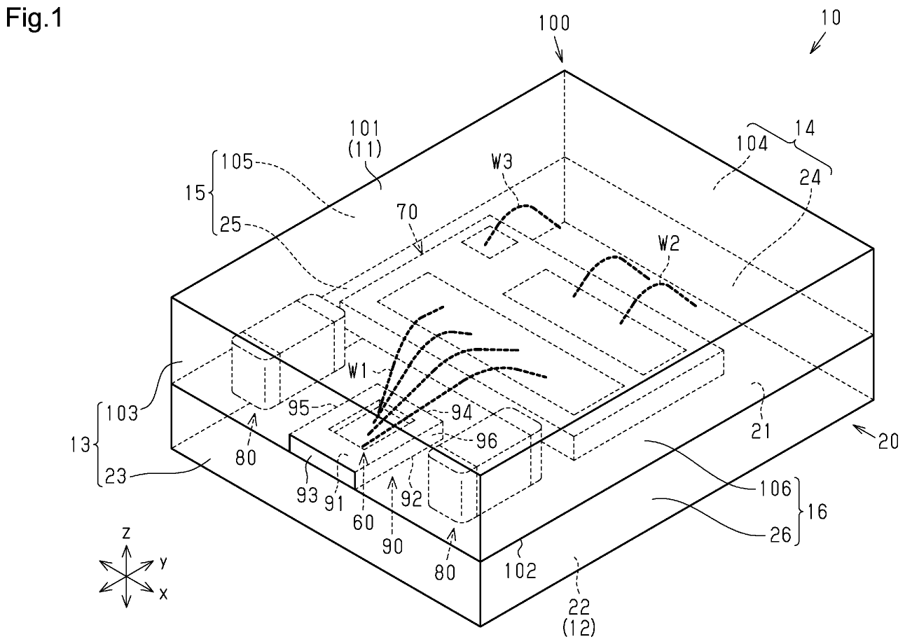

A first embodiment of a semiconductor light emitting device 10 will now be described with reference to FIGS. 1 to 17.

Structure of Semiconductor Light Emitting Device

The semiconductor light emitting device 10 shown in FIG. 1 may be used in, for example, a laser system as light detection and ranging (LiDAR), or laser imaging detection and ranging, which is an example of three-dimensional distance measurement. The semiconductor light emitting device 10 may also be used in a laser system of two-dimensional distance measurement.

As shown in FIG. 1, the semiconductor light emitting device 10 is rectangular and flat. The semiconductor light emitting device 10 includes a device main surface 11 and a device back surface 12, which face opposite directions, and device side surfaces 13 to 16, each of which faces a direction intersecting with the device main surface 11 and the device back surface 12. In the present embodiment, the device side surfaces 13 to 16 face directions orthogonal to the device main surface 11 and the device back surface 12.

The device main surface 11 and the device back surface 12 are spaced apart from each other. In the description hereafter, the arrangement direction of the device main surface 11 and the device back surface 12 is referred to as a z-direction. Two directions that are orthogonal to each other and orthogonal to the z-direction are referred to as an x-direction and a y-direction.

In the present embodiment, as viewed in the z-direction, the device side surfaces 13 and 14 extend in the x-direction, and the device side surfaces 15 and 16 extend in the y-direction. The device side surfaces 13 and 14 face opposite directions in the y-direction. The device side surfaces 15 and 16 face opposite directions in the x-direction. In the present embodiment, as viewed in the z-direction, the semiconductor light emitting device 10 is rectangular such that the short sides extend in the x-direction and the long sides extend in the y-direction.

As shown in FIG. 1, the semiconductor light emitting device 10 includes a substrate 20, a semiconductor light emitting element 60, a switching element 70, a capacitor 80, a transparent member 90, and an encapsulation resin 100. The semiconductor light emitting element 60, the switching element 70, and the capacitor 80 are mounted on the substrate 20. The transparent member 90 covers the semiconductor light emitting element 60. The encapsulation resin 100 encapsulates the switching element 70, the capacitor 80, and the transparent member 90. In the present embodiment, the switching element 70 and the capacitor 80 are each an example of a drive element used to drive the semiconductor light emitting element 60.

The outer surface of the semiconductor light emitting device 10 is defined by the substrate 20, the transparent member 90, and the encapsulation resin 100. The transparent member 90 and the encapsulation resin 100 are stacked on the substrate 20.

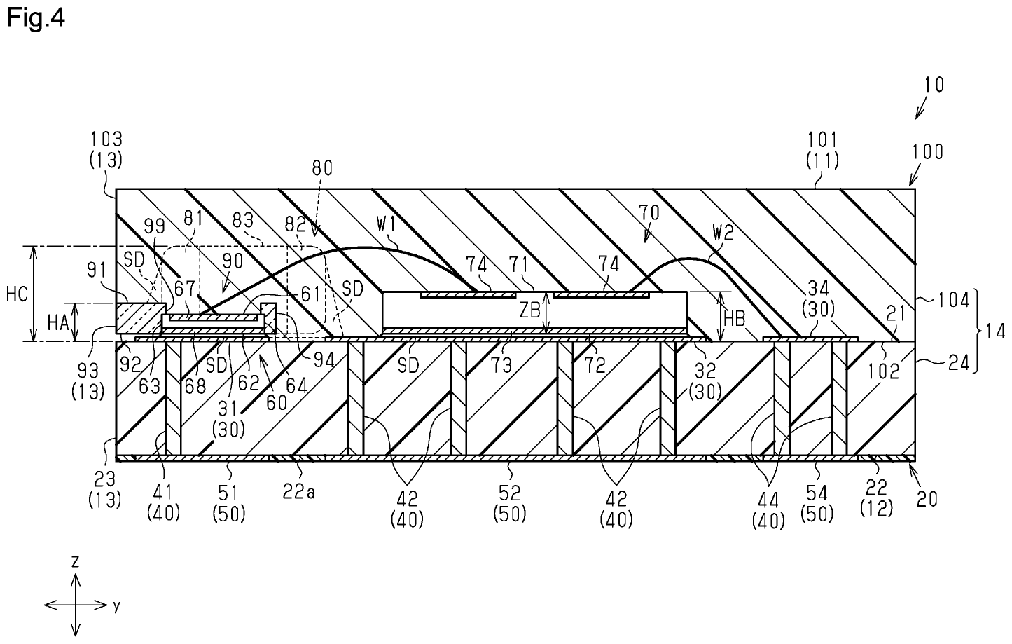

The substrate 20 is formed of, for example, a printed circuit board (PCB) or a ceramic substrate. In the present embodiment, a PCB substrate is used as the substrate 20. In an example, the PCB substrate includes an insulation layer formed from a glass-epoxy resin, a conductive layer formed from copper (Cu) or the like, and connection vias formed from Cu or the like and connecting conductive layers to each other. As shown in FIG. 4, in the description of the present embodiment, the insulation layer is the substrate 20, the conductive layers are main surface wiring lines 30 and external electrodes 50, and the connection vias are connection wiring lines 40.

As shown in FIG. 1, the substrate 20 is rectangular and flat and has a thickness-wise direction conforming to the z-direction. Thus, the z-direction may also be referred to as the thickness-wise direction of the substrate 20. The substrate 20 is located closer to the device back surface 12 of the semiconductor light emitting device 10 than the device main surface 11 in the z-direction. The substrate 20 defines the device back surface 12 and a portion of each of the device side surfaces 13 to 16 in the z-direction.

The substrate 20 includes a substrate main surface 21 and a substrate back surface 22, which face opposite directions in the z-direction, and substrate side surfaces 23 to 26, each of which faces a direction orthogonal to the substrate main surface 21 and the substrate back surface 22. The substrate main surface 21 and the device main surface 11 face the same direction. The substrate back surface 22 and the device back surface 12 face the same direction. In the present embodiment, the substrate back surface 22 defines the device back surface 12. The substrate side surface 23 and the device side surface 13 face the same direction. The substrate side surface 24 and the device side surface 14 face the same direction. The substrate side surface 25 and the device side surface 15 face the same direction. The substrate side surface 26 and the device side surface 16 face the same direction. As viewed in the z-direction, the substrate 20 is rectangular such that the short sides extend in the x-direction and the long sides extend in the y-direction.

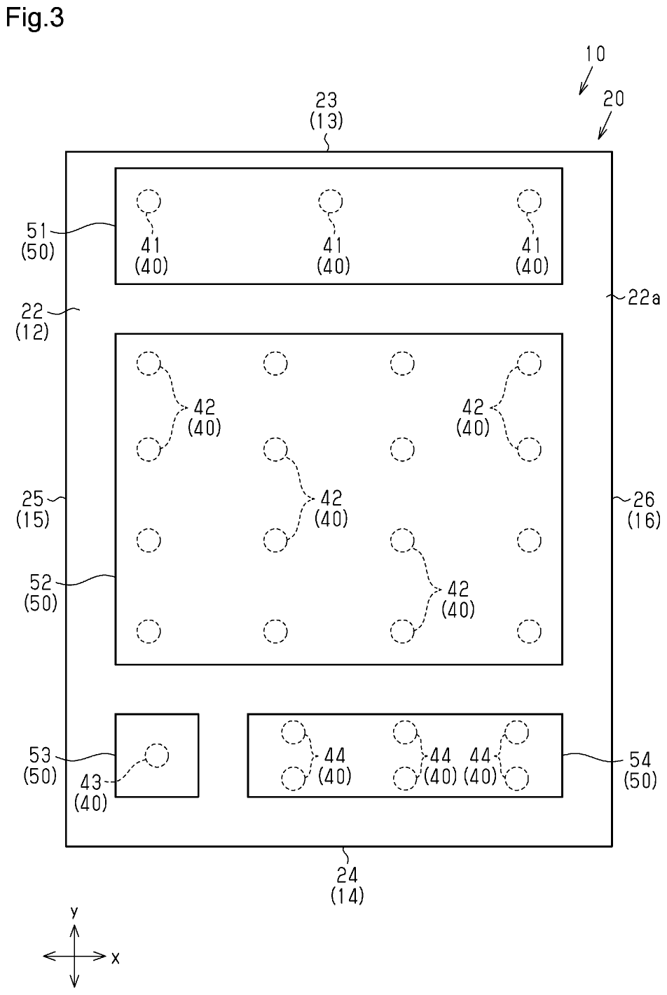

As shown in FIG. 3, the external electrodes 50 are disposed on the substrate back surface 22. For example, when the semiconductor light emitting device 10 is mounted on a circuit substrate, the external electrodes 50 serve as external terminals that are electrically connected to wiring lines or the like on the circuit substrate. That is, for example, when the semiconductor light emitting device 10 is mounted on a circuit substrate, the substrate back surface 22 serves as a mount surface. Thus, in the present embodiment, the semiconductor light emitting device 10 has a package structure of a front surface mount type.

The external electrodes 50 are formed of, for example, a lamination of a nickel (Ni) layer, a palladium (Pd) layer, and a gold (Au) layer. In the present embodiment, the external electrodes 50 include a connection electrode 51, a power supply electrode 52, a control electrode 53, and a ground electrode 54.

As shown in FIGS. 3 and 4, a back surface insulation layer 22a is disposed on the substrate back surface 22. The back surface insulation layer 22a is disposed on a portion of the substrate back surface 22 excluding the external electrodes 50. The back surface insulation layer 22a is formed of, for example, a waterproof insulation coating material.

As shown in FIG. 1, the transparent member 90 is formed of a member that is transmissive to light emitted from the semiconductor light emitting element 60 (more specifically, light emitting element side surface 63, which corresponds to a light emitting surface and will be described later) and is configured to emit the light from the semiconductor light emitting element 60 to the outside of the semiconductor light emitting device 10. The transparent member 90 is disposed on the substrate main surface 21 of the substrate 20. The transparent member 90 defines a portion of the device side surface 13. Thus, in the present embodiment, the semiconductor light emitting device 10 is configured to emit light from the device side surface 13. As viewed in the z-direction, the transparent member 90 is disposed on one of the two ends of the substrate main surface 21 in the y-direction located closer to the substrate side surface 23. As shown in FIG. 1, the transparent member 90 is smaller in size than the substrate 20 and the encapsulation resin 100. Also, the transparent member 90 is smaller in size than the switching element 70.

The transparent member 90 is rectangular and flat. The transparent member 90 includes a transparent main surface 91 and a transparent back surface 92, which face opposite directions in the z-direction, and transparent side surfaces 93 to 96, each of which faces a direction orthogonal to the transparent main surface 91 and the transparent back surface 92. The transparent main surface 91 and the device main surface 11 face the same direction. The transparent back surface 92 and the device back surface 12 face the same direction. The transparent side surface 93 and the device side surface 13 face the same direction. The transparent side surface 94 and the device side surface 14 face the same direction. The transparent side surface 95 and the device side surface 15 face the same direction. The transparent side surface 96 and the device side surface 16 face the same direction. In the present embodiment, the transparent side surface 93 is exposed to the outside of the semiconductor light emitting device 10 and defines a portion of the device side surface 13. The transparent side surface 93 is an example of a transparent surface.

As shown in FIG. 1, the encapsulation resin 100 is rectangular and flat and has a thickness-wise direction conforming to the z-direction. Thus, the thickness-wise direction of the encapsulation resin 100 may also be referred to as the thickness-wise direction of the substrate 20. The encapsulation resin 100 is disposed on the substrate main surface 21 of the substrate 20. Thus, the encapsulation resin 100 is in contact with the substrate main surface 21. The encapsulation resin 100 defines the device main surface 11 and a portion of each of the device side surfaces 13 to 16 in the z-direction. In the present embodiment, the encapsulation resin 100 is greater in thickness (dimension in the z-direction) than the substrate 20. The encapsulation resin 100 is greater in thickness than the transparent member 90. The thickness of the encapsulation resin 100 is greater than or equal to 0.6 mm and less than or equal to 0.8 mm. The thickness of the encapsulation resin 100 may be changed in any manner and may be, for example, less than or equal to the thickness of the substrate 20.

As shown in FIG. 1, the encapsulation resin 100 includes a resin main surface 101 and a resin back surface 102, which face opposite directions in the z-direction, and resin side surfaces 103 to 106, each of which faces a direction orthogonal to the resin main surface 101 and the resin back surface 102. The resin main surface 101 and the device main surface 11 face the same direction. The resin back surface 102 and the device back surface 12 face the same direction. In the present embodiment, the resin main surface 101 defines the device main surface 11. The resin back surface 102 is in contact with the substrate main surface 21 of the substrate 20. The resin side surface 103 and the device side surface 13 face the same direction. The resin side surface 104 and the device side surface 14 face the same direction. The resin side surface 105 and the device side surface 14 face the same direction. The resin side surface 106 and the device side surface 16 face the same direction. As viewed in the z-direction, the encapsulation resin 100 is rectangular so that the short sides extend in the x-direction and the long sides extend in the y-direction. As shown in FIG. 1, in the present embodiment, the resin side surface 103 is flush with the substrate side surface 23. The resin side surface 104 is flush with the substrate side surface 24. The resin side surface 105 is flush with the substrate side surface 25. The resin side surface 106 is flush with the substrate side surface 26. In the present embodiment, the device side surface 13 is defined by the resin side surface 103, the transparent side surface 93, and the substrate side surface 23. The device side surface 14 is defined by the resin side surface 104 and the substrate side surface 24. The device side surface 15 is defined by the resin side surface 105 and the substrate side surface 25. The device side surface 16 is defined by the resin side surface 106 and the substrate side surface 26.

The shape of the encapsulation resin 100 and the substrate 20 as viewed in the z-direction may be changed in any manner. In an example, the shape of each of the encapsulation resin 100 and the substrate 20 as viewed in the z-direction may be square or rectangular so that the long sides extend in the x-direction and the short sides extend in the y-direction.

The internal structure of the semiconductor light emitting device 10 will now be described.

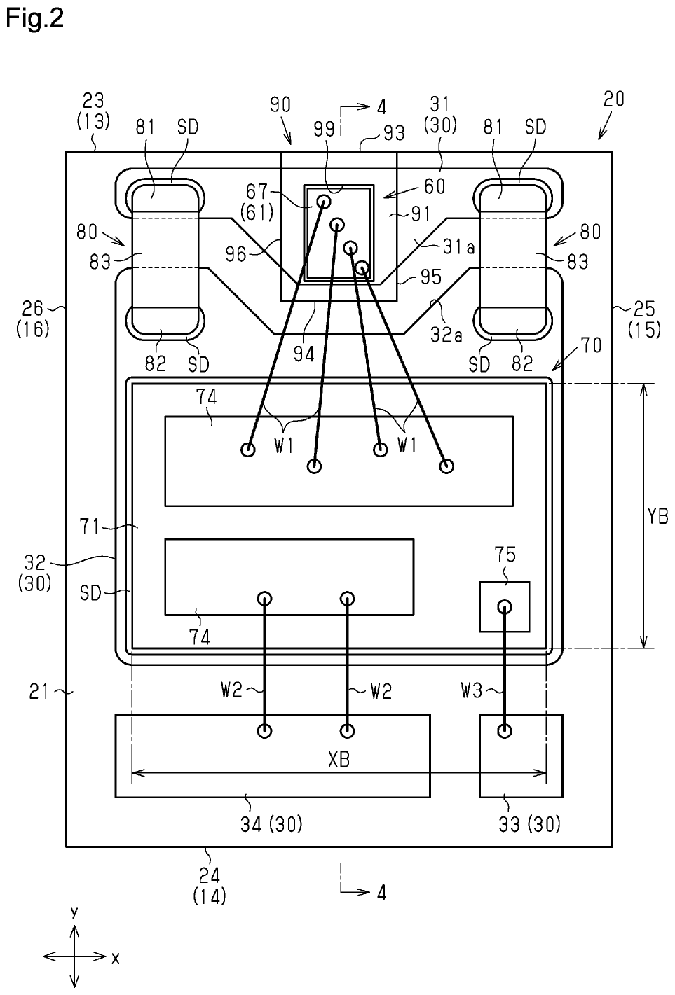

As shown in FIG. 2, the main surface wiring lines 30 are disposed on the substrate main surface 21 of the substrate 20 and are formed of, for example, a copper foil. The main surface wiring lines 30 include a first main surface wiring line 31, a second main surface wiring line 32, a third main surface wiring line 33, and a fourth main surface wiring line 34. The wiring lines 31 to 34 are separated from each other as viewed in the z-direction.

The first main surface wiring line 31 is a wiring line on which the semiconductor light emitting element 60 is mainly mounted. The first main surface wiring line 31 is disposed on one of the two ends of the substrate main surface 21 in the y-direction located closer to the substrate side surface 23. The first main surface wiring line 31 extends over a large portion of the substrate main surface 21 in the x-direction. The first main surface wiring line 31 includes a projection 31a projecting from a central portion of the first main surface wiring line 31 in the x-direction toward the substrate side surface 24 in the y-direction. The shape of the projection 31a as viewed in the z-direction is trapezoidal and tapered from the substrate side surface 23 toward the substrate side surface 24. The semiconductor light emitting element 60 is mounted on the projection 31a. More specifically, the semiconductor light emitting element 60 is bonded to the projection 31a by a conductive bonding material SD (refer to FIG. 4) such as solder or silver (Ag) paste.

The second main surface wiring line 32 is a wiring line on which the switching element 70 is mainly mounted. The second main surface wiring line 32 is disposed on the substrate main surface 21 adjacent to the first main surface wiring line 31 in the y-direction substantially in the center of the substrate main surface 21 in the y-direction. The second main surface wiring line 32 is greater in area than the remaining wiring lines 31, 33, and 34 as viewed in the z-direction. A recess 32a is disposed in a central portion of the second main surface wiring line 32 in the x-direction at one of the two ends of the second main surface wiring line 32 in the y-direction located closer to the substrate side surface 23. The recess 32a is formed to accommodate a distal end of the projection 31a. The switching element 70 is disposed on a portion of the second main surface wiring line 32 located closer to the substrate side surface 24 than the recess 32a. More specifically, the switching element 70 is bonded to the second main surface wiring line 32 by the conductive bonding material SD.

The third main surface wiring line 33 and the fourth main surface wiring line 34 are each electrically connected to the switching element 70. The wiring lines 33 and 34 and the first main surface wiring line 31 are located at opposite sides of the second main surface wiring line 32 in the y-direction. More specifically, the wiring lines 33 and 34 are disposed on the substrate main surface 21 at a position closer to the substrate side surface 24 than the second main surface wiring line 32 in the y-direction. The wiring lines 33 and 34 are aligned with each other in the y-direction and spaced apart from each other in the x-direction. The third main surface wiring line 33 is disposed closer to the substrate side surface 25 than the fourth main surface wiring line 34. In the present embodiment, the fourth main surface wiring line 34 is longer in the x-direction than the third main surface wiring line 33 and is shorter in the x-direction than the switching element 70. The fourth main surface wiring line 34 is equal in length in the y-direction to the third main surface wiring line 33. The dimensions of the third main surface wiring line 33 and the fourth main surface wiring line 34 in the x-direction and the y-direction may be changed in any manner within a range that allows for connection of the second wires W2 and the third wire W3, which will be described later, to the fourth main surface wiring line 34 and the third main surface wiring line 33, respectively. In the present embodiment, the third main surface wiring line 33 is an example of a main surface control wiring line configured to be electrically connected to a control electrode 75 of the switching element 70. The fourth main surface wiring line 34 is an example of a main surface drive wiring line configured to be electrically connected to a drive electrode (second drive electrode 74) of the switching element 70.

As shown in FIGS. 3 and 4, the substrate 20 includes the connection wiring lines 40 extending through the substrate 20 in the z-direction. The connection wiring lines 40 connect the main surface wiring lines 30 and the external electrodes 50. Thus, the connection wiring lines 40 electrically connect the external electrodes 50 to the semiconductor light emitting element 60 and the switching element 70.

The connection wiring lines 40 include connection wiring lines 41, 42, 43, and 44. As shown in FIG. 4, as viewed in the z-direction, the first connection wiring line 41 is disposed to overlap the first main surface wiring line 31 of the substrate main surface 21 and the connection electrode 51 of the substrate back surface 22 and electrically connect the first main surface wiring line 31 and the connection electrode 51. In the present embodiment, multiple first connection wiring lines 41 are provided. The first connection wiring lines 41 are aligned with each other in the y-direction and spaced apart from each other in the x-direction.

As shown in FIG. 4, as viewed in the z-direction, the second connection wiring line 42 is disposed to overlap the second main surface wiring line 32 of the substrate main surface 21 and the power supply electrode 52 of the substrate back surface 22 and electrically connect the second main surface wiring line 32 and the power supply electrode 52. In the present embodiment, multiple second connection wiring lines 42 are provided. The second connection wiring lines 42 are spaced apart from each other in the x-direction and the y-direction in a grid arrangement.

As shown in FIG. 3, as viewed in the z-direction, the third connection wiring line 43 is disposed to overlap the third main surface wiring line 33 of the substrate main surface 21, which is shown in FIG. 2, and the control electrode 53 of the substrate back surface 22 and electrically connect the third main surface wiring line 33 and the control electrode 53.

As shown in FIG. 4, as viewed in the z-direction, the fourth connection wiring line 44 is disposed to overlap the fourth main surface wiring line 34 of the substrate main surface 21 and the ground electrode 54 of the substrate back surface 22 and electrically connect the fourth main surface wiring line 34 and the ground electrode 54. The number of each of the connection wiring lines 41 to 44 may be changed in any manner.

The semiconductor light emitting element 60 is mounted on the projection 31a of the first main surface wiring line 31 (refer to FIG. 2). As shown in FIG. 1, the semiconductor light emitting element 60 is rectangular and flat and has a thickness-wise direction conforming to the z-direction. Thus, the thickness-wise direction of the semiconductor light emitting element 60 may also be referred to as the thickness-wise direction of the substrate 20. In the present embodiment, the semiconductor light emitting element 60 is a light source of the semiconductor light emitting device 10 and is a semiconductor laser element. An example of the semiconductor laser element is a pulsed laser diode. The material of the semiconductor light emitting element 60 is, for example, gallium arsenide (GaAs). The specifications of the semiconductor light emitting element 60 are such that, for example, the oscillation wavelength is 905 nm, the optical output is 75 W or greater, and the pulse width is a few dozen nanoseconds or less. Preferably, the specifications of the semiconductor light emitting element 60 are such that the optical output is 150 W or greater and the pulse width is 10 ns or less. More preferably, the specifications of the semiconductor light emitting element 60 are such that the pulse width is 5 ns or less.

As shown in FIG. 4, the semiconductor light emitting element 60 includes a light emitting element main surface 61 and a light emitting element back surface 62, which face opposite directions in the z-direction. The light emitting element main surface 61 and the substrate main surface 21 face the same direction. The light emitting element back surface 62 and the substrate back surface 22 face the same direction. As viewed in the z-direction, the light emitting element main surface 61 and the light emitting element back surface 62 each are rectangular and have a longitudinal direction and a lateral direction. In the present embodiment, the semiconductor light emitting element 60 is disposed on the substrate main surface 21 so that the long sides extend in the y-direction and the short sides extend in the x-direction.

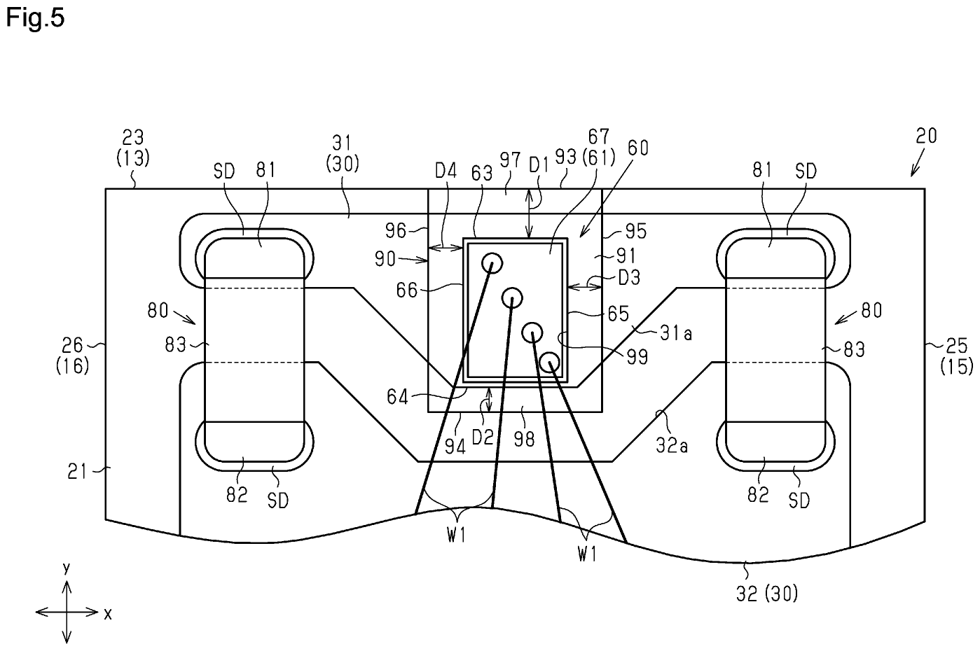

As shown in FIG. 5, the semiconductor light emitting element 60 includes the light emitting element side surfaces 63 to 66, each of which faces a direction intersecting the light emitting element main surface 61. In the present embodiment, the light emitting element side surfaces 63 to 66 face a direction orthogonal to the light emitting element main surface 61 and the light emitting element back surface 62. The light emitting element side surface 63 defines a light emitting surface through which the semiconductor light emitting element 60 emits light. In other words, the semiconductor light emitting element 60 includes a light emitting surface facing a direction intersecting the light emitting element main surface 61. The light emitting element side surface 63 and the substrate side surface 23 (the device side surface 13) face the same direction. In other words, the semiconductor light emitting element 60 is disposed so that the light emitting surface faces the same direction as the substrate side surface 23 (the device side surface 13). Thus, as shown in FIG. 1, the semiconductor light emitting device 10 emits light from the device side surface 13. As shown in FIG. 5, the light emitting element side surface 64 and the substrate side surface 24 face the same direction. The light emitting element side surface 65 and the substrate side surface 25 face the same direction. The light emitting element side surface 66 and the substrate side surface 26 face the same direction.

As shown in FIG. 4, the semiconductor light emitting element 60 includes a first electrode 67 disposed on the light emitting element main surface 61 and a second electrode 68 disposed on the light emitting element back surface 62. In the present embodiment, the first electrode 67 is an anode, and the second electrode 68 is a cathode. The first electrode 67 is an example of a main surface electrode of the semiconductor light emitting element 60. As viewed in the z-direction, the first electrode 67 is rectangular such that the short sides extend in the x-direction and the long sides extend in the y-direction. In the present embodiment, as viewed in the z-direction, the first electrode 67 is slightly smaller than the light emitting element main surface 61. The second electrode 68 is connected to the first main surface wiring line 31 by the conductive bonding material SD. That is, the second electrode 68 is electrically connected to the first main surface wiring line 31.

The switching element 70 is mounted on the second main surface wiring line 32. As shown in FIG. 1, the switching element 70 is rectangular and flat and has a thickness-wise direction conforming to the z-direction. Thus, the thickness-wise direction of the switching element 70 may also be referred to as the thickness-wise direction of the substrate 20. The switching element 70 is configured to control the current supplied to the semiconductor light emitting element 60. In other words, the switching element 70 is configured to drive the semiconductor light emitting element 60. As viewed in the z-direction, the switching element 70 is rectangular and has a longitudinal direction and a lateral direction. In the present embodiment, the switching element 70 is disposed so that the long sides extend in the x-direction and the short sides extend in the y-direction.

The switching element 70 is, for example, a transistor formed from silicon (Si), silicon carbide (SiC), or gallium nitride (GaN). When the switching element 70 is formed from GaN or SiC, it is suitable for high-speed switching. In the present embodiment, the switching element 70 is an N-type metal-oxide-semiconductor field-effect-transistor (MOSFET) formed from S1.

As viewed in the z-direction, the switching element 70 is greater in area than the semiconductor light emitting element 60. In other words, as viewed in the z-direction, the semiconductor light emitting element 60 is smaller in area than the switching element 70. More specifically, the semiconductor light emitting element 60 is shorter in the x-direction than the switching element 70. The semiconductor light emitting element 60 is shorter in the y-direction than the switching element 70. In the present embodiment, the thickness of the switching element 70 is greater than or equal to 0.2 mm and less than or equal to 0.3 mm.

The size of the switching element 70 is set in accordance with the type of material forming the switching element such as S1, SiC, GaN and the specifications of the semiconductor light emitting device 10. In the present embodiment, since the switching element 70 is formed of S1, the switching element 70 is increased in size.

As shown in FIG. 4, the switching element 70 includes a switching element main surface 71 and a switching element back surface 72, which face opposite directions in the z-direction. The switching element 70 includes a first drive electrode 73, which is disposed on the switching element back surface 72, and the second drive electrode 74 and the control electrode 75, which are disposed on the switching element main surface 71. In the present embodiment, the first drive electrode 73 is a drain electrode, the second drive electrode 74 is a source electrode, and the control electrode 75 is a gate electrode. Thus, the switching element 70 is a vertical metal-oxide-semiconductor field-effect transistor (MOSFET) in which the drive electrodes are disposed on the switching element main surface 71 and the switching element back surface 72. The switching element 70 is not limited to a vertical MOSFET and may be a lateral MOSFET in which the first drive electrode 73, the second drive electrode 74, and the control electrode 75 are disposed on the switching element main surface 71.

The first drive electrode 73 is disposed on the entirety of the switching element back surface 72. The first drive electrode 73 is connected to the second main surface wiring line 32 by the conductive bonding material SD. Thus, the first drive electrode 73 is electrically connected to the second main surface wiring line 32. Multiple (two in the present embodiment) second drive electrodes 74 are disposed on the switching element main surface 71 over a large portion of the switching element main surface 71. The second drive electrodes 74 are spaced apart from each other in the y-direction. As shown in FIG. 2, the control electrode 75 is disposed on one of the four corners of the switching element main surface 71. In the present embodiment, as viewed in the z-direction, the switching element 70 is disposed so that the control electrode 75 is located close to the substrate side surface 24 and the substrate side surface 26.

As shown in FIG. 2, the first electrode 67 of the semiconductor light emitting element 60 is electrically connected to the second drive electrode 74 of the switching element 70 by one or more (in the present embodiment, four) first wires W1. More specifically, each first wire W1 includes a first end connected to the first electrode 67 and a second end connected to the second drive electrode 74. In the present embodiment, as viewed in the z-direction, the first wires W1 are disposed so that adjacent ones of the first wires W1 are spaced apart by a gap that gradually increases in the x-direction from the semiconductor light emitting element 60 toward the switching element 70.

The second drive electrode 74 of the switching element 70 is electrically connected to the fourth main surface wiring line 34 by one or more (in the present embodiment, two) second wires W2. More specifically, as viewed in the y-direction, the second drive electrode 74 and the fourth main surface wiring line 34 are disposed to overlap each other. Hence, the second wires W2 are spaced apart in the x-direction and extend in the y-direction as viewed in the z-direction.

The control electrode 75 of the switching element 70 is electrically connected to the third main surface wiring line 33 by one third wire W3. More specifically, as viewed in the y-direction, the control electrode 75 and the third main surface wiring line 33 are disposed to overlap each other. Hence, as viewed in the z-direction, the third wire W3 extends in the y-direction.

The second wires W2 and the third wire W3 are located at a side of the switching element 70 opposite from the first wires W1. More specifically, the second wires W2 and the third wire W3 extend in the y-direction from the switching element main surface 71 to the side opposite to the semiconductor light emitting element 60. Each of the wires W1 to W3 is an example of a wire electrically connected to the switching element 70.

As shown in FIG. 2, the semiconductor light emitting device 10 includes multiple (in the present embodiment, two) capacitors 80. The capacitors 80 include a capacitor bank configured to temporarily store electric charge, which will be current flowing to the semiconductor light emitting element 60. The number of the capacitors 80 and the capacitance of each capacitor 80 are set in accordance with output of the semiconductor light emitting element 60. The two capacitors 80 are disposed at opposite sides of the semiconductor light emitting element 60 in the x-direction and spaced apart from the semiconductor light emitting element 60. The capacitors 80 are aligned with each other in the y-direction and spaced apart from each other in the x-direction. As viewed in the x-direction, the capacitors 80 are disposed to overlap the semiconductor light emitting element 60. Each capacitor 80 extends over the first main surface wiring line 31 and the second main surface wiring line 32 in the y-direction and is mounted on both the first main surface wiring line 31 and the second main surface wiring line 32. In the present embodiment, the two capacitors 80 are connected to two ends of each of the wiring lines 31 and 32 in the x-direction.

The capacitors 80 are identical in structure. Each capacitor 80 is rectangular box-shaped and has a longitudinal direction and a lateral direction. The capacitor 80 includes one longitudinal end provided with a first terminal 81 and the other longitudinal end provided with a second terminal 82. The capacitor 80 is disposed so that the longitudinal direction conforms to the y-direction and the lateral direction conforms to the x-direction. The first terminal 81 of the capacitor 80 is bonded to the first main surface wiring line 31 by the conductive bonding material SD. The second terminal 82 of the capacitor 80 is bonded to the second main surface wiring line 32 by the conductive bonding material SD. Thus, the capacitor 80 is electrically connected to the first main surface wiring line 31 and the second main surface wiring line 32. In other words, the capacitor 80 is electrically connected to the second electrode 68 of the semiconductor light emitting element 60 and the first drive electrode 73 of the switching element 70. The capacitor 80 includes a capacitor main surface 83 facing the same direction as the substrate main surface 21.

The capacitor 80 is, for example, a ceramic capacitor or a silicon capacitor. In an example, the thickness (dimension the z-direction) of the capacitor 80 is greater than the thickness of each of the semiconductor light emitting element 60, the transparent member 90, and the switching element 70. When the capacitor 80 is a ceramic capacitor, the thickness of the capacitor 80 is approximately greater than or equal to 0.3 mm and less than or equal to 0.8 mm. When the capacitor 80 is a silicon capacitor, the thickness of the capacitor 80 is greater than or equal to 0.1 mm and less than or equal to 0.3 mm. In the present embodiment, the capacitor 80 is a ceramic capacitor, and the thickness of the capacitor 80 is approximately 0.5 mm. Thus, the capacitor main surface 83 is located closer to the resin main surface 101 of the encapsulation resin 100 than the resin back surface 102 in the z-direction.

The semiconductor light emitting element 60, the transparent member 90, the switching element 70, the capacitors 80, and the wires W1 to W3 are disposed in the encapsulation resin 100. In other words, the encapsulation resin 100 encapsulates the semiconductor light emitting element 60, the transparent member 90, the switching element 70, the capacitors 80, and the wires W1 to W3.

Thus, the encapsulation resin 100 encapsulates the transparent member 90 together with the semiconductor light emitting element 60 and the drive element. Further, the encapsulation resin 100 encapsulates the wires connected to the switching element 70 together with the semiconductor light emitting element 60 and the drive element. More specifically, the encapsulation resin 100 encapsulates the wires connected to the switching element 70 and the main surface wiring lines 30 together with the semiconductor light emitting element 60 and the drive element.

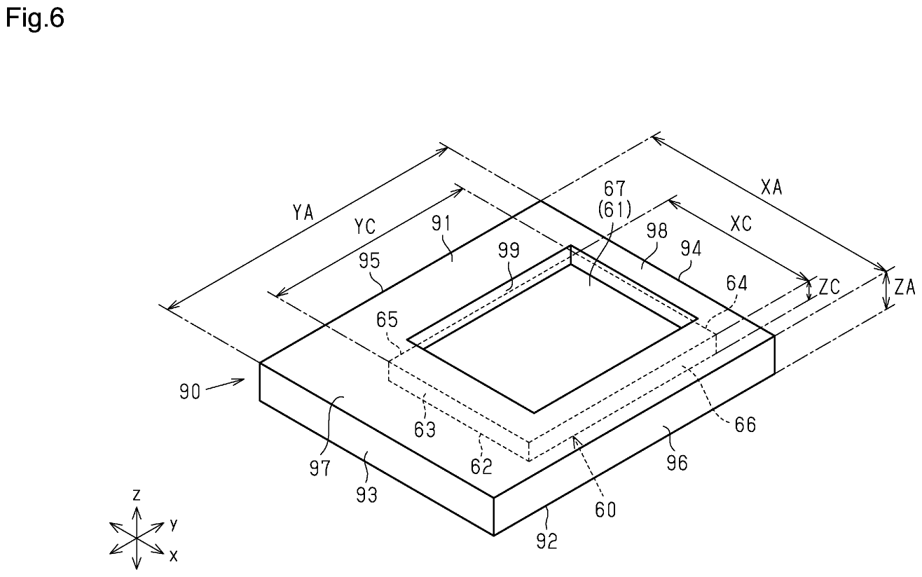

The semiconductor light emitting element 60 and the transparent member 90 will now be described with reference to FIGS. 4 to 7. In FIG. 6, to facilitate the distinction between transparent member 90 and the semiconductor light emitting element 60, the semiconductor light emitting element 60 is indicated by broken lines for the sake of convenience.

As shown in FIG. 6, the transparent member 90 is formed integrally with the semiconductor light emitting element 60. The transparent member 90 is configured to cover the light emitting element side surface 63, which is the light emitting surface of the semiconductor light emitting element 60. In the present embodiment, the transparent member 90 covers a peripheral portion of the light emitting element main surface 61 of the semiconductor light emitting element 60 and the light emitting element side surfaces 63 to 66 of the semiconductor light emitting element 60.

The transparent member 90 has a dimension XA in the x-direction. The semiconductor light emitting element 60 has a dimension XC in the x-direction. As viewed in the z-direction, the dimension XA is larger than the dimension XC. The transparent member 90 has a dimension YA in the y-direction. The semiconductor light emitting element 60 has a dimension YC in the y-direction. The dimension YA is larger than the dimension YC. The transparent member 90 has a dimension ZA in the z-direction. The semiconductor light emitting element 60 has a dimension ZC in the z-direction. The dimension ZA is larger than the dimension ZC. In other words, the thickness of the transparent member 90 is greater than the thickness of the semiconductor light emitting element 60. The dimension XA of the transparent member 90 is smaller than a dimension XB (refer to FIG. 2) of the switching element 70 in the x-direction. The dimension YA of the transparent member 90 is smaller than the dimension YB (refer to FIG. 2) of the switching element 70 in the y-direction. The dimension ZA of the transparent member 90 is smaller than the dimension ZB (refer to FIG. 4) of the switching element 70 in the z-direction. In other words, the thickness of the transparent member 90 is smaller than the thickness of the switching element 70. In the present embodiment, the thickness (dimension in the z-direction) of the transparent member 90 is greater than 0.1 mm and less than 0.2 mm. In the present embodiment, the thickness of the transparent member 90 is smaller than the thickness of the switching element 70 (refer to FIG. 4). In the present embodiment, the dimension XC of the semiconductor light emitting element 60 in the x-direction is approximately 0.4 mm. The dimension YC of the semiconductor light emitting element 60 in the y-direction is approximately 0.6 mm. The thickness (dimension ZC in the z-direction) of the semiconductor light emitting element 60 is approximately 0.1 mm.

As shown in FIG. 4, a distance HA between the substrate main surface 21 and the transparent main surface 91 of the transparent member 90 is shorter than a distance HB between the substrate main surface 21 and the switching element main surface 71 of the switching element 70. The distance HA is also shorter than a distance HC between the substrate main surface 21 and the capacitor main surface 83 of the capacitor 80.

As shown in FIG. 5, the semiconductor light emitting element 60 is off-center of the transparent member 90 in the y-direction. More specifically, the semiconductor light emitting element 60 is deviated from the transparent member 90 to a position closer to the transparent side surface 94 than the transparent side surface 93 in the y-direction. Thus, a distance D1 between the transparent side surface 93 of the transparent member 90 and the light emitting element side surface 63 (light emitting surface) of the semiconductor light emitting element 60 in the y-direction is greater than a distance D2 between the transparent side surface 94 and the light emitting element side surface 64 in the y-direction. This structure allows the semiconductor light emitting element 60 to be located closer to the switching element 70 (refer to FIG. 2) in the y-direction while allowing the transparent member 90 to transmit light from the semiconductor light emitting element 60 to the outside of the semiconductor light emitting device 10. The distance D1 is greater than a distance D3 between the transparent side surface 95 and the light emitting element side surface 65 in the x-direction. The distance D1 is also greater than a distance D4 between the transparent side surface 96 and the light emitting element side surface 66 in the x-direction.

In the present embodiment, the transparent member 90 includes a transparent portion 97 located between the transparent side surface 93 and the light emitting element side surface 63. The dimensions of the transparent portion 97 in the x-direction and the z-direction are larger than the dimension XC in the x-direction and the dimension ZC in the z-direction (refer to FIG. 6) of the semiconductor light emitting element 60. The transparent portion 97 covers the light emitting element side surface 63, which is the light emitting surface of the semiconductor light emitting element 60, and is transmissive to the light emitted from the light emitting surface. That is, the light emitted from the semiconductor light emitting element 60 transmits through the transparent portion 97. The transparent portion 97 includes the transparent side surface 93, which corresponds to a transparent surface. In the present embodiment, the dimension of the transparent portion 97 in the x-direction is equal to the dimension XA of the transparent member 90 in the x-direction. The dimension of the transparent portion 97 in the z-direction is equal to the dimension ZA of the transparent member 90 in the z-direction.

The transparent member 90 includes a cover portion 98 between the transparent side surface 94 and the light emitting element side surface 64. As viewed in the z-direction, the cover portion 98 projects from the projection 31a of the first main surface wiring line 31. In the y-direction, the cover portion 98 projects beyond the distal end of the projection 31a toward the second main surface wiring line 32. The positional relationship between the transparent member 90 and the first main surface wiring line 31 as viewed in the z-direction may be changed in any manner. In an example, the transparent member 90 may be disposed so that the cover portion 98 does not project beyond the projection 31a of the first main surface wiring line 31 as viewed in the z-direction.

As viewed in the z-direction, each capacitor 80 is spaced apart from the transparent member 90 in the x-direction. Hence, the encapsulation resin 100 is disposed between the transparent member 90 and the capacitor 80.

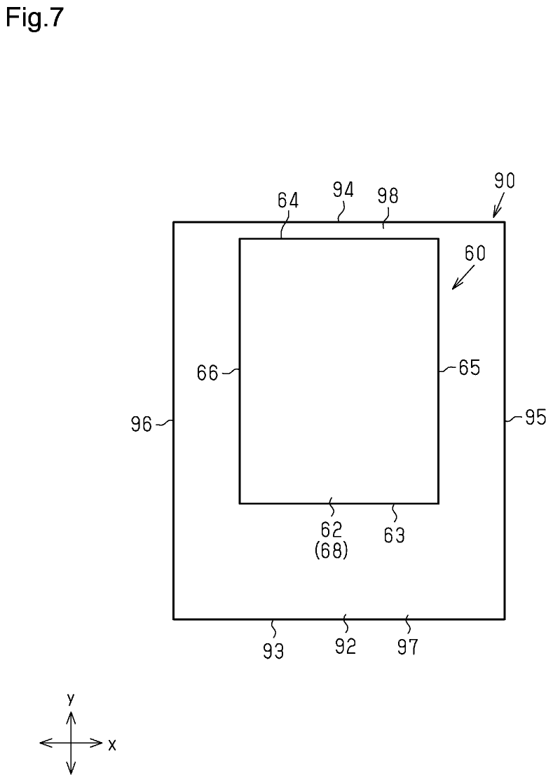

As shown in FIG. 7, the light emitting element back surface 62 of the semiconductor light emitting element 60 is exposed from the transparent member 90 in the z-direction. As shown in FIG. 4, the light emitting element back surface 62 of the semiconductor light emitting element 60 is flush with the transparent back surface 92 of the transparent member 90.

As shown in FIGS. 4 to 6, the transparent member 90 includes an opening 99 from which the light emitting element main surface 61 of the semiconductor light emitting element 60 is exposed in the z-direction. The first electrode 67 of the light emitting element main surface 61 is exposed from the opening 99 in the z-direction. In the present embodiment, as viewed in the z-direction, the opening 99 is rectangular such that the short sides extend in the x-direction and the long sides extend in the y-direction. In the present embodiment, the first electrode 67 is entirely exposed from the opening 99 in the z-direction. The shape of the opening 99 as viewed in the z-direction may be changed in any manner and may be, for example, a circle or an ellipse.

The first end of each first wire W1 is connected to the first electrode 67 exposed from the opening 99. The transparent member 90 includes the opening 99 to avoid interference of the transparent member 90 with the first wire W1. As shown in FIG. 4, the encapsulation resin 100 fills the opening 99. Thus, the first wires W1 are encapsulated by the encapsulation resin 100.

As shown in FIG. 4, the transparent main surface 91 and the transparent side surfaces 94 to 96 (refer to FIG. 5) of the transparent member 90 are covered by the encapsulation resin 100. In contrast, the transparent back surface 92 and the transparent side surface 93 (light emitting surface) of the transparent member 90 are not covered by the encapsulation resin 100. Alternatively, the transparent back surface 92 may be covered by the encapsulation resin 100.

The physical properties of each component of the semiconductor light emitting device 10 will now be described.

In the substrate 20, a glass-epoxy resin is used as an insulation layer that electrically insulates the main surface wiring lines 30, the external electrodes 50, and the connection wiring lines 40 from each other. The linear expansion coefficient of the glass-epoxy resin is, for example, greater than or equal to 12 ppm/° C. and less than or equal to 17 ppm/° C. In the present embodiment, the linear expansion coefficient of the insulation layer of the substrate 20 corresponds to the linear expansion coefficient of the substrate 20.

The semiconductor light emitting element 60 is mainly formed from GaAs. The linear expansion coefficient of GaAs is approximately 5.7 ppm/° C.

The switching element 70 is mainly formed from S1. The linear expansion coefficient of S1 is 3.3 ppm/° C.

The wires W1 to W3 are mainly formed of Au or Cu. The linear expansion coefficient of Au is 14.3 ppm/° C. The linear expansion coefficient of Cu is 16.3 ppm/° C.

The transparent member 90 is formed from an electrically insulative, light-transmissive material. In an example, the transparent member 90 is formed from a resin material having transmittance of 80% or greater. Preferably, the transparent member 90 is formed from a resin material having transmittance greater than 80%. More specifically, the transparent member 90 is formed from a resin material having transmittance greater than 80% to light having a wavelength of 400 nm or greater. The transparent member 90 is formed from, for example, a transparent epoxy resin, polycarbonate resin, or acrylic resin. The linear expansion coefficient of the transparent member 90 is greater than the linear expansion coefficient of the substrate 20. In the present embodiment, the transparent member 90 includes an epoxy resin. The linear expansion coefficient of the epoxy resin is approximately 64 ppm/° C. The glass-transition temperature is, for example, approximately 120° C.

The encapsulation resin 100 is formed from an electrically insulative, light-blocking material. In an example, the encapsulation resin 100 is formed from a material having a linear expansion coefficient that is greater than that of the substrate 20 and smaller than that of the transparent member 90. In other words, the encapsulation resin 100 is formed from a material having a linear expansion coefficient such that the difference in linear expansion coefficient between the encapsulation resin 100 and the substrate 20 is less than the difference in linear expansion coefficient between the transparent member 90 and the substrate 20. Preferably, in an example, the linear expansion coefficient of the encapsulation resin 100 is less than or equal to 20 ppm/° C. In an example, the linear expansion coefficient of the encapsulation resin 100 is approximately 20 ppm/° C. The linear expansion coefficient of the encapsulation resin 100 may be less than or equal to the linear expansion coefficient of the substrate 20. In the present embodiment, the encapsulation resin 100 is formed from a black epoxy resin. The encapsulation resin 100 includes filler. An example of the filler is silica (SiO₂). Thus, the encapsulation resin 100 has a higher glass-transition temperature than the transparent member 90. The glass-transition temperature of the encapsulation resin 100 is, for example, greater than or equal to 150° C. and less than or equal to 200° C.

Circuit Configuration of Semiconductor Light Emitting Device

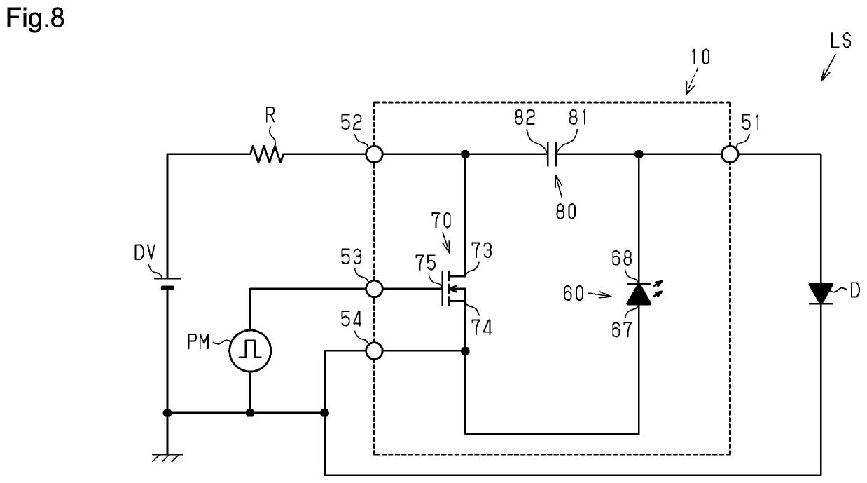

The circuit configuration of the semiconductor light emitting device 10, described above, will now be described with reference to FIG. 8. FIG. 8 is a circuit configuration of a laser system LS in which the semiconductor light emitting device 10 is used.

As shown in FIG. 8, the laser system LS includes the semiconductor light emitting device 10, a drive power supply DV, a current limiting resistor R, a diode D, and a driver circuit PM. The drive power supply DV is a direct current power supply having a positive electrode and a negative electrode and supplies electric power to the semiconductor light emitting device 10. The current limiting resistor R is disposed between the positive electrode of the drive power supply DV and the semiconductor light emitting device 10 to limit current flowing from the drive power supply DV to the semiconductor light emitting device 10. The diode D is connected in antiparallel to the semiconductor light emitting element 60 to prevent a reverse flow of current to the semiconductor light emitting element 60. In an example, the diode D is a Schottky diode. The driver circuit PM transmits a control signal for controlling activation and deactivation of the switching element 70 to the control electrode 75 of the switching element 70. In an example, the driver circuit PM is a square wave oscillation circuit that generates a pulse control signal.

The semiconductor light emitting element 60 is connected in series to the switching element 70. More specifically, the first electrode 67 (anode electrode) of the semiconductor light emitting element 60 is electrically connected to the second drive electrode 74 (source electrode) of the switching element 70. The first drive electrode 73 (drain electrode) of the switching element 70 is electrically connected to the power supply electrode 52. The second electrode 68 (cathode electrode) of the semiconductor light emitting element 60 is electrically connected to the connection electrode 51.

The capacitor 80 is connected in parallel to the semiconductor light emitting element 60 and the switching element 70 that are connected in series. More specifically, the first terminal 81 of the capacitor 80 is electrically connected to the second electrode 68 of the semiconductor light emitting element 60. The second terminal 82 of the capacitor 80 is electrically connected to the first drive electrode 73 of the switching element 70.

The second drive electrode 74 of the switching element 70 is electrically connected to the ground electrode 54. The diode D includes an anode electrode electrically connected to the connection electrode 51. The diode D includes a cathode electrode connected to the ground electrode 54. Thus, the diode D is connected in antiparallel to the semiconductor light emitting element 60.

The control electrode 75 of the switching element 70 is electrically connected to the control electrode 53. The driver circuit PM is electrically connected to the control electrode 53. Thus, the driver circuit PM is electrically connected to the control electrode 75 of the switching element 70. The driver circuit PM and the drive power supply DV each have a negative electrode connected to ground.

The laser system LS having the above configuration operates as follows. When the switching element 70 is switched off by a control signal of the driver circuit PM, the drive power supply DV stores power in the capacitor 80. When the switching element 70 is switched on by a control signal of the driver circuit PM, the capacitor 80 is discharged so that a current flows to the semiconductor light emitting element 60. As a result, the semiconductor light emitting element 60 outputs a pulse laser beam.

Manufacturing Method of Semiconductor Light Emitting Device

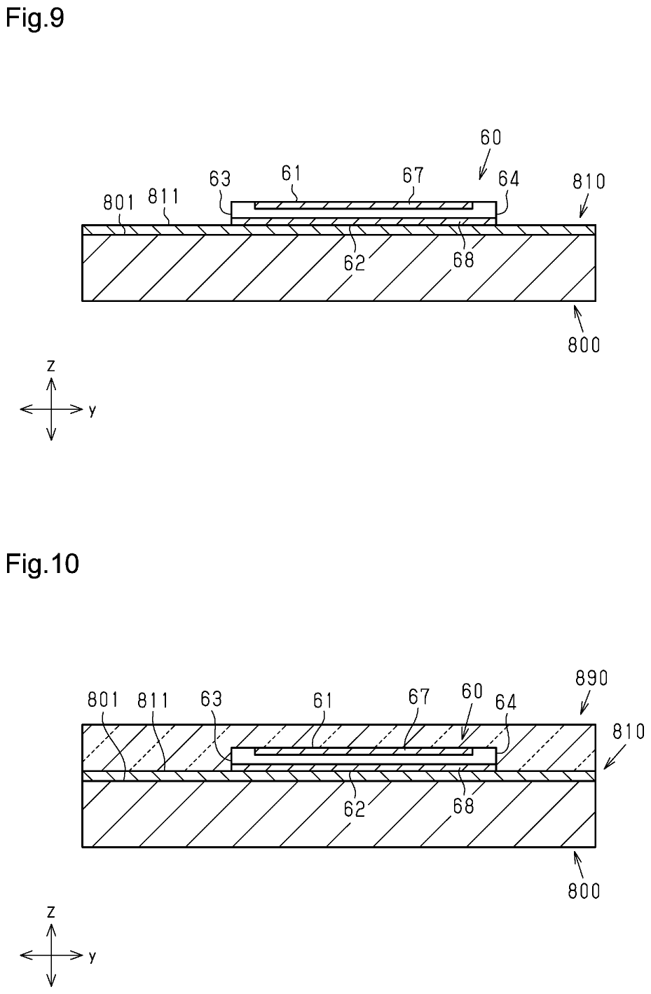

An example of a method for manufacturing the semiconductor light emitting device 10 will now be described with reference to FIGS. 9 to 17.

The method for manufacturing the semiconductor light emitting device 10 includes, for example, a transparent member forming step, an element mounting step, a wire forming step, a resin layer forming step, and a mirror-finishing step. In the present embodiment, the transparent member forming step, the element mounting step, the wire forming step, the resin layer forming step, and the mirror-finishing step are performed in order.

The transparent member forming step, which forms a transparent member integrally with the semiconductor light emitting element 60, includes a light emitting element mounting step, a transparent layer forming step, a support substrate removing step, an opening forming step, and a cutting step. In the present embodiment, the light emitting element mounting step, the transparent layer forming step, the support substrate removing step, the opening forming step, and the cutting step are performed in order.

In the light emitting element mounting step, as shown in FIG. 9, a flat support substrate 800 having a thickness-wise direction conforming to the z-direction is prepared. The support substrate 800 is formed of a resin substrate or a metal substrate and includes a substrate main surface 801 facing one side in the thickness-wise direction of the support substrate 800. Element mounting tape 810 is applied to the substrate main surface 801. The tape 810 includes a tape main surface 811 facing the same direction as the substrate main surface 801. The semiconductor light emitting element 60 is mounted on the tape main surface 811. In this case, the light emitting element back surface 62 of the semiconductor light emitting element 60 is in contact with the tape main surface 811.

In the transparent layer forming step, as shown in FIG. 10, a transparent layer 890 is formed on the tape main surface 811. In an example, the transparent layer 890 is formed on the entirety of the tape main surface 811. The transparent layer 890 encapsulates the semiconductor light emitting element 60. The transparent layer 890 is formed from an electrically insulative, light-transmissive material. The transparent layer 890 corresponds to the transparent member 90 and is formed from the same material as that of the transparent member 90. In an example, the transparent layer 890 is formed from a transparent epoxy resin. Since the transparent layer 890 is formed on the tape main surface 811, the light emitting element back surface 62 of the semiconductor light emitting element 60 is not covered by the transparent layer 890. The transparent layer 890 is formed through, for example, compression molding or transfer molding.

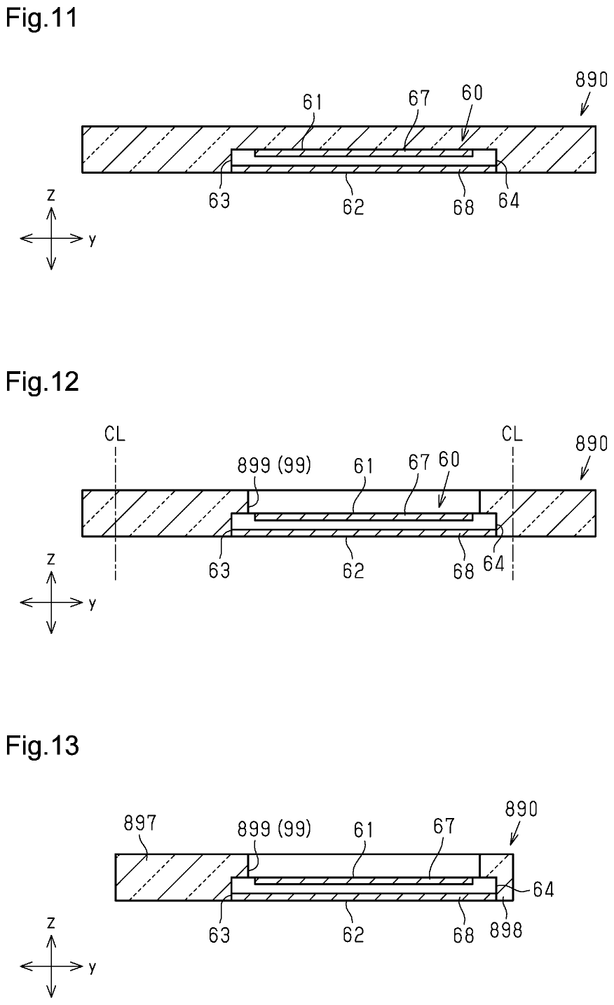

In the support substrate removing step, as shown in FIG. 11, the support substrate 800 and the tape 810 are removed from the semiconductor light emitting element 60 and the transparent layer 890. The process for removing the support substrate 800 and the tape 810 uses a debonding device to remove the support substrate 800 and the tape 810 from the semiconductor light emitting element 60 and the transparent layer 890. Alternatively, the support substrate 800 and the tape 810 may be removed by mechanical grinding. As a result, the light emitting element back surface 62 of the semiconductor light emitting element 60 is exposed from the transparent layer 890 in the z-direction. The light emitting element back surface 62 is flush with a surface of the transparent layer 890 that faces the same direction as the light emitting element back surface 62.

In the opening forming step, as shown in FIG. 12, an opening 899 is formed in the transparent layer 890. The opening 899 corresponds to the opening 99 of the transparent member 90. More specifically, the light emitting element main surface 61 of the semiconductor light emitting element 60 is exposed from the opening 899 in the z-direction. The opening 899 is formed by, for example, laser cutting.

In the cutting step, the transparent layer 890 is cut in the z-direction. More specifically, as shown in FIG. 12, for example, a dicing blade is used to cut the transparent layer 890 along cutting lines CL indicated by single-dashed lines. As shown in FIG. 13, the transparent layer 890 includes a transparent portion 897 and a covering portion 898. The transparent portion 897 is larger in dimension in the y-direction than the covering portion 898. The transparent portion 897 is also larger in the dimension in the y-direction than the transparent portion 97 of the transparent member 90. The covering portion 898 is equal in the dimension in the y-direction to the cover portion 98 of the transparent member 90.

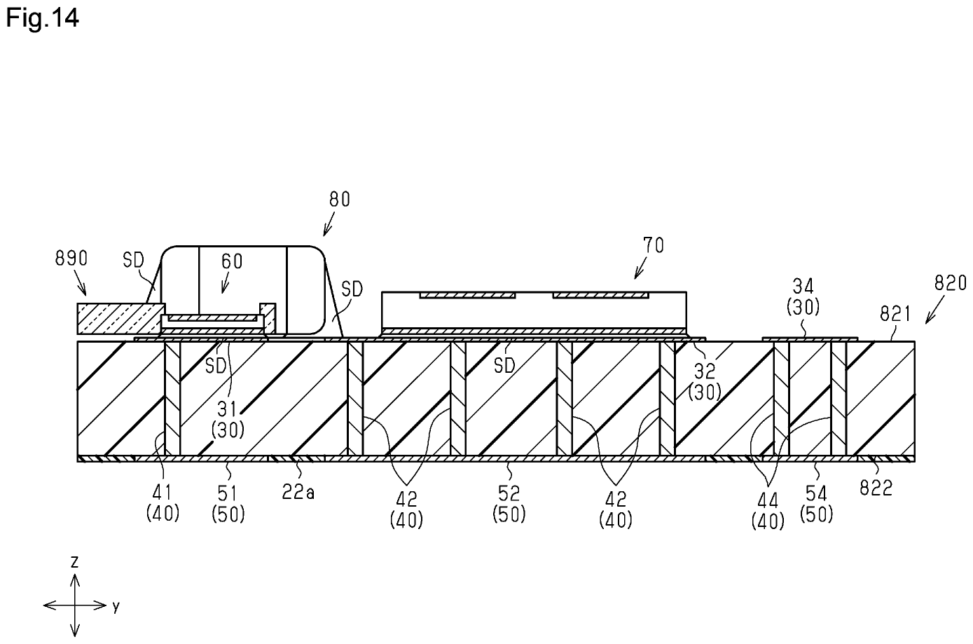

In the element mounting step, as shown in FIG. 14, a substrate 820 is prepared. The substrate 820 corresponds to the substrate 20 of the semiconductor light emitting device 10. Therefore, the substrate 820 includes a substrate main surface 821, on which the first main surface wiring line 31, the second main surface wiring line 32, the third main surface wiring line 33 (not shown), and the fourth main surface wiring line 34 are formed. The substrate 820 includes a substrate back surface 822, on which the connection electrode 51, the power supply electrode 52, the control electrode 53 (not shown), and the ground electrode 54 are formed. In addition, the first connection wiring lines 41, the second connection wiring lines 42, the third connection wiring lines 43 (not shown), and the fourth connection wiring line 44 are formed in the substrate 820.

The switching element 70, the capacitors 80, and the semiconductor light emitting element 60, which is integrated with the transparent layer 890, are mounted on the substrate main surface 821 of the substrate 820. In an example, die bonding is performed so that the semiconductor light emitting element 60 is mounted on the first main surface wiring line 31 via the conductive bonding material SD, the switching element 70 is mounted on the second main surface wiring line 32 via the conductive bonding material SD, and the capacitors 80 are mounted on the wiring lines 31 and 32 via the conductive bonding material SD.

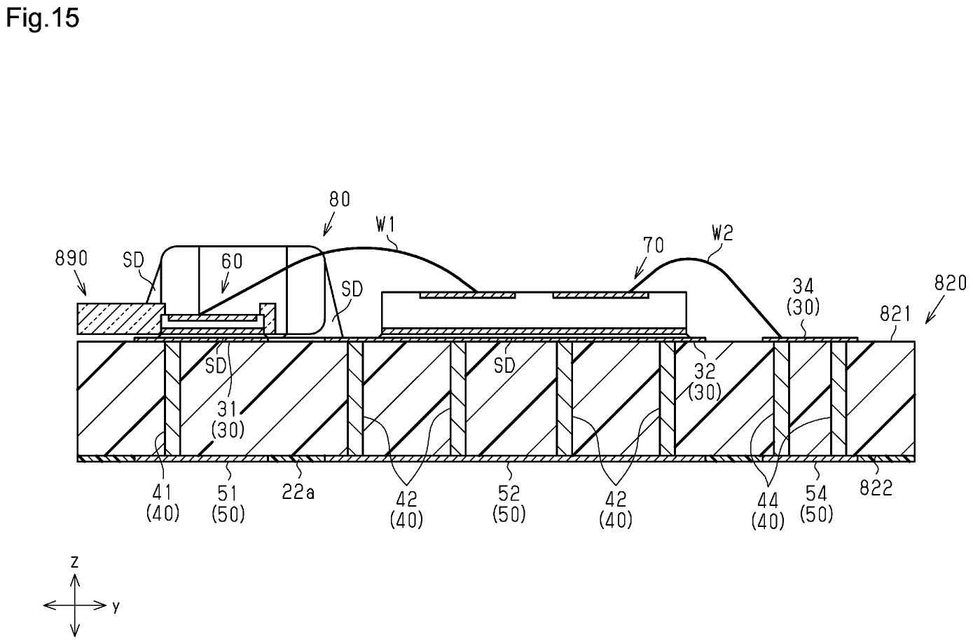

In the wire forming step, a wire bonding device forms one or more (in the present embodiment, four) first wires W1, one or more (in the present embodiment, two) second wires W2, and one third wire W3. FIG. 15 shows the first wires W1 and the second wires W2.

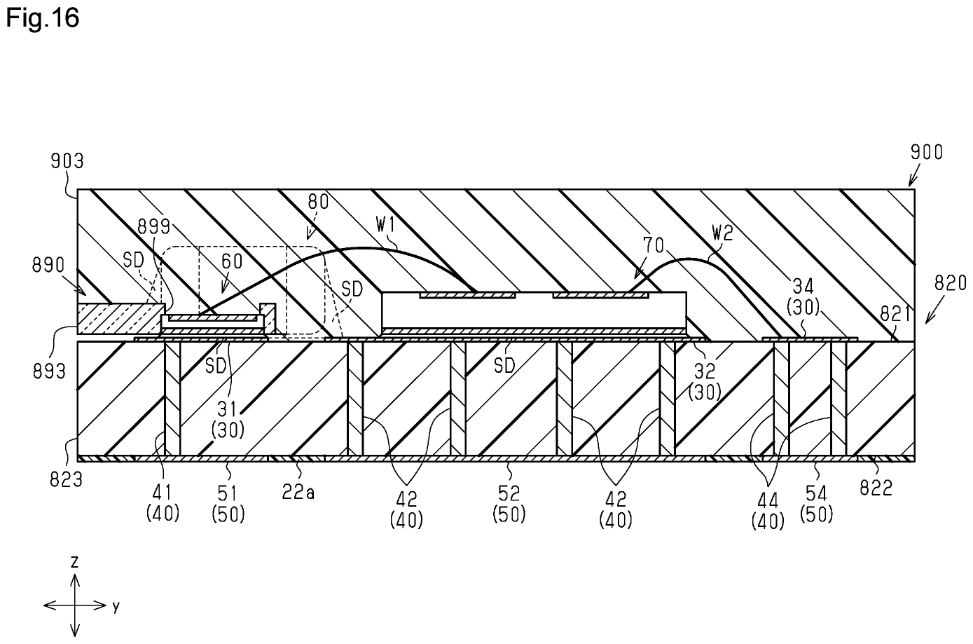

In the resin layer forming step, as shown in FIG. 16, a resin layer 900 is formed on the substrate main surface 21. The resin layer 900 corresponds to the encapsulation resin 100. The resin layer 900 is formed from an electrically insulative, light-blocking material. In the present embodiment, the resin layer 900 is formed from a black epoxy resin. The resin layer 900 encapsulates the switching element 70, the capacitor 80, the wires W1 to W3, and the semiconductor light emitting element 60, which is integrated with the transparent layer 890. In other words, the resin layer 900 encapsulates the transparent layer 890 together with the semiconductor light emitting element 60 and the drive element. The resin layer 900 encapsulates the second wires W2 together with the semiconductor light emitting element 60 and the drive element. The resin layer 900 encapsulates the third wire W3 together with the semiconductor light emitting element 60 and the drive element. In the present embodiment, the drive element includes the switching element 70 and the capacitors 80. The resin layer 900 is formed through, for example, transfer molding or compression molding. In this case, the transparent layer 890 includes a transparent side surface 893 facing the same direction as the substrate side surface 23. The transparent side surface 893 is not covered by the resin layer 900. The resin layer 900 is formed to fill the opening 899 of the transparent layer 890. Thus, the resin layer 900 encapsulates the first wires W1 together with the semiconductor light emitting element 60 and the drive element.

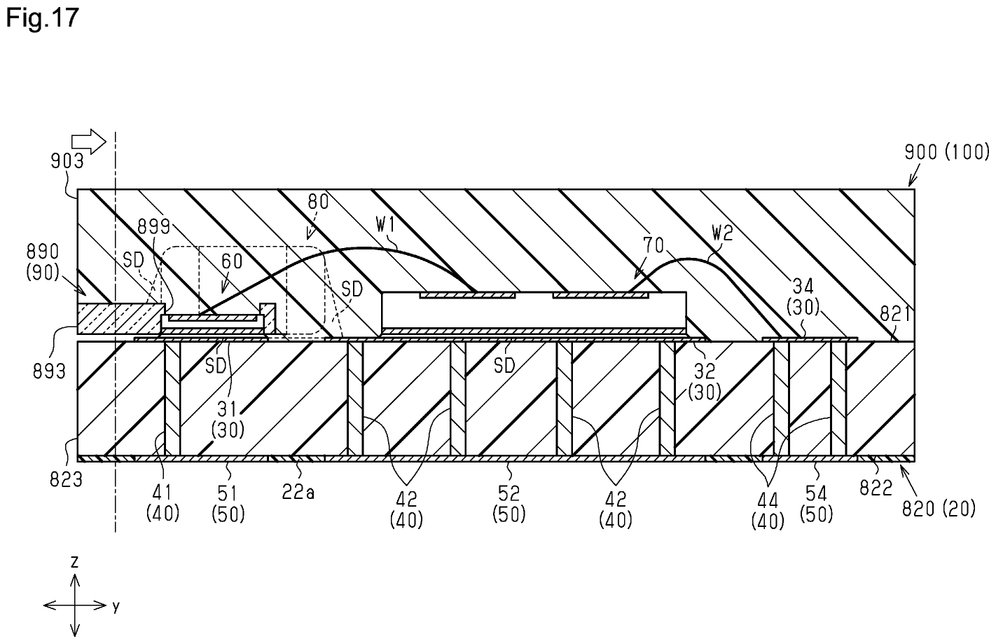

In the mirror-finishing step, as shown in FIG. 17, a mirror polishing machine is used to polish a resin side surface 903 of the resin layer 900, a transparent side surface 893 of the transparent layer 890, and a substrate side surface 823 of the substrate 820. The resin side surface 903 is a surface of the resin layer 900 facing the same direction as the transparent side surface 893. In the mirror-finishing step, for example, the resin layer 900, the transparent layer 890, and the substrate 820 are polished to the position indicated by a single-dashed line. This forms the encapsulation resin 100, the transparent member 90, and the substrate 20. The resin side surface 103 of the encapsulation resin 100, the transparent side surface 93 of the transparent member 90, and the substrate side surface 23 of the substrate 20 each become a mirror-finished smooth surface. Thus, the transparent side surface 93 is flatter than the transparent side surfaces 94 to 96. In an example, when the transparent side surface 93 has a smaller surface roughness than the transparent side surfaces 94 to 96, it is considered that the transparent side surface 93 is flatter than the transparent side surfaces 94 to 96. The surface roughness may be expressed by, for example, arithmetic average roughness (Ra). The steps described above manufacture the semiconductor light emitting device 10.

Operation

The operation of the semiconductor light emitting device 10 of the present embodiment will now be described. In a comparative example of a semiconductor light emitting device, the encapsulation resin 100 is omitted from the semiconductor light emitting device 10, and the transparent member 90 covers the semiconductor light emitting element 60, the switching element 70, the capacitors 80, and the wires W1 to W3.

The inventors of the present application conducted a thermal shock test on the semiconductor light emitting device of the comparative example. In the thermal shock test, the temperature is increased from −40° C. to 150° C. and decreased from 150° C. to −40° C. in one cycle. The test was performed for 100 cycles. The result shows an excessive stress was produced in the semiconductor light emitting device of the comparative example. In an example, an excessive load was applied to the wires W1 to W3 and the switching element 70. In addition, the thermal shock test was performed on a number of semiconductor light emitting devices of the comparative example. In some of the semiconductor light emitting devices, the second wires W2 were separated from the fourth main surface wiring line 34, and the third wire W3 was separated from the third main surface wiring line 33.

From the results, it is considered that the production of excessive stress in the semiconductor light emitting device of the comparative example, in other words, the application of excessive load to the wires W1 to W3 and the switching element 70, is caused by thermal expansion and contraction of the substrate 20 and the transparent member 90 due to the linear expansion coefficient of the transparent member 90 being larger than the linear expansion coefficient of the substrate 20 and the difference in linear expansion coefficient being significant between the substrate 20 and the transparent member 90. In particular, as in the semiconductor light emitting element of the comparative example, when a drive element used to drive the semiconductor light emitting element 60 is mounted on the substrate main surface 21 in addition to the semiconductor light emitting element 60, the semiconductor light emitting device will be increased in size as compared to when only the semiconductor light emitting element 60 is mounted on the substrate main surface 21. Accordingly, the encapsulation resin 100 will be increased in size. This increases the effect of the thermal expansion and contraction of the encapsulation resin 100 on the wires W1 to W3 and the switching element 70.

In this regard, it is desirable that the wires W1 to W3 and the switching element 70 be encapsulated by a material having a smaller linear expansion coefficient than the transparent member 90, that is, a material having a linear expansion coefficient that is closer to that of the substrate 20 than that of the transparent member 90.

Hence, in the semiconductor light emitting device 10 of the present embodiment, the transparent member 90 covers only the semiconductor light emitting element 60. The wires W1 to W3 and the switching element 70 are encapsulated by the encapsulation resin 100, which has a smaller linear expansion coefficient than the transparent member 90. This reduces the difference in the linear expansion coefficient between the substrate 20 and the encapsulation resin 100, thereby reducing stress produced in the semiconductor light emitting device 10 by the difference in linear expansion coefficient. In other words, the load applied to the wires W1 to W3 and the switching element 70 is reduced.

Advantages

The semiconductor light emitting device 10 of the present embodiment has the following advantages.

(1-1) The semiconductor light emitting device 10 includes the substrate 20, the semiconductor light emitting element 60 mounted on the substrate main surface 21 of the substrate 20, the drive element mounted on the substrate main surface 21 and used to drive the semiconductor light emitting element 60, the transparent member 90 covering the light emitting element side surface 63 of the semiconductor light emitting element 60, and the encapsulation resin 100 formed from a material having a smaller linear expansion coefficient than that of the transparent member 90 and encapsulating the semiconductor light emitting element 60 and the drive element.

In this structure, the encapsulation resin 100, which encapsulates the semiconductor light emitting element 60 and the drive element, is formed from a material having a smaller linear expansion coefficient than the material of the transparent member 90. Thus, the difference in linear expansion coefficient between the encapsulation resin 100 and the substrate 20 is less than the difference in linear expansion coefficient between the transparent member 90 and the substrate 20. Accordingly, the differences in thermal expansion amount and thermal contraction amount between the encapsulation resin 100 and the substrate 20 are less than those between the transparent member 90 and the substrate 20 caused by changes in the temperature of the semiconductor light emitting device 10. This results in reduction in the stress produced in the semiconductor light emitting device 10 caused by changes in the temperature of the semiconductor light emitting device 10.

(1-2) The transparent member 90 includes the opening 99, from which the first electrode 67 is exposed. The first electrode 67 is the main surface electrode disposed on the light emitting element main surface 61 of the semiconductor light emitting element 60. The first wires W1 are connected to the first electrode 67 through the opening 99. The encapsulation resin 100 fills the opening 99.

In this structure, the first wires W1 are entirely encapsulated by the encapsulation resin 100. This reduces the load on the first wires W1 caused by changes in the temperature of the semiconductor light emitting device 10.

(1-3) The encapsulation resin 100 encapsulates the transparent member 90. The transparent member 90 includes the transparent side surface 93, which is the transparent surface exposed from the resin side surface 103.

In this structure, the semiconductor light emitting element 60, which is encapsulated by the transparent member 90, is also encapsulated by the encapsulation resin 100. Therefore, the semiconductor light emitting element 60 is protected further assuredly. In addition, although the transparent member 90 is encapsulated by the encapsulation resin 100, light emitted from the light emitting element side surface 63, which is the light emitting surface of the semiconductor light emitting element 60, is transmitted to the outside of the semiconductor light emitting device 10 through the transparent member 90.

(1-4) The transparent side surface 93 (transparent surface) of the transparent member 90 is flush with the resin side surface 103 and the substrate side surface 23. Each of the transparent side surface 93, the resin side surface 103, and the substrate side surface 23 is a mirror-finished smooth surface.

In this structure, the transparent side surface 93, which is a smooth surface, limits diffusion of light emitted from the semiconductor light emitting element 60 when transmitting through the transparent side surface 93. This limits decreases in the optical output of the semiconductor light emitting device 10.

(1-5) The drive element includes the switching element 70. The second drive electrode 74, which corresponds to a drive electrode, is disposed on the switching element main surface 71 of the switching element 70. The fourth main surface wiring line 34, which is the main surface drive wiring line electrically connected to the second drive electrode 74, is disposed on the substrate main surface 21 of the substrate 20. The second wires W2 connect the second drive electrode 74 and the fourth main surface wiring line 34.

In this structure, the switching element 70, the fourth main surface wiring line 34, and the second wires W2 are encapsulated by the encapsulation resin 100. Thus, the load on the second wires W2 caused by changes in the temperature of the semiconductor light emitting device 10 is reduced. This limits separation of the second wires W2 from the fourth main surface wiring line 34 and deformation of the switching element 70.

(1-6) The drive element includes the switching element 70. The control electrode 75 is disposed on the switching element main surface 71 of the switching element 70. The third main surface wiring line 33, which is the main surface control wiring line electrically connected to the control electrode 75, is disposed on the substrate main surface 21 of the substrate 20. The third wire W3 connects the control electrode 75 and the third main surface wiring line 33.

In this structure, the switching element 70, the third main surface wiring line 33, and the third wire W3 are encapsulated by the encapsulation resin 100. Thus, the load on the third wire W3 caused by changes in the temperature of the semiconductor light emitting device 10 is reduced. This limits separation of the third wire W3 from the third main surface wiring line 33 and deformation of the switching element 70.

(1-7) The drive element includes the capacitor 80. The capacitor 80 is electrically connected to the semiconductor light emitting element 60 and the switching element 70.

In this structure, the area of a conductive loop, through which current sequentially flows through the capacitor 80, the switching element 70, and the semiconductor light emitting element 60, is smaller than that in a structure in which the capacitor 80 is disposed outside the semiconductor light emitting device 10. This reduces the inductance of a conductive path electrically connecting the capacitor 80, the switching element 70, and the semiconductor light emitting element 60.

(1-8) The distance HA between the substrate main surface 21 of the substrate 20 and the transparent main surface 91 of the transparent member 90 in the z-direction is shorter than the distance HC between the substrate main surface 21 and the capacitor main surface 83 of the capacitor 80 in the z-direction.

In this structure, the encapsulation resin 100 has a smaller volume than the transparent member 90. This limits deformation of the encapsulation resin 100 caused by the difference in linear expansion coefficient between the transparent member 90 and the encapsulation resin 100 when the temperature of the semiconductor light emitting device 10 changes. Thus, the load on each of the wires W1 to W3 and the switching element 70 caused by changes in the temperature of the semiconductor light emitting device 10 is reduced.

(1-9) The distance HA between the substrate main surface 21 of the substrate 20 and the transparent main surface 91 of the transparent member 90 in the z-direction is shorter than the distance HB between the substrate main surface 21 and the switching element main surface 71 of the switching element 70 in the z-direction.

In this structure, the encapsulation resin 100 has a smaller volume than the transparent member 90. This limits deformation of the encapsulation resin 100 caused by the difference in linear expansion coefficient between the transparent member 90 and the encapsulation resin 100 when the temperature of the semiconductor light emitting device 10 changes. Thus, the load on each of the wires W1 to W3 and the switching element 70 caused by changes in the temperature of the semiconductor light emitting device 10 is reduced.

(1-10) The switching element 70 is entirely covered by the encapsulation resin 100. The transparent member 90 is disposed on and around the semiconductor light emitting element 60 and covers the light emitting element side surface 63, which is the light emitting surface. The switching element 70 is spaced apart from the transparent member 90. The encapsulation resin 100 is disposed between the switching element 70 and the transparent member 90.

In this structure, the encapsulation resin 100 is disposed between the transparent member 90 and the switching element 70. This limits changes in the distance between the semiconductor light emitting element 60 and the switching element 70 resulting from changes in the volume of the transparent member 90 in accordance with changes in the temperature of the semiconductor light emitting device 10. Thus, the load on each of the wires W1 to W3 and the switching element 70 caused by changes in the temperature of the semiconductor light emitting device 10 is reduced.

(1-11) Each capacitor 80 is entirely covered by the encapsulation resin 100. The transparent member 90 is disposed on and around the semiconductor light emitting element 60 and covers the light emitting element side surface 63, which is the light emitting surface. The capacitor 80 is spaced apart from the transparent member 90. The encapsulation resin 100 is disposed between the capacitor 80 and the transparent member 90.

In this structure, the encapsulation resin 100 is disposed between the transparent member 90 and each capacitor 80. This limits movement of the capacitor 80 caused by changes in the volume of the transparent member 90 in accordance with changes in the temperature of the semiconductor light emitting device 10.

(1-12) The light emitting element back surface 62 of the semiconductor light emitting element 60 is flush with the transparent back surface 92 of the transparent member 90.

This structure allows the coupled body of the semiconductor light emitting element 60 and the transparent member 90 to be readily mounted on the substrate main surface 21 so that the substrate main surface 21 of the substrate 20 is disposed parallel to the light emitting element back surface 62. Accordingly, the light emitting element side surface 63, or the light emitting surface of the semiconductor light emitting element 60, and the transparent side surface 93, or the transparent surface of the transparent member 90, are readily arranged perpendicular to the substrate main surface 21.

(1-13) The encapsulation resin 100 is configured to have a higher glass-transition temperature than the transparent member 90.

In this structure, the encapsulation resin 100 has a greater thermal resistance than the transparent member 90 and protects the wires W1 to W3, the switching element 70, and the capacitor 80 in a wider range of temperatures than the transparent member 90. Therefore, the semiconductor light emitting device 10 is used in the wider range of temperatures.

(1-14) The external electrodes 50 are disposed on the substrate back surface 22 of the substrate 20 and separately electrically connected to the semiconductor light emitting element 60 and the switching element 70.

In this structure, the semiconductor light emitting device 10 has a package structure of a front surface mount type. Thus, the semiconductor light emitting device 10 is reduced in size in a direction orthogonal to the z-direction as compared to, for example, in a structure including a lead frame projecting sideward from the substrate 20.

(1-15) The substrate 20 includes the connection wiring lines 40 extending through the substrate 20 in the z-direction. Thus, the connection wiring lines 40 electrically connect the semiconductor light emitting element 60 and the switching element 70 to the external electrodes 50.

This structure shortens the conductive path between the semiconductor light emitting element 60 and the external electrodes 50, the conductive path between the first drive electrode 73 of the switching element 70 and the external electrodes 50, the conductive path between the second drive electrode 74 of the switching element 70 and the external electrodes 50, and the conductive path between the control electrode 75 of the switching element 70 and the external electrodes 50. As a result, the inductance caused by the length of the conductive paths is reduced.

(1-16) The first electrode 67, or the main surface electrode formed on the light emitting element main surface 61 of the semiconductor light emitting element 60, is connected to the second drive electrode 74 of the switching element 70 by the first wires W1. This structure simplifies the electrical connection configuration of the first electrode 67 and the second drive electrode 74 and reduces the distance between the first electrode 67 and the second drive electrode 74 as compared to a structure in which the first electrode 67 is connected to the main surface wiring line formed on the substrate main surface 21 by a wire and the main surface wiring line is connected to the second drive electrode 74 by a wire as the electrical connection configuration of the first electrode 67 and the second drive electrode 74. As a result, the conductive path between the first electrode 67 and the second drive electrode 74 is shortened, and the inductance caused by the length of the conductive path is reduced.

(1-17) The drive element includes multiple (in the present embodiment, two) capacitors 80. The two capacitors 80 are aligned with each other in the y-direction and spaced apart from each other in the x-direction. The semiconductor light emitting element 60 is disposed between the two capacitors 80 in the x-direction.

In this structure, the semiconductor light emitting element 60 may be disposed in the center of the substrate main surface 21 in the x-direction. The semiconductor light emitting element 60 is aligned with the switching element 70 in the x-direction. Thus, the first electrode 67 of the semiconductor light emitting element 60 is readily connected to the second drive electrode 74 of the switching element 70 by the first wires W1.

(1-18) The second drive electrode 74 of the switching element 70 is connected to the ground electrode 54 by the second wires W2, the fourth main surface wiring line 34, and the fourth connection wiring line 44.

In this structure, when the ground electrode 54 is electrically connected to ground of the driver circuit PM, if the electrical potential of the second drive electrode 74 of the switching element 70 varies due to noise or the like, the electrical potential of the ground of the driver circuit PM follows and varies. This inhibits the gate-source voltage of the switching element 70 from becoming a negative value. This limits variations in the threshold voltage of the switching element 70.

(1-19) The method for manufacturing the semiconductor light emitting device 10 includes a step for encapsulating the semiconductor light emitting element 60 with the transparent layer 890, a step for mounting the semiconductor light emitting element 60, encapsulated by the transparent layer 890, and the drive element on the substrate main surface 821 of the substrate 820, and a step for forming the resin layer 900 to encapsulate the semiconductor light emitting element 60 and the drive element. The linear expansion coefficient of the transparent layer 890 is greater than the linear expansion coefficient of the substrate 820. The linear expansion coefficient of the resin layer 900 is smaller than the linear expansion coefficient of the transparent layer 890.

In this structure, the resin layer 900, which encapsulates the semiconductor light emitting element 60 and the drive element, is formed from a material having a smaller linear expansion coefficient than the transparent layer 890. Thus, the difference in linear expansion coefficient between the resin layer 900 and the substrate 820 is less than the difference in linear expansion coefficient between the transparent layer 890 and the substrate 820. Accordingly, the differences in thermal expansion amount and thermal contraction amount between the resin layer 900 and the substrate 820 are less than those between the transparent layer 890 and the substrate 820 caused by changes in the temperature of the semiconductor light emitting device 10. This results in reduction in the stress produced in the semiconductor light emitting device 10 caused by changes in the temperature of the semiconductor light emitting device 10.

(1-20) The method for manufacturing the semiconductor light emitting device 10 includes a step for mirror-finishing the resin side surface 903 of the resin layer 900, the substrate side surface 823 of the substrate 820, and the transparent side surface 893 of the transparent layer 890.

In this structure, this step forms the substrate 20, the encapsulation resin 100, and the transparent member 90 and also forms the substrate side surface 23, the resin side surface 103, and the transparent side surface 93. Thus, an advantage similar to the advantage (1-4) is obtained.

### Second Embodiment

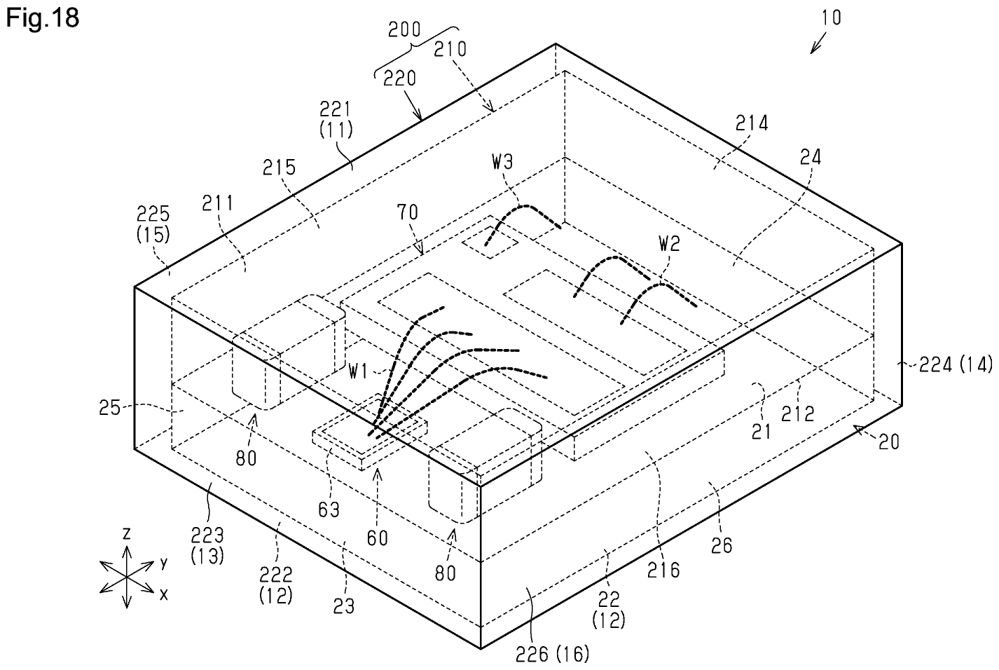

A second embodiment of a semiconductor light emitting device 10 will now be described with reference to FIGS. 18 to 27. The present embodiment of the semiconductor light emitting device 10 differs from the first embodiment of the semiconductor light emitting device 10 mainly in that a transparent member 200 is included instead of the transparent member 90 and the encapsulation resin 100 and the substrate 20 is a multilayer substrate. In the description below, the same reference characters are given to those components that are the same as the corresponding components of the first embodiment. Such components will not be described in detail.

Structure of Semiconductor Light Emitting Device

The structure of the semiconductor light emitting device 10 will now be described with reference to FIGS. 18 to 20. In FIG. 18, for the sake of convenience, the substrate 20, the semiconductor light emitting element 60, the switching element 70, the capacitor 80, the wires W1 to W3, and a first transparent member 210 are indicated by broken lines and disposed in a second transparent member 220, which will be described later.

As shown in FIG. 18, the semiconductor light emitting device 10 includes the transparent member 200. In an example, the transparent member 200 is formed from the same material as the transparent member 90. The transparent member 200 encapsulates the semiconductor light emitting element 60, the switching element 70, the capacitors 80, and the wires W1 to W3. The transparent member 200 also encapsulates the substrate 20. More specifically, the transparent member 200 covers the substrate main surface 21 and the substrate side surfaces 23 to 26. In other words, the transparent member 200 covers the substrate side surface 23, which is a light emitting-side substrate side surface facing the same direction as the light emitting element side surface 63. The light emitting element side surface 63 is the light emitting surface of the semiconductor light emitting element 60. In contrast, the transparent member 200 does not cover the substrate back surface 22.

As shown in FIG. 18, the transparent member 200 is rectangular-box-shaped. The transparent member 200 includes the first transparent member 210, which is disposed on the substrate main surface 21 of the substrate 20, and the second transparent member 220, which covers the first transparent member 210 and the substrate side surfaces 23 to 26 of the substrate 20. The first transparent member 210 and the second transparent member 220 are formed from the same material. The second transparent member 220 encapsulates the first transparent member 210.

The first transparent member 210 encapsulates the semiconductor light emitting element 60, the switching element 70, the capacitors 80, and the wires W1 to W3. In other words, the first transparent member 210 encapsulates the drive element used to drive the semiconductor light emitting element 60. In the present embodiment, the drive element includes the switching element 70 and the capacitor 80. In other words, the transparent member 200 encapsulates the drive element. As viewed in the z-direction, the first transparent member 210 is equal in size to the substrate 20.

The first transparent member 210 includes a first transparent main surface 211 and a first transparent back surface 212, which face opposite directions in the z-direction, and first transparent side surfaces 213 to 216, each of which faces a direction intersecting the first transparent main surface 211 and the first transparent back surface 212. The first transparent main surface 211 and the substrate main surface 21 of the substrate 20 face the same direction. The first transparent back surface 212 and the substrate back surface 22 face the same direction. The first transparent side surface 213 and the substrate side surface 23 face the same direction. The first transparent side surface 214 and the substrate side surface 24 face the same direction. The first transparent side surface 215 and the substrate side surface 25 face the same direction. The first transparent side surface 216 and the substrate side surface 26 face the same direction. In the present embodiment, the first transparent side surface 213 is flush with the substrate side surface 23. The first transparent side surface 214 is flush with the substrate side surface 24. The first transparent side surface 215 is flush with the substrate side surface 25. The first transparent side surface 216 is flush with the substrate side surface 26. In the present embodiment, the first transparent side surface 213 is an example of a first light emitting side surface facing the same direction as the light emitting element side surface 63, which is the light emitting surface of the semiconductor light emitting element 60.

The second transparent member 220 includes a second transparent main surface 221 and a second transparent back surface 222, which face opposite directions in the z-direction, and second transparent side surfaces 223 to 226, each of which faces a direction intersecting the second transparent main surface 221 and the second transparent back surface 222.

As shown in FIGS. 18 to 20, the second transparent main surface 221 faces the same direction as the first transparent main surface 211 and covers the first transparent main surface 211 from the z-direction. The second transparent back surface 222 faces the same direction as the substrate back surface 22 and is flush with the substrate back surface 22. The second transparent side surface 223 faces the same direction as the first transparent side surface 213 and the substrate side surface 23 and covers the first transparent side surface 213 and the substrate side surface 23 from the y-direction. The second transparent side surface 224 faces the same direction as the first transparent side surface 214 and the substrate side surface 24 and covers the first transparent side surface 214 and the substrate side surface 24 from the y-direction. The second transparent side surface 225 faces the same direction as the first transparent side surface 215 and the substrate side surface 25 and covers the first transparent side surface 215 and the substrate side surface 25 from the x-direction. The second transparent side surface 226 faces the same direction as the first transparent side surface 216 and the substrate side surface 26 and covers the first transparent side surface 216 and the substrate side surface 26 in the x-direction.

Thus, the surfaces 221 to 226 of the second transparent member 220 define the outer surfaces of the semiconductor light emitting device 10. More specifically, the second transparent main surface 221 defines the device main surface 11. The second transparent back surface 222 and the substrate back surface 22 of the substrate 20 define the device back surface 12. The second transparent side surface 223 defines the device side surface 13. The second transparent side surface 224 defines the device side surface 14. The second transparent side surface 225 defines the device side surface 15. The second transparent side surface 226 defines the device side surface 16. Thus, the second transparent side surface 223 defines a transparent surface that transmits light emitted from the semiconductor light emitting element 60.

As shown in FIGS. 18 to 20, the second transparent side surface 223 is a mirror-finished smooth surface. The second transparent side surfaces 224 to 226 are formed by dicing, which will be described later in detail. Each of the second transparent side surfaces 224 to 226 is an example of a diced side surface. The second transparent side surface 223 is flatter than the second transparent side surfaces 224 to 226. In an example, when the second transparent side surface 223 has a smaller surface roughness than the second transparent side surfaces 224 to 226, it is considered that the second transparent side surface 223 is flatter than the second transparent side surfaces 224 to 226. The surface roughness may be expressed by, for example, arithmetic average roughness (Ra).

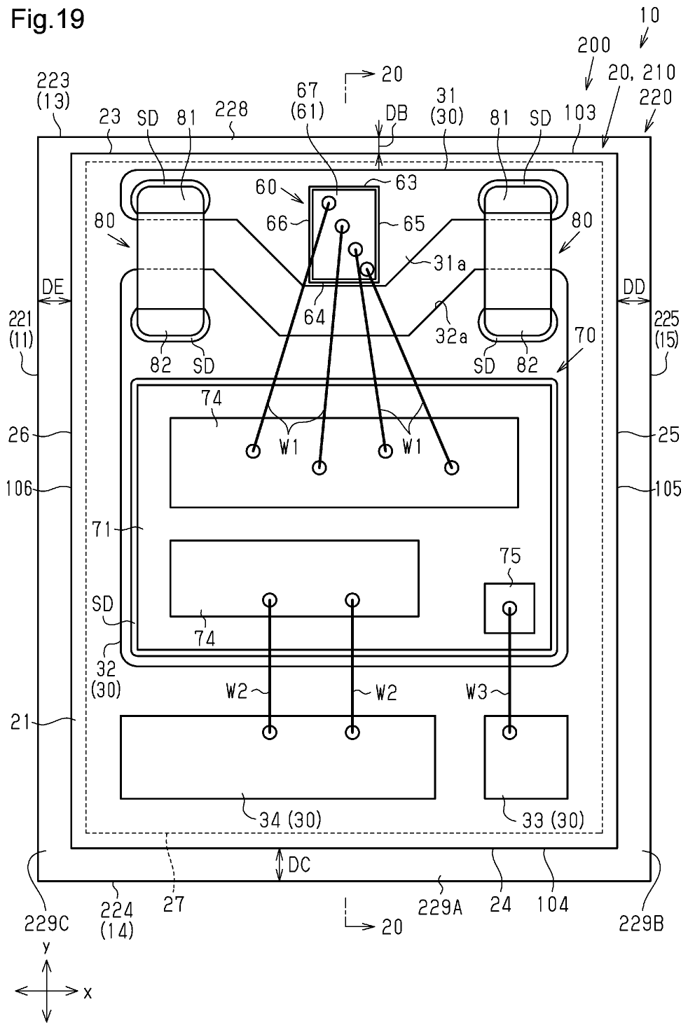

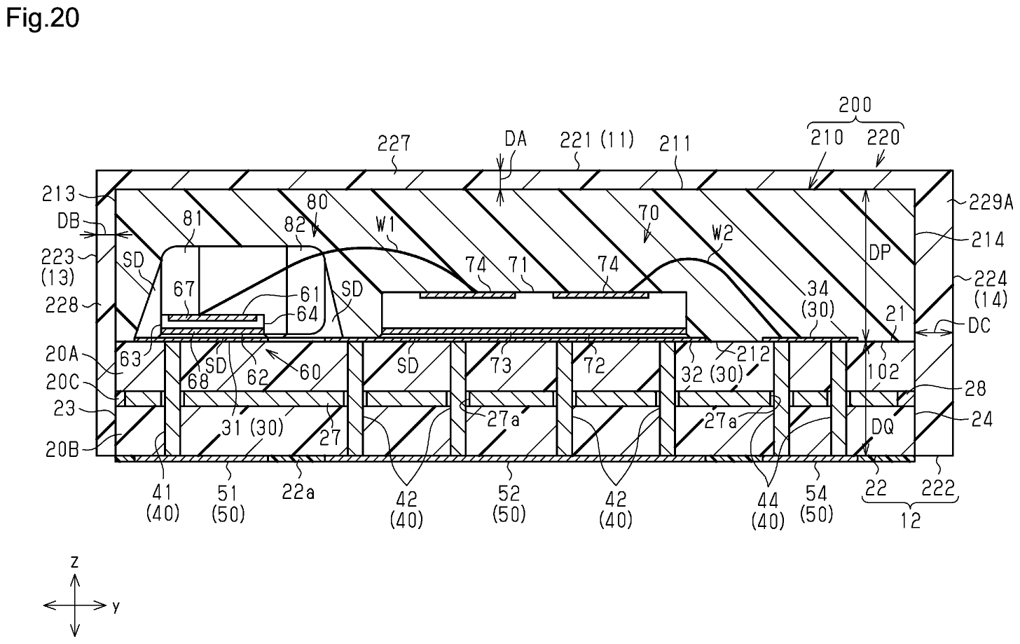

As shown in FIGS. 19 and 20, the second transparent member 220 includes a main surface cover 227 covering the first transparent main surface 211, a light emitting-side cover 228 covering the first transparent side surface 213 and the substrate side surface 23, a side surface cover 229A covering the first transparent side surface 214 and the substrate side surface 24, a side surface cover 229B covering the first transparent side surface 215 and the substrate side surface 25, and a side surface cover 229C covering the first transparent side surface 216 and the substrate side surface 26. In the present embodiment, the light emitting-side cover 228 covers the entire substrate side surface 23. The side surface cover 229A covers the entire substrate side surface 24. The side surface cover 229B covers the entire substrate side surface 25. The side surface cover 229C covers the entire substrate side surface 26.

As shown in FIG. 20, a thickness DA of the main surface cover 227 (dimension of the main surface cover 227 in the z-direction) is smaller than a thickness DP of the first transparent member 210 and a thickness DQ of the substrate 20. In the present embodiment, the thickness DA of the main surface cover 227 is smaller than the thickness DC of the side surface cover 229A (dimension of the side surface cover 229A in the y-direction), the thickness DD of the side surface cover 229B (dimension of the side surface cover 229B in the x-direction), and the thickness DE of the side surface cover 229C (dimension of the side surface cover 229C in the x-direction), which are shown in FIG. 19. In the present embodiment, the thicknesses DC, DD, and DE are equal to each other.

As shown in FIG. 19, the thickness DB of the light emitting-side cover 228 (dimension of the light emitting-side cover 228 in the y-direction) is smaller than the thickness DC of the side surface cover 229A, the thickness DD of the side surface cover 229B, and the thickness DE of the side surface cover 229C. In the present embodiment, the thickness DB of the light emitting-side cover 228 is equal to the thickness DA of the main surface cover 227.

The thicknesses DA to DE may be changed in any manner. In an example, the thickness DA may be equal to the thicknesses DC to DE. The thickness DB may be smaller than the thickness DA. The thicknesses DC to DE may differ from each other.

As shown in FIG. 20, in the present embodiment, the substrate 20 includes a multilayer substrate including multiple insulation layers and a conductive layer. In the present embodiment, the substrate 20 includes a main surface layer 20A including the substrate main surface 21 and serving as an insulation layer, a back surface layer 20B including the substrate back surface 22 and serving as an insulation layer, and an intermediate layer 20C disposed between the main surface layer 20A and the back surface layer 20B in the z-direction and serving as a conductive layer. In the present embodiment, the intermediate layer 20C is a single layer but is not limited to the single layer. The intermediate layer 20C may include multiple layers. That is, the substrate 20 may include four or more conductive layers.

The main surface layer 20A and the back surface layer 20B are formed from an electrically insulative material. In an example, a glass-epoxy resin is used as the electrically insulative material. In the same manner as the first embodiment, the main surface wiring lines 30, which are conductive layers, are disposed on the surface (substrate main surface 21) of the main surface layer 20A. In the same manner as the first embodiment, the external electrodes 50, which are conductive layers, are disposed on the surface (substrate back surface 22) of the back surface layer 20B.

The intermediate layer 20C is in contact with the main surface layer 20A and the back surface layer 20B. In the present embodiment, the thickness of the intermediate layer 20C is smaller than the thickness of the main surface layer 20A and the thickness of the back surface layer 20B. The intermediate layer 20C includes a metal layer 27 and an insulation layer 28.

In an example, the metal layer 27 is formed from Cu. As viewed in the z-direction, the metal layer 27 is disposed to overlap the semiconductor light emitting element 60. As viewed in the z-direction, the metal layer 27 is disposed to overlap the switching element 70. In the present embodiment, as shown in FIG. 19, as viewed in the z-direction, the metal layer 27 is disposed to overlap substantially the entirety of the substrate main surface 21 and the substrate back surface 22. As viewed in the z-direction, the metal layer 27 is rectangular such that the short sides extend in the x-direction and the long sides extend in the y-direction. The peripheral edge of the metal layer 27 is slightly smaller than the peripheral edge of the substrate main surface 21 and the peripheral edge of the substrate back surface 22. That is, the metal layer 27 is located inward from the substrate side surfaces 23 to 26. Thus, as viewed in the z-direction, the metal layer 27 is disposed to overlap the main surface wiring lines 30, the wires W1 to W3, the semiconductor light emitting element 60, the switching element 70, and the capacitors 80.

As shown in FIG. 20, through holes 27a extend through the metal layer 27 to separate the metal layer 27 from the connection wiring lines 40. The through holes 27a extend through the metal layer 27 in the z-direction.

The insulation layer 28 is formed from an electrically insulative material. In an example, a glass-epoxy resin is used as the electrically insulative material. Preferably, the insulation layer 28 is formed from the same material as the main surface layer 20A and the back surface layer 20B. The insulation layer 28 is disposed to surround the metal layer 27 and defines a peripheral edge of the intermediate layer 20C. That is, the insulation layer 28 defines the substrate side surfaces 23 to 26 of the intermediate layer 20C.

The intermediate layer 20C may also be disposed between the connection wiring line 40 and an inner surface of the metal layer 27 defining the through hole 27a. As a result, the metal layer 27 is readily electrically insulated from the connection wiring lines 40.

Manufacturing Method of Semiconductor Light Emitting Device

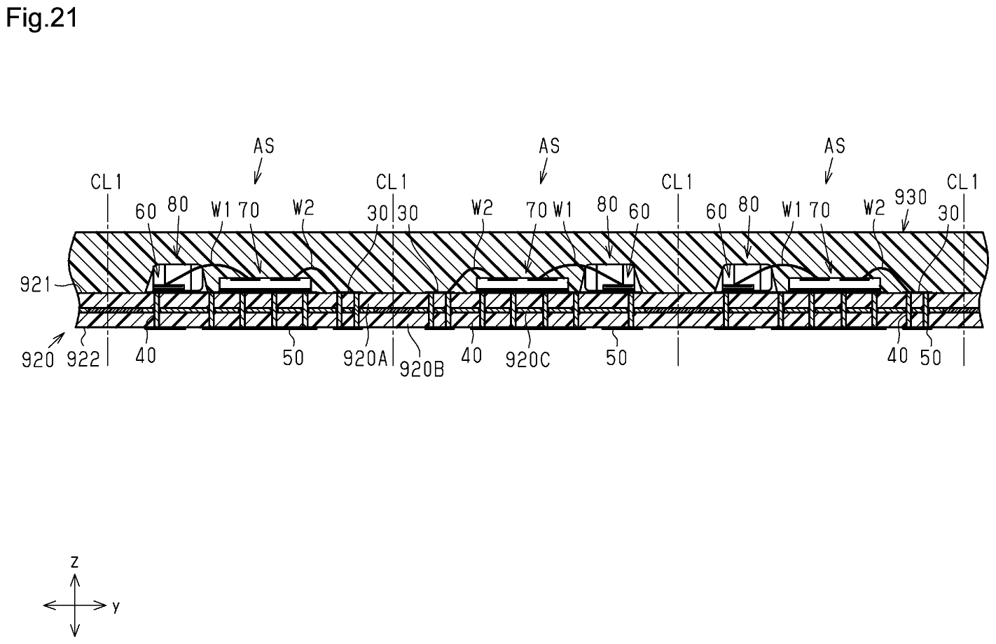

An example of a method for manufacturing the semiconductor light emitting device 10 will now be described with reference to FIGS. 21 to 27.

The method for manufacturing the semiconductor light emitting device 10 of the present embodiment includes the element mounting step, the wire forming step, a first transparent layer forming step, a first cutting step, a second transparent layer forming step, a second cutting step, and the mirror-finishing step. In the present embodiment, the element mounting step, the wire forming step, the first transparent layer forming step, the first cutting step, the second transparent layer forming step, the second cutting step, and the mirror-finishing step are performed in order.

In the element mounting step, as shown in FIG. 21, a substrate 920 is prepared. The substrate 920 is a member including multiple substrates 20. The substrate 920 includes a substrate main surface 921 and a substrate back surface 922 facing opposite directions in the z-direction. The main surface wiring lines 30 are formed on the substrate main surface 921. The external electrodes 50 are formed on the substrate back surface 922. The connection wiring lines 40 are formed in the substrate 920 and extend through the substrate 920 in the z-direction.

The substrate 920 has a multilayer structure in which multiple layers are stacked in the thickness-wise direction (the z-direction) of the substrate 920. The substrate 920 includes a main surface layer 920A including the substrate main surface 921, a back surface layer 920B including the substrate back surface 922, and an intermediate layer 920C disposed between the main surface layer 920A and the back surface layer 920B in the z-direction. The main surface layer 920A corresponds to the main surface layer 20A of the substrate 20. The back surface layer 920B corresponds to the back surface layer 20B of the substrate 20. The intermediate layer 920C corresponds to the intermediate layer 20C of the substrate 20.

Then, the semiconductor light emitting element 60, the switching element 70, and the capacitors 80 are mounted on the substrate main surface 921 of the substrate 920. The semiconductor light emitting element 60, the switching element 70, and the capacitors 80 are mounted in the same process as those of the first embodiment.

In the wire forming step, the first wires W1, the second wires W2, and the third wire W3 are formed. The wires W1 to W3 are formed in the same process as those of the first embodiment. FIG. 21 shows the first wires W1 and the second wires W2.

In the first transparent layer forming step, as shown in FIG. 21, a first transparent layer 930 is formed on the substrate main surface 921. The first transparent layer 930 includes the first transparent member 210 and is formed from a light-transmissive material. More specifically, the first transparent layer 930 is formed from a clear resin material. Examples of the clear resin material include an epoxy resin, a polycarbonate resin, and an acrylic resin. The first transparent layer 930 encapsulates the semiconductor light emitting element 60. In the present embodiment, the first transparent layer 930 encapsulates the semiconductor light emitting elements 60, the switching elements 70, the capacitors 80, and the wires W1 to W3.

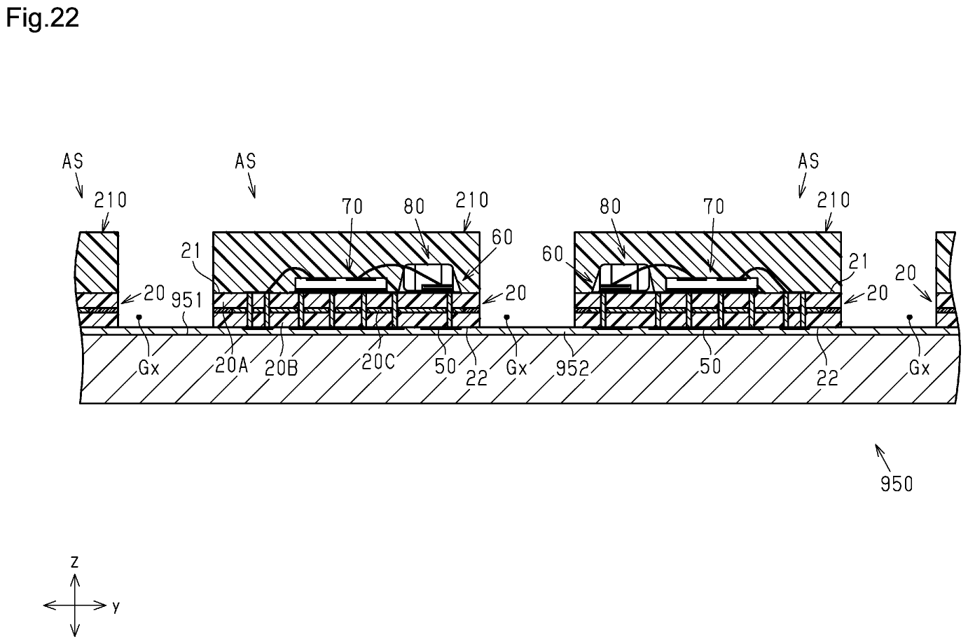

In the first cutting step, for example, a dicing blade is used to cut the first transparent layer 930 and the substrate 920 in the z-direction. More specifically, the first transparent layer 930 and the substrate 920 are cut along cutting lines CL1 shown in FIG. 21. Consequently, as shown in FIG. 22, the substrate 20 and the first transparent member 210 are formed. More specifically, the first cutting step singulates a semiconductor light emitting assembly (hereafter, referred to as “assembly AS”) that includes the substrate 20, the semiconductor light emitting element 60 mounted on the substrate main surface 21, the switching element 70, and multiple (in the present embodiment, two) capacitors 80, the wires W1 to W3, and the first transparent member 210. In the assembly AS, the first transparent member 210 encapsulates the semiconductor light emitting element 60 mounted on the substrate main surface 21 of the substrate 20, the switching element 70, multiple (in the present embodiment, two) capacitors 80, and the wires W1 to W3. As described above, a plurality of assemblies AS is prepared by the element mounting step, the wire forming step, the first transparent layer forming step, and the first cutting step.

The second transparent layer forming step includes an assembly mounting step and the transparent layer forming step.

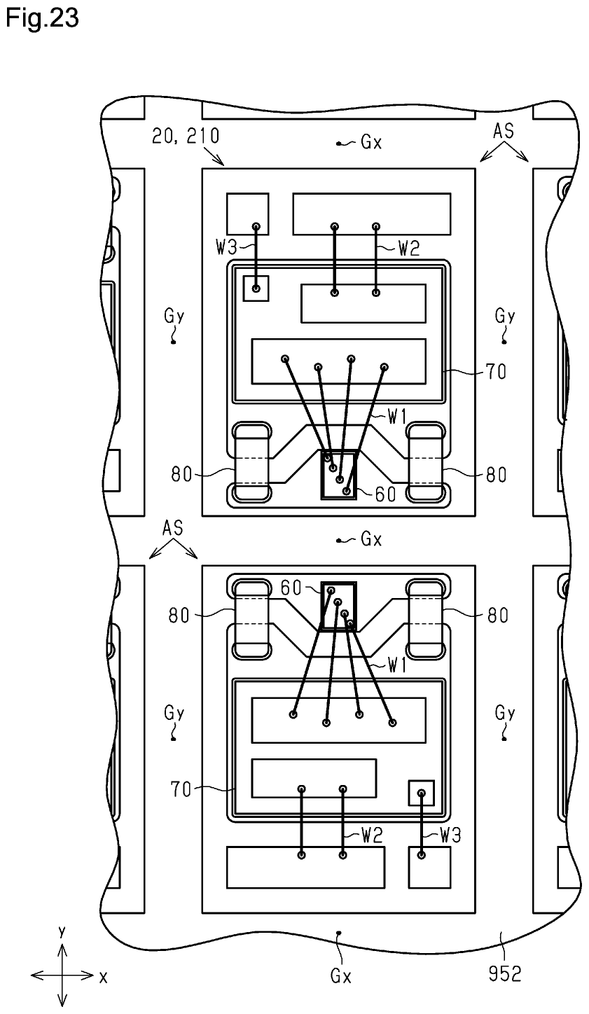

In the assembly mounting step, as shown in FIG. 22, a support substrate 950 is prepared. The support substrate 950 is flat and has a thickness-wise direction conforming to the z-direction. The support substrate 950 includes a substrate main surface 951 facing one direction in the z-direction. Mounting tape 952 is applied to the substrate main surface 951. The assemblies AS are mounted on the mounting tape 952. As shown in FIGS. 22 and 23, as viewed in the z-direction, the assemblies AS are spaced apart from each other in both the x-direction and the y-direction. The assemblies AS that are disposed in the x-direction are aligned with each other in the y-direction and spaced apart in the x-direction. The assemblies AS that are disposed in the y-direction are aligned with each other in the x-direction and spaced apart in the y-direction. As shown in FIG. 23, as viewed in the z-direction, in some of the assemblies AS, the assembly AS is surrounded by gaps Gx extending in the x-direction and gaps Gy extending in the y-direction.

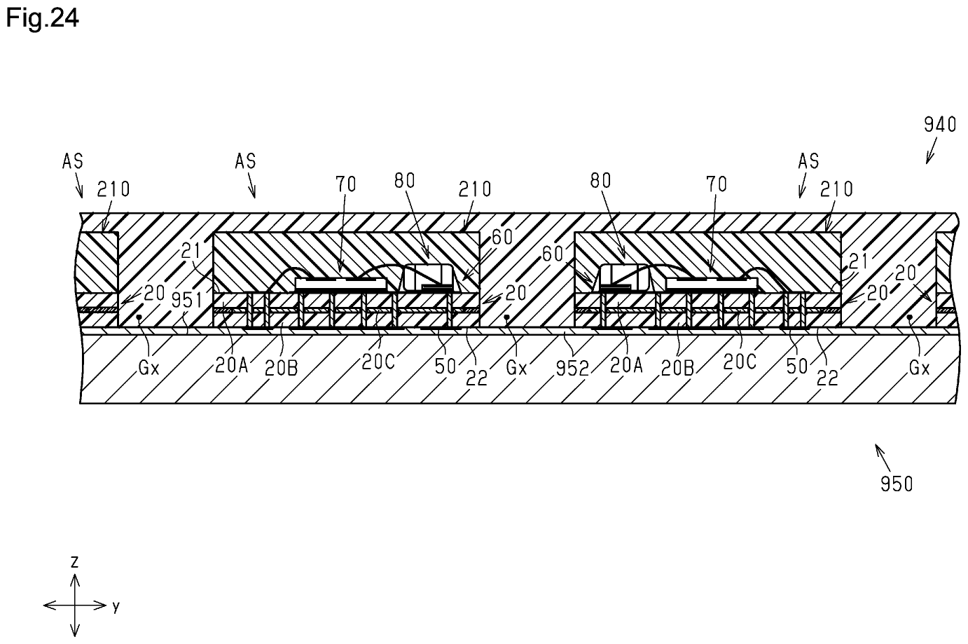

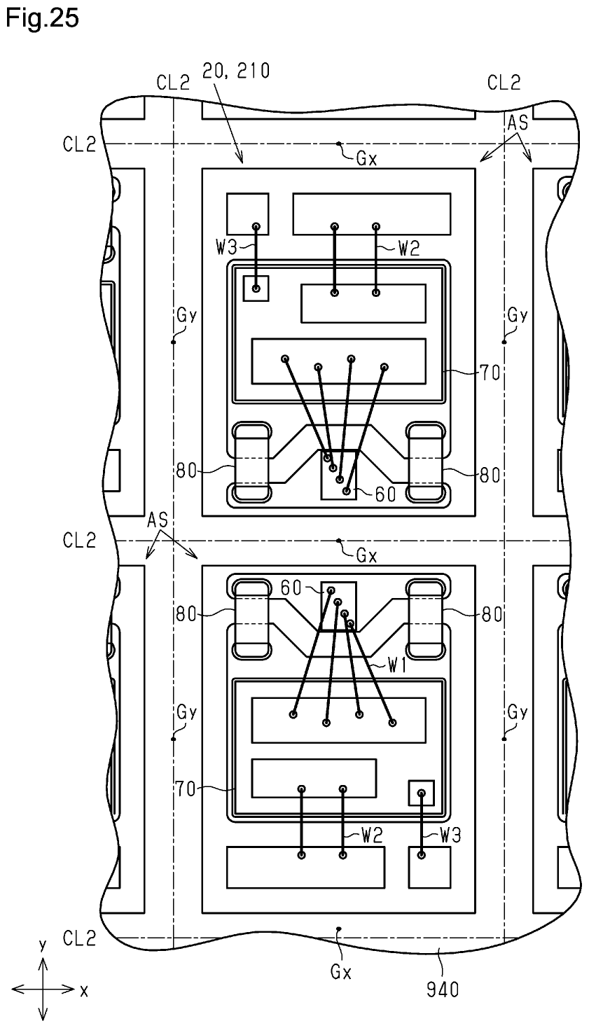

In the transparent layer forming step, as shown in FIG. 24, a second transparent layer 940 is formed to cover each assembly AS. The second transparent layer 940 includes the second transparent member 220 and is formed from a clear resin material. Examples of the clear resin material include an epoxy resin, a polycarbonate resin, and an acrylic resin. In the present embodiment, the second transparent layer 940 and the first transparent layer 930 are formed from the same material. As shown in FIGS. 24 and 25, the second transparent layer 940 is formed to fill the gaps Gx and the gaps Gy. Thus, the second transparent layer 940 encapsulates all of the substrate side surfaces of the substrate 920 in each assembly AS.

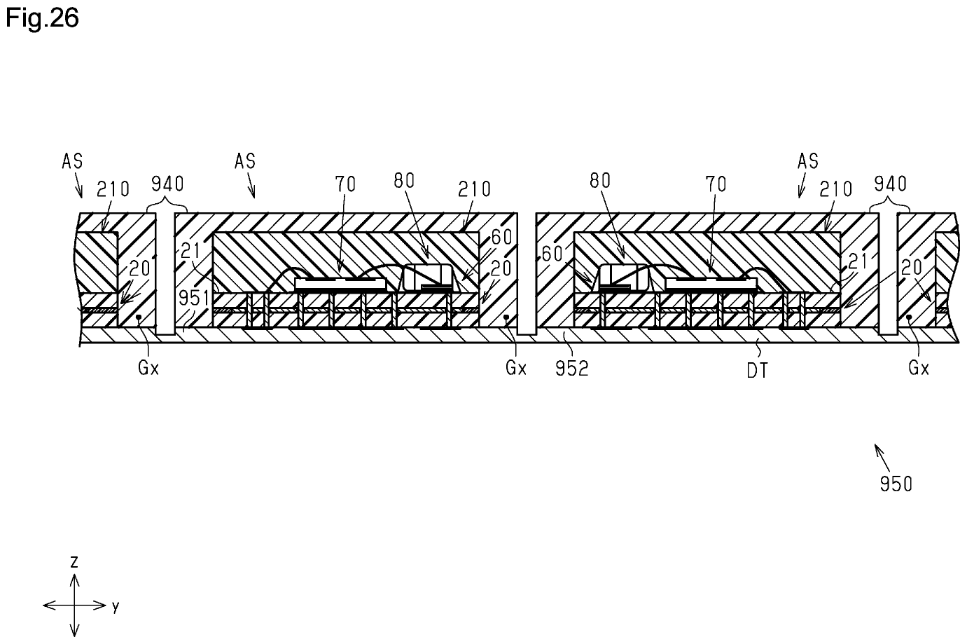

In the second cutting step, the support substrate 950 and the mounting tape 952 are removed. The support substrate 950 and the mounting tape 952 are removed, for example, by a step similar to the support substrate removing step of the first embodiment. Then, as shown in FIG. 26, dicing tape DT is prepared. The assemblies AS encapsulated by the second transparent layer 940 are disposed on the dicing tape DT. For example, a dicing blade is used to cut the second transparent layer 940 along cutting lines CL2 shown in FIG. 25. The cutting lines CL2 in the x-direction extend in the center of the gap Gx in the y-direction. The cutting lines CL2 in the y-direction extend in the center of the gap Gy in the x-direction. The width of the dicing blade and the size of the gaps Gx and Gy are set so that the dicing blade can enter the gaps Gx and Gy. As a result, the assemblies AS covered by the second transparent layer 940 are formed.

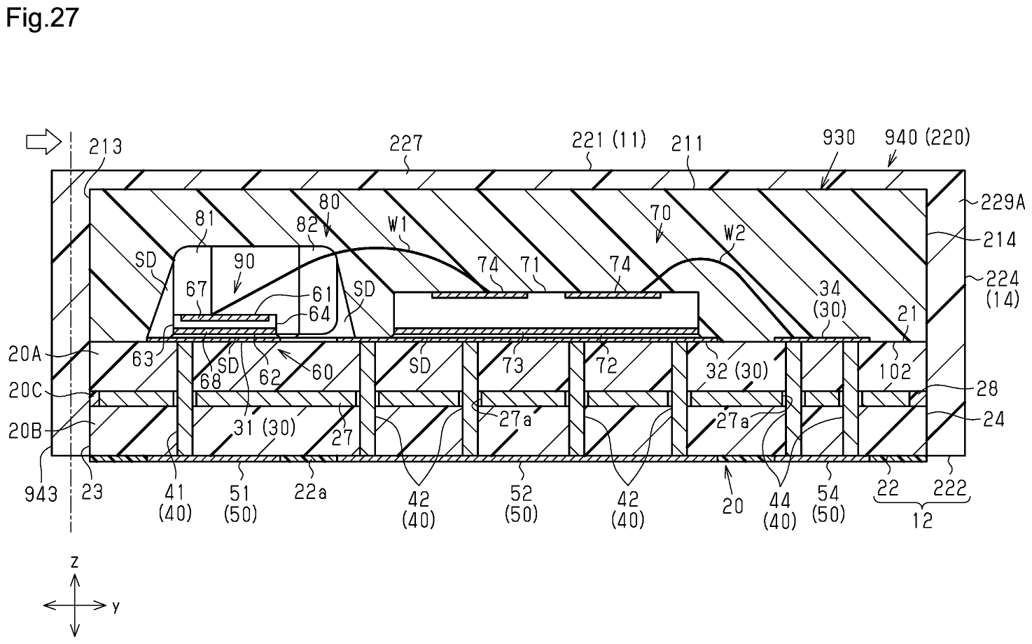

In the mirror-finishing step, the second transparent side surface 943 of the second transparent layer 940 is polished by a mirror-finishing machine. In an example, the second transparent layer 940 is polished to the position indicated by the single-dashed line shown in FIG. 27. As a result, the second transparent member 220 is formed. In other words, the transparent member 200 is formed. The second transparent side surface 223 (refer to FIG. 20) of the second transparent member 220 is a smooth surface. The second transparent side surfaces 224 to 226 (refer to FIG. 19) of the second transparent member 220 are not mirror-finished and thus are diced side surfaces formed by dicing in the second cutting step. When the second transparent side surfaces 224 to 226 are the diced side surfaces, cut marks are formed in the second transparent side surfaces 224 to 226 by the dicing blade. Therefore, the second transparent side surface 223 is flatter than the second transparent side surfaces 224 to 226. The steps described above manufacture the semiconductor light emitting device 10.

Advantages

The semiconductor light emitting device 10 of the present embodiment has the following advantages in addition to the advantages (1-7) and (1-14) to (1-18) of the first embodiment.

(2-1) The semiconductor light emitting device 10 includes the substrate 20 including the substrate main surface 21, the semiconductor light emitting element 60 mounted on the substrate main surface 21, and the transparent member 200 encapsulating the semiconductor light emitting element 60 and transmitting light. The substrate 20 includes the substrate side surface 23, which is the light emitting-side substrate side surface facing the same direction as the light emitting element side surface 63. The light emitting element side surface 63 is the light emitting surface of the semiconductor light emitting element 60. The transparent member 200 includes the light emitting-side cover 228 covering the substrate side surface 23. The light emitting-side cover 228 includes a transparent side surface 223, which is the transparent surface facing the same direction as the light emitting element side surface 63. The transparent side surface 223 includes a mirror-finished smooth surface.

In this structure, since the transparent member 200 covers the substrate side surface 23, only the transparent side surface 223 is mirror-finished. That is, the substrate side surface 23 is not mirror-finished. Thus, during the mirror-finishing process, dust of the substrate side surface 23 will not be produced and will not collect on the mirror-finishing machine. This avoids formation of cut marks (polish marks) on the transparent side surface 223 caused by such dust. When light from the semiconductor light emitting element 60 transmits through the transparent side surface 223, diffusion of the light caused by cut marks (polished marks) is avoided. This limits decreases in the optical output of the semiconductor light emitting device 10.

(2-2) The transparent member 200 includes the side surface covers 229A to 229C covering the substrate side surfaces 24 to 26 of the substrate 20. The side surface covers 229A to 229C include the transparent side surfaces 224 to 226, which are the diced side surfaces having cut marks. The transparent side surface 223, which is the transparent surface, is flatter than the transparent side surfaces 224 to 226.

In this structure, of the transparent side surfaces of the transparent member 200 (the second transparent side surfaces 223 to 226 of the second transparent member 220), only the second transparent side surface 223 is mirror-finished to be the transparent surface. This reduces manufacturing costs as compared to a structure in which one or more of the second transparent side surfaces 224 to 226 are mirror-finished in addition to the second transparent side surface 223.

(2-3) As viewed in the z-direction, the distance between the substrate side surface 23 and the transparent side surface 223 is shorter than the distance between the substrate side surface 24 and the transparent side surface 224, the distance between the substrate side surface 25 and the transparent side surface 225, and the distance between the substrate side surface 26 and the transparent side surface 226.

This structure reduces the thickness of the light emitting-side cover 228, through which light from the semiconductor light emitting element 60 transmits, in the y-direction (light emission direction). Thus, light from the semiconductor light emitting element 60 is less likely to be diffused by the transparent member 200.

(2-4) The substrate 20 includes the main surface layer 20A including the substrate main surface 21, the back surface layer 20B including the substrate back surface 22, and the intermediate layer 20C disposed between the main surface layer 20A and the back surface layer 20B. The intermediate layer 20C includes the metal layer 27.

With this structure, when moisture from the outside of the substrate 20 permeates through the substrate back surface 22 toward the substrate main surface 21, the metal layer 27 limits permeation to the substrate main surface 21 beyond the metal layer 27. This limits collection of moisture on the semiconductor light emitting element 60, the switching element 70, the capacitor 80, the wires W1 to W3, and the main surface wiring lines 30 mounted on the substrate main surface 21. In addition, heat from the semiconductor light emitting element 60 and the switching element 70 is dissipated to the metal layer 27. This limits an excessive increase in the temperature of the semiconductor light emitting element 60 and the switching element 70.

(2-5) As viewed in the z-direction, the metal layer 27 is disposed to overlap the semiconductor light emitting element 60 and the switching element 70.

With this structure, when moisture permeates through the substrate back surface 22 toward the substrate main surface 21, the metal layer 27 limits the permeation of moisture toward the semiconductor light emitting element 60 and the switching element 70. This limits collection of moisture on the semiconductor light emitting element 60 and the switching element 70.

(2-6) The metal layer 27 is located inward from the substrate side surfaces 23 to 26 of the substrate 20.

With this structure, in the manufacturing process of the semiconductor light emitting device 10, when the substrate 920 is cut using a dicing blade, only the insulation layer of the substrate 920 is cut. Thus, the substrate 920 is readily cut.

(2-7) The through holes 27a in the metal layer 27 separate the metal layer 27 from the connection wiring lines 40. The insulation layer 28 is disposed between the connection wiring lines 40 and the inner surfaces defining the through holes 27a.

In this structure, the connection wiring lines 40 are electrically insulated from the metal layer 27.

(2-8) The substrate back surface 22 of the substrate 20 is covered by the back surface insulation layer 22a.

This structure limits permeation of moisture to the substrate back surface 22 from the outside of the substrate 20. That is, permeation of moisture into the substrate 20 is limited. This further limits collection of moisture on the semiconductor light emitting element 60, the switching element 70, the capacitor 80, the wires W1 to W3, and the main surface wiring lines 30 mounted on the substrate main surface 21.

(2-9) The light emitting-side cover 228 of the transparent member 200 (the second transparent member 220) covers at least the main surface layer 20A and the intermediate layer 20C of the substrate side surface 23 of the substrate 20.

With this structure, even when moisture permeates the substrate side surface 23 from the back surface layer 20B, the metal layer 27 limits permeation of moisture to the main surface layer 20A.

(2-10) The light emitting-side cover 228 covers the entire substrate side surface 23.

With this structure, the light emitting-side cover 228 limits permeation of moisture from the substrate side surface 23, thereby limiting permeation of moisture from the outside of the substrate 20 through the substrate side surface 23 to the substrate main surface 21.

(2-11) The transparent member 200 includes the first transparent member 210, which is disposed on the substrate main surface 21 of the substrate 20, and the second transparent member 220, which encapsulates the first transparent member 210. The first transparent member 210 encapsulates the semiconductor light emitting element 60, the switching element 70, the capacitors 80, and the wires W1 to W3. The second transparent member 220 includes the light emitting-side cover 228.

With this structure, in the manufacturing process of the semiconductor light emitting device 10, the assembly in which the first transparent member 210 is formed on the substrate main surface 21 is readily transported by a transport device. In addition, the first transparent member 210 protects the semiconductor light emitting element 60, the switching element 70, the capacitors 80, and the wires W1 to W3. This prevents contact of the semiconductor light emitting element 60, the switching element 70, the capacitors 80, and the wires W1 to W3 with an external part during the transportation, thereby limiting deformation of the wires W1 to W3 during the transportation.

(2-12) The second transparent member 220 covers the entire first transparent member 210.

With this structure, in the manufacturing process of the semiconductor light emitting device 10, the second transparent layer 940 is readily formed.

(2-13) The first transparent member 210 includes the first transparent main surface 211 facing the same direction as the substrate main surface 21, the first transparent side surface 213, which is the first light emitting side surface facing the same direction as the light emitting element side surface 63, and the first transparent side surfaces 214 to 216 intersecting the first transparent side surface 213 (the light emitting surface) as viewed in the z-direction. The light emitting element side surface 63 is the light emitting surface of the semiconductor light emitting element 60. The second transparent member 220 includes the main surface cover 227 covering the first transparent main surface 211, the light emitting-side cover 228 covering the first transparent side surface 213, and the side surface covers 229A to 229C covering the first transparent side surfaces 214 to 216. The main surface cover 227 includes the second transparent main surface 221 facing the same direction as the first transparent main surface 211. The side surface covers 229A to 229C include the second transparent side surfaces 224 to 226, which are the diced side surfaces. The distance between the first transparent side surface 213 and the second transparent side surface 223 is shorter than the distance between the first transparent side surface 214 and the second transparent side surface 224, the distance between the first transparent side surface 215 and the second transparent side surface 225, and the distance between the first transparent side surface 216 and the second transparent side surface 226.

This structure reduces the thickness of the light emitting-side cover 228, through which light from the semiconductor light emitting element 60 transmits, in the y-direction (light emission direction). Thus, light from the semiconductor light emitting element 60 is less likely to be diffused by the transparent member 200.

(2-14) The distance between the first transparent main surface 211 and the second transparent main surface 221 is shorter than the distance between the first transparent side surface 214 and the second transparent side surface 224, the distance between the first transparent side surface 215 and the second transparent side surface 225, and the distance between the first transparent side surface 216 and the second transparent side surface 226.

This structure reduces the thickness of the main surface cover 227, thereby reducing the thickness of the transparent member 200. This allows for reduction in the size of the semiconductor light emitting device 10 in the z-direction (the height-wise direction of the semiconductor light emitting device 10).

(2-15) The side surface covers 229A to 229C of the transparent member 200 (the second transparent member 220) cover at least the main surface layer 20A and the intermediate layer 20C of the substrate side surfaces 24 to 26 of the substrate 20.

With this structure, even when moisture permeates the substrate side surfaces 24 to 26 from the back surface layer 20B, the metal layer 27 limits permeation of moisture to the main surface layer 20A.

(2-16) The side surface covers 229A to 229C cover the entire substrate side surfaces 24 to 26, respectively.

With this structure, the side surface covers 229A to 229C limit permeation of moisture from the substrate side surfaces 24 to 26, thereby limiting permeation of moisture from the outside of the substrate 20 through the substrate side surfaces 24 to 26 to the substrate main surface 21.

(2-17) The method for manufacturing the semiconductor light emitting device 10 includes a step of preparing a plurality of assembles AS, a step of forming the second transparent layer 940 covering the first transparent layer 930 and the substrate 920 of each assembly AS, a step of cutting the second transparent layer 940 for singulation, and a step of polishing the second transparent side surface 943, the transparent surface being a surface of the second transparent layer 940 facing the same direction as the light emitting element side surface 63. Each assembly AS includes the substrate 20 including the substrate main surface 21 and the substrate side surfaces 23 to 26, the semiconductor light emitting element 60 mounted on the substrate main surface 21 and including the light emitting element side surface 63, which is the light emitting surface facing a direction intersecting the substrate main surface 21, and the first transparent layer 930 encapsulating the semiconductor light emitting element 60 and transmitting light.

In this structure, since the second transparent layer 940 covers the substrate side surface 23, only the second transparent side surface 943 is mirror-finished. That is, the substrate side surface 23 is not mirror-finished. Thus, during the mirror-finishing process, dust of the substrate side surface 23 will not be produced and will not collect on the mirror-finishing machine. This avoids formation of cut marks (polish marks) on the second transparent side surface 943 caused by such dust. When light from the semiconductor light emitting element 60 transmits through the second transparent side surface 943, diffusion of the light caused by cut marks (polished marks) is avoided. This limits decreases in the optical output of the semiconductor light emitting device 10.

### Third Embodiment

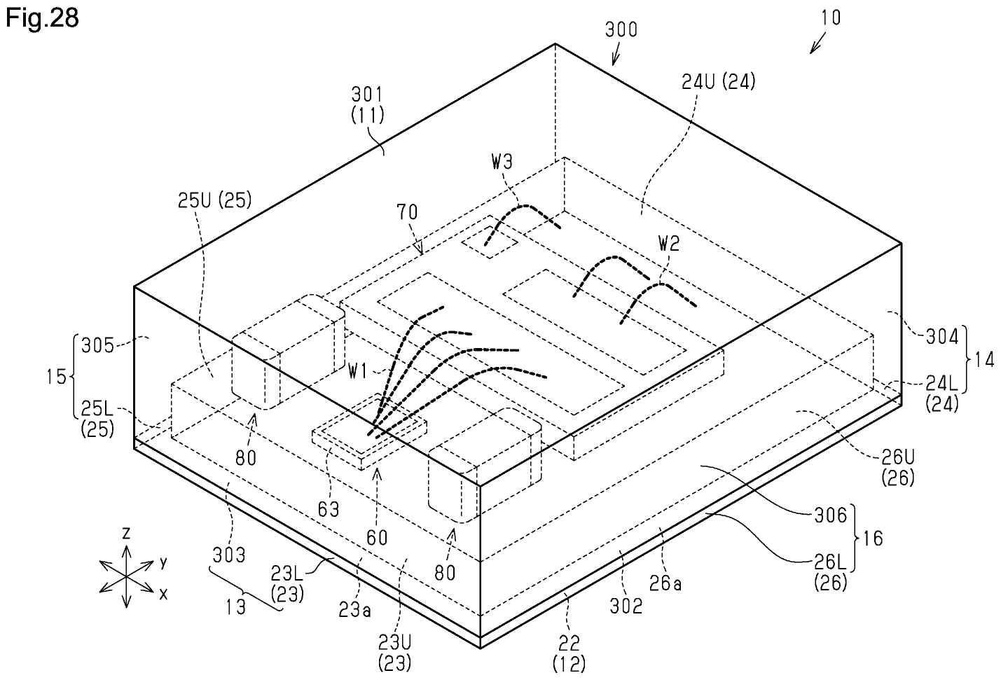

A third embodiment of a semiconductor light emitting device 10 will now be described with reference to FIGS. 28 to 34. The present embodiment of the semiconductor light emitting device 10 differs from the second embodiment of the semiconductor light emitting device 10 in a transparent member 300 and the structure of the substrate 20. In the description below, the same reference characters are given to those components that are the same as the corresponding components of the second embodiment. Such components will not be described in detail.

Structure of Semiconductor Light Emitting Device

The structure of the semiconductor light emitting device 10 will now be described with reference to FIGS. 28 to 30. In FIG. 28, for the sake of convenience, the substrate 20, the semiconductor light emitting element 60, the switching element 70, the capacitor 80, and the wires W1 to W3 are indicated by broken lines and disposed in the transparent member 300.

The transparent member 300 is formed from the same material as the transparent member 200 of the second embodiment. As shown in FIG. 28, the transparent member 300 encapsulates a semiconductor light emitting element 60, a switching element 70, multiple (in the present embodiment, two) capacitors 80, and wires W1 to W3. The transparent member 300 encapsulates a portion of each of the substrate side surfaces 23 to 26 in the z-direction.

The transparent member 300 includes a transparent main surface 301 and a transparent back surface 302 facing opposite directions in the z-direction and transparent side surfaces 303 to 306, each of which faces a direction intersecting the transparent main surface 301 and the transparent back surface 302.

The transparent main surface 301 and the substrate main surface 21 face the same direction. The transparent back surface 302 and the substrate back surface 22 face the same direction. In the present embodiment, the transparent main surface 301 defines the device main surface 11. The substrate back surface 22 defines the device back surface 12.

The transparent side surface 303 and the substrate side surface 23 face the same direction. The transparent side surface 304 and the substrate side surface 24 face the same direction. The transparent side surface 305 and the substrate side surface 25 face the same direction. The transparent side surface 306 and the substrate side surface 26 face the same direction. The transparent side surface 303 covers a portion of the substrate side surface 23 in the z-direction and the entirety of the substrate side surface 23 in the x-direction. The transparent side surface 304 covers a portion of the substrate side surface 24 in the z-direction and the entirety of the substrate side surface 24 in the x-direction. The transparent side surface 305 covers a portion of the substrate side surface 25 in the z-direction and the entirety of the substrate side surface 25 in the y-direction. The transparent side surface 306 covers a portion of the substrate side surface 26 in the z-direction and the entirety of the substrate side surface 26 in the y-direction.

As shown in FIG. 28, the present embodiment of the substrate 20 differs from the second embodiment of the substrate 20 in that a portion of each of the substrate side surfaces 23 to 26 is not covered by the transparent member 300. More specifically, in the present embodiment, the portions of the substrate side surfaces 23 to 26 that are not covered by the transparent member 300 are exposed to the outside of the semiconductor light emitting device 10.

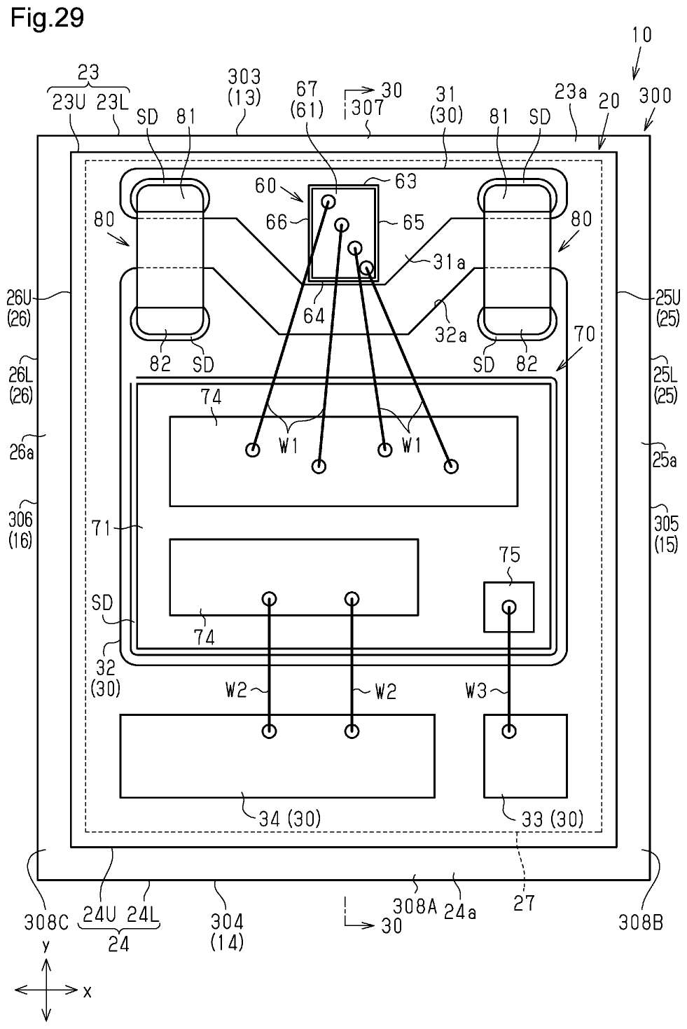

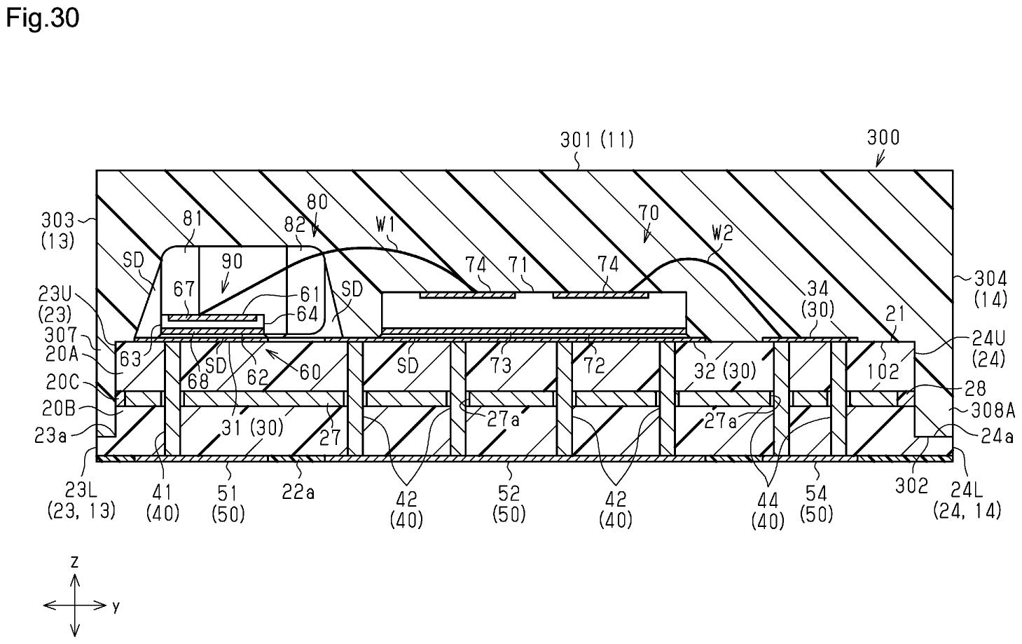

As shown in FIG. 29, the peripheral portion of the substrate 20 is recessed inward along the entire perimeter. More specifically, of the two ends of the substrate 20 in the y-direction, the one located closer to the substrate side surface 23 includes a recess 23a, and the one located closer to the substrate side surface 24 includes a recess 24a. Of the two ends of the substrate 20 in the x-direction, the one located closer to the substrate side surface 25 includes a recess 25a, and the one located closer to the substrate side surface 26 includes a recess 26a. The recess 23a is continuous with the recesses 25a and 26a. The recess 24a is continuous with the recesses 25a and 26a. The recesses 23a, 24a, 25a, and 26a are open toward the substrate main surface 21 in the z-direction. Thus, in each of the substrate side surfaces 23 to 26, a portion located toward the substrate main surface 21 is positioned inward from a portion located toward the substrate back surface 22. More specifically, as shown in FIG. 30, the recesses 23a and 24a are entirely formed in the main surface layer 20A and the intermediate layer 20C of the substrate 20 in the z-direction. Also, the recesses 23a and 24a are formed in a portion of the back surface layer 20B of the substrate 20 located toward the intermediate layer 20C in the z-direction. Although not shown, in the same manner as the recesses 23a and 24a, the recesses 25a and 26a are entirely formed in the main surface layer 20A and the intermediate layer 20C of the substrate 20 in the z-direction and are formed in a portion of the back surface layer 20B of the substrate 20 located toward the intermediate layer 20C in the z-direction.

The substrate side surface 23 includes a substrate side surface 23U corresponding to the recess 23a and a substrate side surface 23L located toward the substrate back surface 22 from the recess 23a. In the x-direction, the substrate side surface 23U is disposed inward from the substrate side surface 23L.

The substrate side surface 24 includes a substrate side surface 24U corresponding to the recess 24a and a substrate side surface 24L located toward the substrate back surface 22 from the recess 24a. In the x-direction, the substrate side surface 24U is disposed inward from the substrate side surface 24L.

As shown in FIG. 29, the substrate side surface 25 includes a substrate side surface 25U corresponding to the recess 25a and a substrate side surface 25L located toward the substrate back surface 22 from the recess 25a. In the y-direction, the substrate side surface 25U is disposed inward from the substrate side surface 25L.

The substrate side surface 26 includes a substrate side surface 26U corresponding to the recess 26a and a substrate side surface 26L located toward the substrate back surface 22 from the recess 26a. In the y-direction, the substrate side surface 26U is disposed inward from the substrate side surface 26L.

The substrate side surfaces 23U to 26U are equal to each other in the dimension in the z-direction. The substrate side surfaces 23L to 26L are equal to each other in the dimension in the z-direction. The substrate side surface 23U is continuous with the substrate side surfaces 25U and 26U. The substrate side surface 24U is continuous with the substrate side surfaces 25U and 26U.

The transparent member 300 is disposed in the recesses 23a, 24a, 25a, and 26a. Thus, the substrate side surfaces 23U to 26U are covered by the transparent member 300. More specifically, the transparent member 300 includes a light emitting-side cover 307 disposed in the recess 23a and side surface covers 308A to 308C disposed in the recesses 24a, 25a, and 26a. The side surface cover 308A includes the transparent side surface 304. The side surface cover 308B includes the transparent side surface 305. The side surface cover 308C includes the transparent side surface 306.

In the present embodiment, the thickness of the light emitting-side cover 307 (dimension of the light emitting-side cover 307 in the y-direction) is smaller than the thickness of the side surface cover 308A (dimension of the side surface cover 308A in the y-direction), the thickness of the side surface cover 308B (dimension of the side surface cover 308B in the x-direction), and the thickness of the side surface cover 308C (dimension of the side surface cover 308C in the x-direction). In the present embodiment, the thicknesses of the side surface covers 308A to 308C are equal to each other.

The thicknesses of the light emitting-side cover 307 and the side surface covers 308A to 308C may be changed in any manner. In an example, the thickness of the light emitting-side cover 307 may be equal to the thickness of the side surface covers 308A to 308C. The side surface covers 308A to 308C may have different thicknesses.

In the present embodiment, the substrate side surface 23L is flush with the transparent side surface 303. The substrate side surface 24L is flush with the transparent side surface 304. The substrate side surface 25L is flush with the transparent side surface 305. The substrate side surface 26L is flush with the transparent side surface 306. Thus, the substrate side surfaces 23L to 26L are exposed to the outside of the semiconductor light emitting device 10. In the present embodiment, the substrate side surface 23L and the transparent side surface 303 define the device side surface 13. The substrate side surface 24L and the transparent side surface 304 define the device side surface 14. The substrate side surface 25L and the transparent side surface 305 define the device side surface 15. The substrate side surface 26L and the transparent side surface 306 define the device side surface 16.

Manufacturing Method of Semiconductor Light Emitting Device

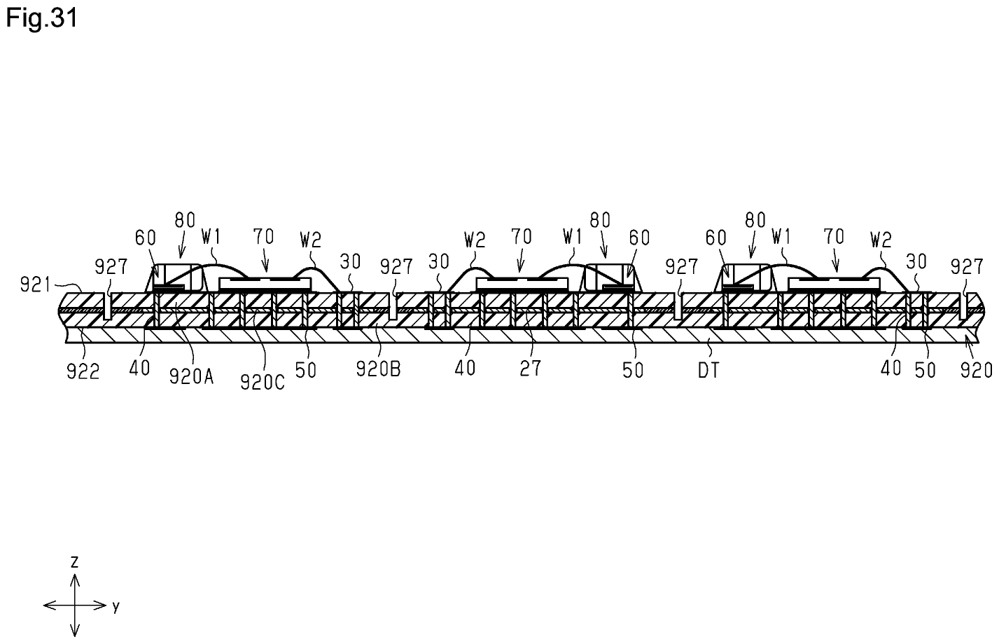

An example of a method for manufacturing the semiconductor light emitting device 10 will now be described with reference to FIGS. 31 to 34.

The method for manufacturing the semiconductor light emitting device 10 includes the element mounting step, the wire forming step, a substrate processing step, the transparent layer forming step, the cutting step, and the mirror-finishing step. In the present embodiment, the element mounting step, the wire forming step, the substrate processing step, the transparent layer forming step, the cutting step, and the mirror-finishing step are performed in order. The steps in the method for manufacturing the semiconductor light emitting device 10 may be changed in any manner. In an example, the substrate processing step may be performed prior to the element mounting step.

As shown in FIG. 31, the element mounting step and the wire forming step are the same as the element mounting step and the wire forming step of the second embodiment. The substrate 920 has a multilayer structure in which multiple layers are stacked in the thickness-wise direction (the z-direction) of the substrate 920. The substrate 920 includes a main surface layer 920A including the substrate main surface 921, a back surface layer 920B including the substrate back surface 922, and an intermediate layer 920C disposed between the main surface layer 920A and the back surface layer 920B in the z-direction. The main surface layer 920A corresponds to the main surface layer 20A of the substrate 20. The back surface layer 920B corresponds to the back surface layer 20B of the substrate 20. The intermediate layer 920C corresponds to the intermediate layer 20C of the substrate 20.

As shown in FIG. 31, in the substrate processing step, the substrate 920 is disposed on the dicing tape DT. Then, for example, the dicing blade is used to form slits 927 in the substrate 920. In other words, the substrate 920 is not cut apart in the substrate processing step. As viewed in the z-direction, the slits 927 are formed in the x-direction and the y-direction in conformance with the size of the substrate 20. In the present embodiment, as shown in FIG. 31, in the z-direction, the slits 927 each have a bottom located closer to the substrate back surface 922 than the border between the intermediate layer 920C and the back surface layer 920B.

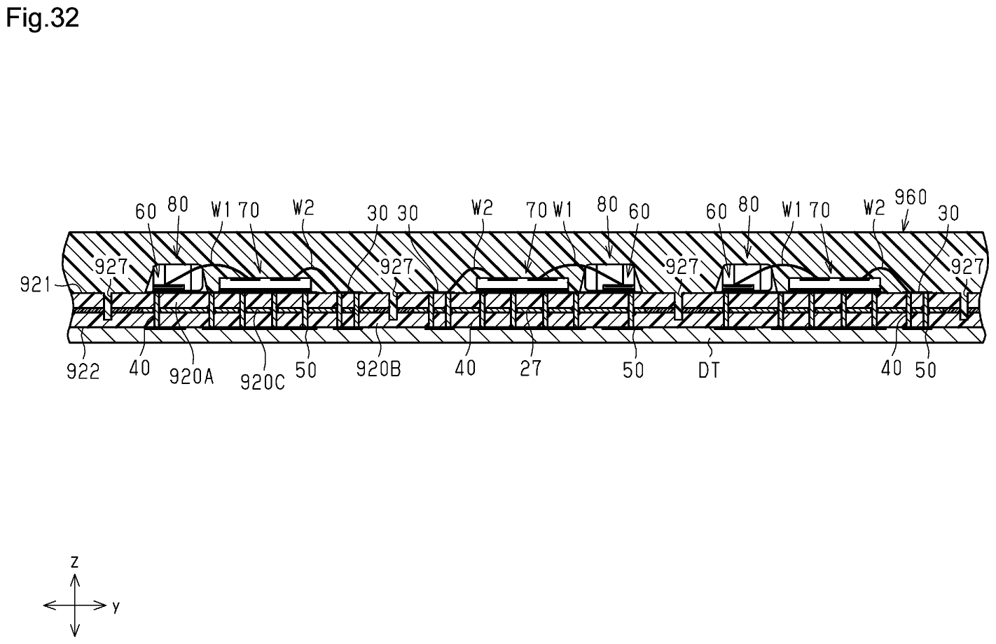

In the transparent layer forming step, as shown in FIG. 32, a transparent layer 960 is formed. The transparent layer 960 includes the transparent member 300 and is formed from a clear resin material. Examples of the clear resin material include an epoxy resin, a polycarbonate resin, and an acrylic resin. The transparent layer 960 encapsulates the semiconductor light emitting element 60. In the present embodiment, the transparent layer 960 encapsulates multiple semiconductor light emitting elements 60, multiple switching elements 70, and capacitors 80. More specifically, the transparent layer 960 covers all of the semiconductor light emitting elements 60, all of the switching elements 70, and all of the capacitors 80 mounted on the substrate 920. The transparent layer 960 fills each slit 927.

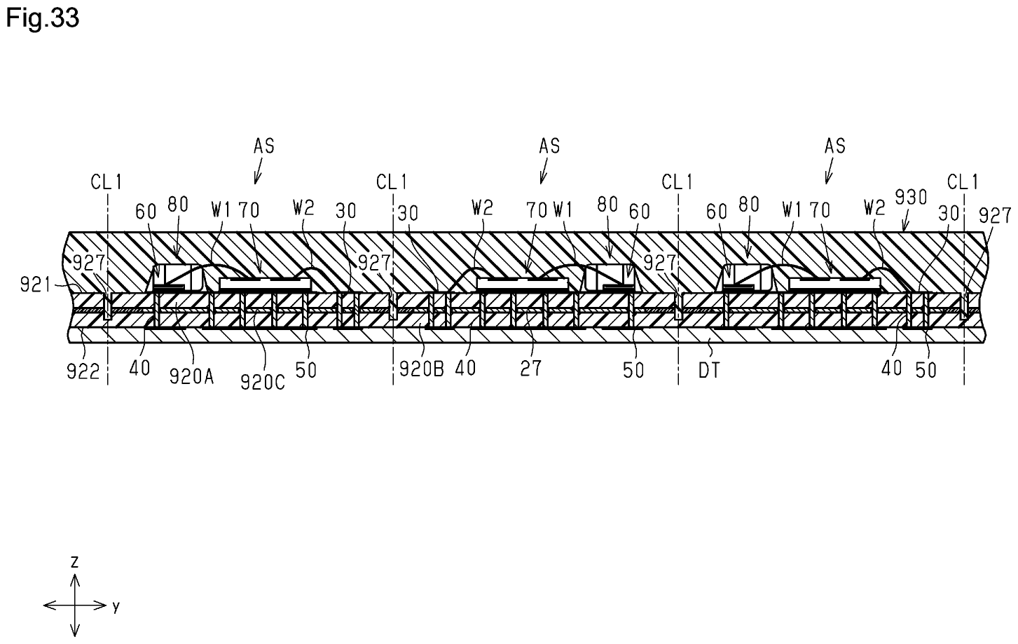

In the cutting step, as shown in FIG. 33, the transparent layer 960 and the substrate 920 are cut along cutting lines CL indicated by single-dashed lines. In other words, in the cutting step, as viewed in the z-direction, the transparent layer 960 and the substrate 920 are cut along the slits 927. This forms multiples assemblies AS, each of which includes the semiconductor light emitting element 60, the switching element 70, and the capacitors 80 mounted on the singulated substrate 920 and encapsulated by the singulated transparent layer 960. Then, the dicing tape DT is removed from the assembly AS.

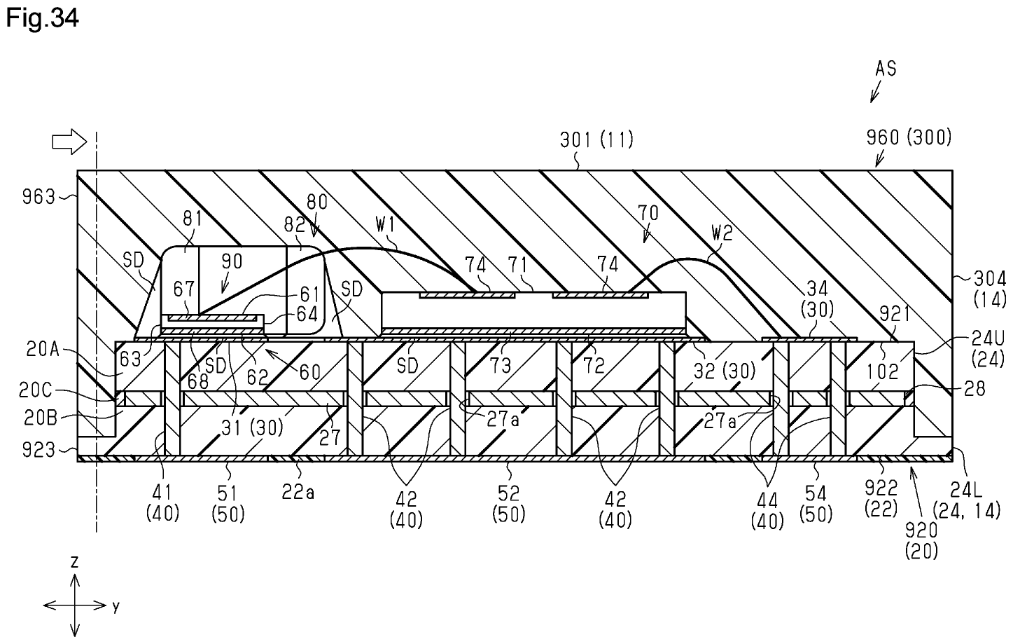

In the mirror-finishing step, as shown in FIG. 34, the mirror-finishing process is performed on the transparent side surface 963, which is a surface of the transparent layer 960 facing the same direction as the light emitting element side surface 63, that is, the light emitting surface of the semiconductor light emitting element 60, and a substrate side surface 923, which is a surface of the substrate 920 facing the same direction as the light emitting element side surface 63. More specifically, a mirror-finishing machine polishes the transparent side surface 963 and the substrate side surface 923 inward from the position indicated by a single-dashed line, which corresponds to a state prior to the mirror-finishing process, in the y-direction. As a result, the substrate 20 and the transparent member 300 are formed. The transparent side surface 303 (refer to FIG. 30) of the transparent member 300 becomes a mirror-finished smooth surface. The transparent side surfaces 304 to 306 (refer to FIG. 29) of the transparent member 300 are not mirror-finished in this step and will become diced side surfaces formed by dicing in the cutting step. When the transparent side surfaces 304 to 306 are the diced side surfaces, cut marks are formed by the dicing blade. Therefore, the transparent side surface 303 is flatter than the transparent side surfaces 304 to 306. In an example, when the transparent side surface 303 has a smaller surface roughness than the transparent side surfaces 304 to 306, it is considered that the transparent side surface 303 is flatter than the transparent side surfaces 304 to 306. The surface roughness may be expressed by, for example, arithmetic average roughness (Ra). The steps described above manufacture the semiconductor light emitting device 10.

Advantages

The semiconductor light emitting device 10 of the present embodiment has the following advantages in addition to the advantages of the second embodiment.

(3-1) The semiconductor light emitting device 10 includes the substrate 20 including the substrate main surface 21, the semiconductor light emitting element 60 mounted on the substrate main surface 21, and the transparent member 300 encapsulating the semiconductor light emitting element 60 and transmitting light. The substrate 20 includes the substrate side surface 23, which is the light emitting-side substrate side surface facing the same direction as the light emitting element side surface 63. The light emitting element side surface 63 is the light emitting surface of the semiconductor light emitting element 60. The transparent member 300 includes the light emitting-side cover 307 covering the substrate side surface 23U of the substrate side surface 23. The light emitting-side cover 307 includes a transparent side surface 303, which is the transparent surface facing the same direction as the light emitting element side surface 63. The transparent side surface 303 includes a mirror-finished smooth surface.

In this structure, since the transparent member 300 covers the substrate side surface 23U, only the transparent side surface 303 and the substrate side surface 23L are mirror-finished. Thus, the substrate side surface 23U of the substrate side surface 23 is not mirror-finished. Thus, during the mirror-finishing process of the substrate side surface 23, dust of the substrate side surface 23U will not be produced and will not collect on the mirror-finishing machine. This avoids formation of cut marks (polish marks) on the transparent side surface 303 caused by such dust of the substrate side surface 23. When light from the semiconductor light emitting element 60 transmits through the transparent side surface 303, the light is less likely to be diffused by cut marks (polished marks). This limits decreases in the optical output of the semiconductor light emitting device 10.

(3-2) The transparent member 300 includes the side surface covers 308A to 308C covering the substrate side surfaces 24U to 26U of the substrate side surfaces 24 to 26 of the substrate 20. The side surface covers 308A to 308C include the transparent side surfaces 304 to 306, which are the diced side surfaces having cut marks. The transparent side surface 303, which is the transparent surface, is flatter than the transparent side surfaces 304 to 306.

In this structure, of the transparent side surfaces 303 to 306 of the transparent member 300, only the transparent side surface 303 is mirror-finished to be the transparent surface. This reduces manufacturing costs as compared to a structure in which one or more of the transparent side surfaces 304 to 306 is mirror-finished in addition to the transparent side surface 303.

(3-3) As viewed in the z-direction, the distance between the substrate side surface 23U and the transparent side surface 303 is shorter than the distance between the substrate side surface 24U and the transparent side surface 304, the distance between the substrate side surface 25U and the transparent side surface 305, and the distance between the substrate side surface 26U and the transparent side surface 306.

This structure reduces the thickness of the light emitting-side cover 307, through which light from the semiconductor light emitting element 60 transmits, in the y-direction (light emission direction). Thus, light from the semiconductor light emitting element 60 is less likely to be diffused by the transparent member 200.

(3-4) The method for manufacturing the semiconductor light emitting device 10 includes a step of preparing the substrate 920 including the substrate main surface 921, a step of mounting multiple semiconductor light emitting elements 60 on the substrate main surface 921, a step of forming the slits 927 in the substrate 920 so as to define and singulate the semiconductor light emitting elements 60, a step of forming the transparent layer 960 encapsulating the semiconductor light emitting element 60 and filling the slits 927, a step of cutting the transparent layer 960 and the substrate 920 along the slits 927, a step of polishing the transparent side surface 963, which is the transparent surface of the transparent layer 960 facing the same direction as the light emitting element side surface 63, and the substrate side surface 923 of the substrate 920, which faces the same direction as the light emitting element side surface 63, the light emitting element side surface 63 being a light emitting surface.

In this structure, the transparent layer 960, which fills the slits 927 in the substrate 920, covers a portion of the substrate side surface 923. Thus, the transparent side surface 963 and a portion of the substrate side surface 923 are mirror-finished. That is, the side surface of the substrate side surface 923 corresponding to the slit 927 is not mirror-finished. Thus, during the mirror-finishing process of the substrate side surface 923, since produced dust is less likely to collect on the mirror-finishing machine, cut marks (polished marks) caused by the dust of the substrate side surface 923 is less likely to be formed on the transparent side surface 963. When light from the semiconductor light emitting element 60 transmits through the transparent side surface 963, the light is less likely to be diffused by cut marks (polished marks). This limits decreases in the optical output of the semiconductor light emitting device 10.

(3-5) The bottom of the slit 927 is located closer to the substrate back surface 922 than the border between the intermediate layer 920C and the back surface layer 920B of the substrate 920.

With this structure, of the substrate side surface 923 and a substrate side surface other than the substrate side surface 923 (hereafter, referred to as “the substrate side surface 923 and the like”), the transparent layer 960 is located closer to the substrate back surface 922 than the metal layer 27 of the intermediate layer 920C. Even when moisture from the outside of the substrate 920 permeates through the substrate side surface 923 and the like into the substrate 920, the metal layer 27 limits the permeation of moisture to the substrate main surface 921. This limits collection of moisture on the semiconductor light emitting element 60, the switching element 70, the capacitor 80, the wires W1 to W3, and the main surface wiring lines 30 mounted on the substrate main surface 21.

### Modified Examples

The embodiments exemplify, without any intention to limit, applicable forms of a semiconductor light emitting device according to the present disclosure. The semiconductor light emitting device according to the present disclosure may be applicable to forms differing from the above embodiments. In an example of such a form, the structure of the embodiments is partially replaced, changed, or omitted, or a further structure is added to the embodiments. The modified examples described below may be combined with one another as long as there is no technical inconsistency. In the modified examples, the same reference characters are given to those components that are the same as the corresponding components of the above embodiment. Such components will not be described in detail.

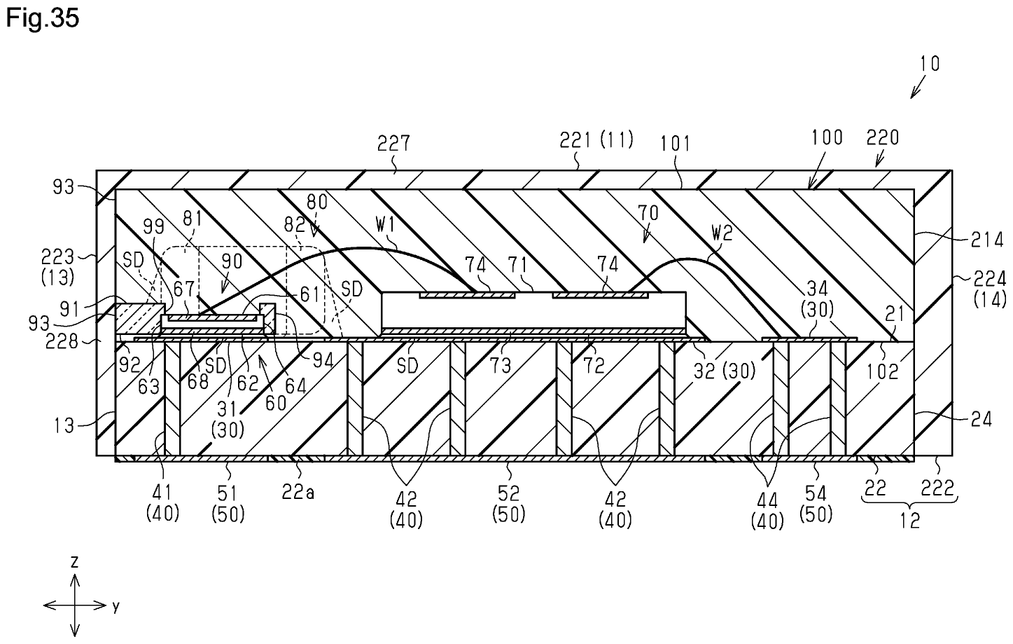

The first embodiment and the second embodiment may be combined. In an example, as shown in FIG. 35, the semiconductor light emitting device 10 includes the transparent member 90 and the encapsulation resin 100 of the first embodiment and the second transparent member 220 of the second embodiment. The transparent member 90 and the encapsulation resin 100 are the same as the transparent member 90 and the encapsulation resin 100 of the first embodiment. The second transparent member 220 covers the resin main surface 101 and the resin side surfaces 103 to 106 of the encapsulation resin 100 (the resin side surfaces 105 and 106 are not shown in FIG. 35), the transparent side surface 93 of the transparent member 90, and the substrate side surfaces 23 to 26 of the substrate 20 (the substrate side surfaces 25 and 26 are not shown in FIG. 35). In other words, the semiconductor light emitting device 10 of the modified example shown in FIG. 35 differs from that of the first embodiment in that the transparent side surface 93 is not exposed to the exterior of the semiconductor light emitting device 10. The second transparent member 220 does not cover the substrate back surface 22. The second transparent side surface 223 of the second transparent member 220 is a mirror-finished smooth surface facing the same direction as the light emitting element side surface 63, which is the light emitting surface of the semiconductor light emitting element 60. Each of the second transparent side surfaces 224 to 226 is an example of a diced side surface as in the second embodiment. Thus, in the same manner as the second embodiment, the second transparent side surface 223 is flatter than the second transparent side surfaces 224 to 226.

As shown in FIG. 35, the light emitting-side cover 228, which is mirror-finished, is smaller in thickness than the side surface cover 229A, which is not mirror-finished. In addition, although not shown, the light emitting-side cover 228 is smaller in thickness than the side surface covers 229B and 229C, which are not mirror-finished.

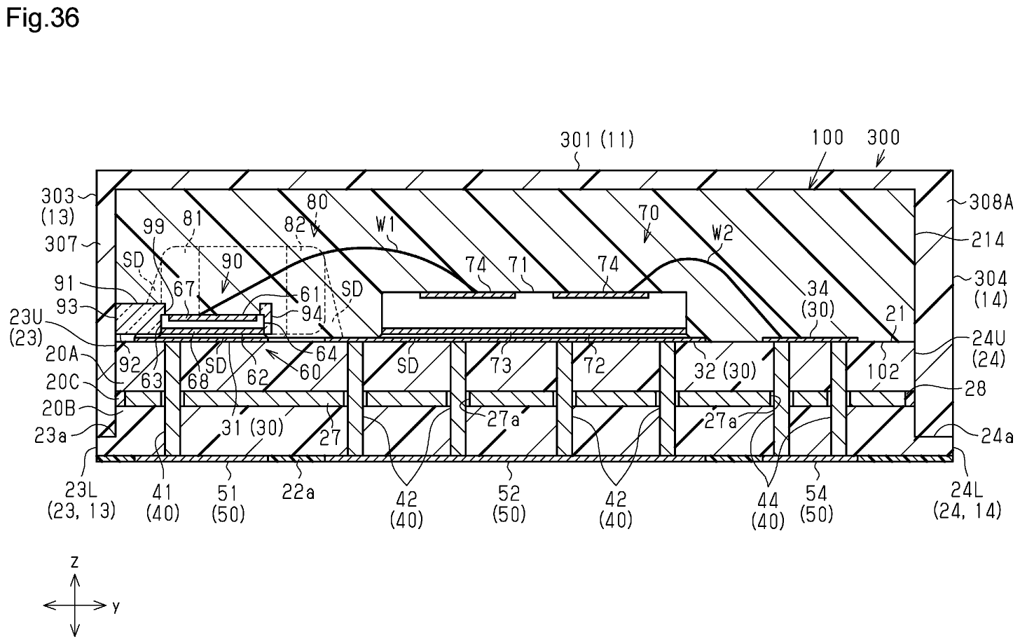

The first embodiment and the third embodiment may be combined. In an example, as shown in FIG. 36, the semiconductor light emitting device 10 includes the transparent member 90 and the encapsulation resin 100 of the first embodiment and the transparent member 300 of the third embodiment. The transparent member 90 and the encapsulation resin 100 are the same as the transparent member 90 and the encapsulation resin 100 of the first embodiment. The transparent member 300 differs in the structure from that of the third embodiment. More specifically, the transparent member 300 covers the resin main surface 101 and the resin side surfaces 103 to 106 (the resin side surfaces 105 and 106 are not shown in FIG. 35) of the encapsulation resin 100, the transparent side surface 93 of the transparent member 90, and the recesses 23a to 26a in the substrate side surfaces 23 to 26 (the substrate side surfaces 25 and 26 are not shown in FIG. 35) of the substrate 20. In other words, the semiconductor light emitting device 10 of the modified example shown in FIG. 35 differs from that of the first embodiment in that the transparent side surface 93 is not exposed to the exterior of the semiconductor light emitting device 10. The transparent member 300 does not cover the substrate back surface 22. The transparent side surface 303 of the transparent member 300 is a mirror-finished smooth surface facing the same direction as the light emitting element side surface 63, which is the light emitting surface of the semiconductor light emitting element 60.

In the first embodiment, the resin side surface 103 of the encapsulation resin 100 may be located closer to the substrate side surface 24 than the substrate side surface 23.

In the first embodiment, the range of the semiconductor light emitting element 60 covered by the transparent member 90 may be changed in any manner. The transparent member 90 may be configured not to cover at least one of the light emitting element side surfaces 64 to 66 of the semiconductor light emitting element 60. That is, it is sufficient that the transparent member 90 covers at least the light emitting element side surface 63, which is the light emitting surface, among the light emitting element side surfaces 63 to 66 of the semiconductor light emitting element 60.

In the first embodiment, the transparent back surface 92 of the transparent member 90 does not necessarily have to be flush with the light emitting element back surface 62 of the semiconductor light emitting element 60. In an example, the transparent back surface 92 may be disposed to project from the light emitting element back surface 62 in a direction away from the light emitting element main surface 61.

In the first embodiment, the distance HA between the substrate main surface 21 of the substrate 20 and the transparent main surface 91 of the transparent member 90 may be changed in any manner. In an example, the distance HA may be greater than or equal to the distance HB between the substrate main surface 21 and the switching element main surface 71 of the switching element 70. The distance HA may be greater than or equal to the distance HC between the substrate main surface 21 and the capacitor main surface 83 of the capacitor 80.

In the first embodiment, the transparent member 90 may be disposed closely next to the capacitor 80 in the x-direction. The transparent member 90 may be disposed to encapsulate the capacitor 80.

In the first embodiment, the transparent member 90 may be disposed closely next to the switching element 70 in the y-direction.

In the first embodiment, the material of the encapsulation resin 100 may be changed to any material having a smaller linear expansion coefficient than that of the transparent member 90. In an example, the encapsulation resin 100 may be formed from a material having a glass-transition temperature that is lower than or equal to that of the transparent member 90. The filler may be omitted from the encapsulation resin 100.

In the first embodiment, the transparent side surface 93, which is the transparent surface of the transparent member 90, does not necessarily have to be a mirror-finished smooth surface. In an example, the transparent side surface 93 may be a diced side surface that is cut with a dicing blade. Also, the resin side surface 103 of the encapsulation resin 100 and the substrate side surface 23 of the substrate 20 may each be a diced surface that is cut with a dicing blade.

In the first embodiment, the substrate 20 may be a multilayer substrate as in the second embodiment.

In the method for manufacturing the semiconductor light emitting device 10 of the first embodiment, after the transparent layer 890 encapsulates the semiconductor light emitting element 60, the semiconductor light emitting element 60 is mounted on the substrate 820. Instead, for example, after the semiconductor light emitting element 60 is mounted on the substrate 820, the transparent layer 890 may encapsulate the semiconductor light emitting element 60.

In the second embodiment, the main surface cover 227 may be omitted from the second transparent member 220. At least one of the side surface covers 229A to 229C may be omitted from the second transparent member 220. That is, it is sufficient that the second transparent member 220 includes at least the light emitting-side cover 228.

In the second embodiment, the positional relationship between the light emitting-side cover 228 of the second transparent member 220 and the substrate side surface 23 of the substrate 20 may be changed in any manner. In an example, the distal surface of the light emitting-side cover 228 (surface of the light emitting-side cover 228 located closest to the substrate back surface 22 in the z-direction) may be disposed toward the substrate main surface 21 from the substrate back surface 22. It is preferred that the distal surface of the light emitting-side cover 228 is located in the substrate side surface 23 closer to the substrate back surface 22 than the metal layer 27 in the z-direction.

In the second embodiment, the positional relationship of the side surface covers 229A to 229C of the second transparent member 220 and the substrate side surface 23 of the substrate 20 may be changed in any manner. In an example, the distal surface of the side surface covers 229A to 229C (surfaces of the side surface covers 229A to 229C located closest to the substrate back surface 22 in the z-direction) may be disposed toward the substrate main surface 21 from the substrate back surface 22. It is preferred that the distal surfaces of the side surface covers 229A to 229C are located in the substrate side surfaces 24 to 26 in the z-direction closer to the substrate back surface 22 than the metal layer 27.

In the second embodiment, the thickness of the light emitting-side cover 228 may be greater than or equal to the thickness of the side surface covers 229A to 229C. In other words, the distance between the first transparent side surface 213 and the second transparent side surface 223 in the y-direction may be greater than or equal to the distance between the first transparent side surface 214 and the second transparent side surface 224 in the y-direction, the distance between the first transparent side surface 215 and the second transparent side surface 225 in the x-direction, and the distance between the first transparent side surface 216 and the second transparent side surface 226 in the x-direction.

In the second embodiment, the thickness of each of the side surface covers 229A to 229C may be changed in any manner. In an example, the thickness may differ between the side surface cover 229A, the side surface cover 229B, and the side surface cover 229C.

In the second embodiment, at least one of the switching element 70 and the capacitor 80 may be disposed outward from the first transparent member 210 and encapsulated by the second transparent member 220.

In the third embodiment, the positional relationship between the light emitting-side cover 307 of the transparent member 300 and the substrate side surface 23 of the substrate 20 may be changed in any manner. In an example, the distal surface of the light emitting-side cover 307 (surface of the light emitting-side cover 307 located closest to the substrate back surface 22 in the z-direction) may be located in the substrate side surface 23 closer to the substrate main surface 21 than the metal layer 27 in the z-direction.

In the third embodiment, the positional relationship of the side surface covers 308A to 308C of the transparent member 300 with the substrate side surface 23 of the substrate 20 may be changed in any manner. In an example, the distal surfaces of the side surface covers 308A to 308C (surfaces of the side surface covers 308A to 308C located closest to the substrate back surface 22 in the z-direction) may be located in the substrate side surfaces 24 to 26 closer to the substrate main surface 21 than the metal layer 27 in the z-direction.

In the third embodiment, the thickness of the light emitting-side cover 307 may be greater than or equal to the thickness of each of the side surface covers 308A to 308C. In other words, the distance between the transparent side surface 303 and the substrate side surface 23U in the y-direction may be greater than or equal to the distance between the transparent side surface 304 and the substrate side surface 24U in the y-direction, the distance between the transparent side surface 305 and the substrate side surface 25U in the x-direction, and the distance between the transparent side surface 306 and the substrate side surface 26U in the x-direction.

In the second and third embodiments, the switching element 70 may be configured to be attached to the outside of the semiconductor light emitting device 10.

In the second and third embodiments, the substrate 20 may be a single-layer substrate as in the first embodiment.

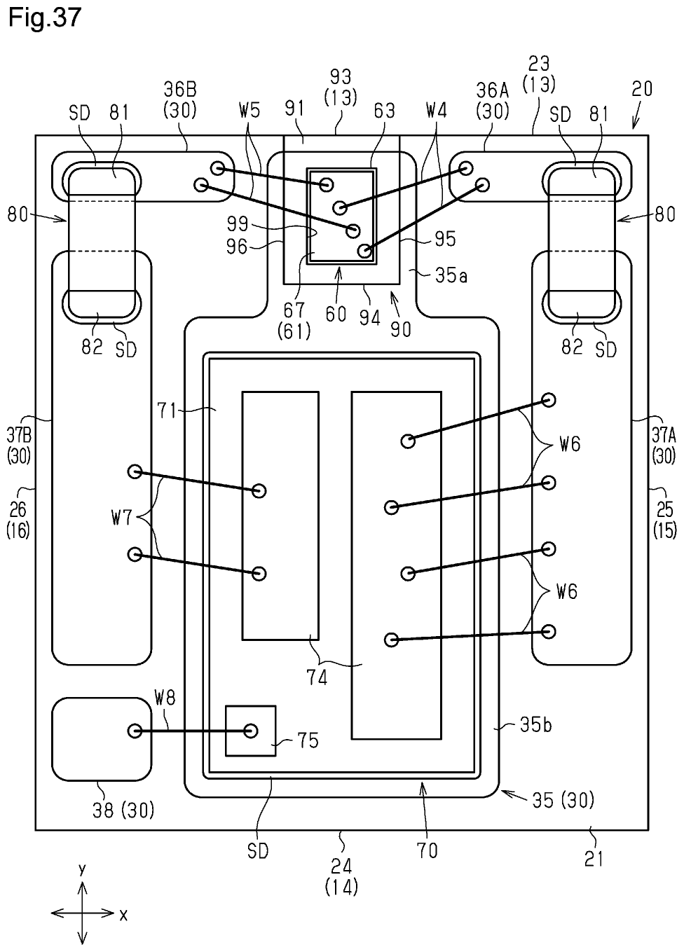

In each embodiment, the structure of the main surface wiring lines 30 of the substrate 20 may be changed in any manner. In an example, as shown in FIG. 37, the main surface wiring lines 30 include a first drive wiring line 35, two second drive wiring lines 36A and 36B, two third drive wiring lines 37A and 37B, and a control wiring line 38.

The semiconductor light emitting element 60 and the switching element 70 are mounted on the first drive wiring line 35. The first drive wiring line 35 includes a light emitting element mount 35a, on which the semiconductor light emitting element 60 is mounted, and a switching element mount 35b, on which the switching element 70 is mounted.

The light emitting element mount 35a projects from the switching element mount 35b in the y-direction. The light emitting element mount 35a is disposed closer to the substrate side surface 23 than the switching element mount 35b in the y-direction. The light emitting element mount 35a is smaller in the dimension in the x-direction than the switching element mount 35b. The light emitting element mount 35a is smaller in the dimension in the y-direction than the switching element mount 35b.

The semiconductor light emitting element 60 is bonded to the light emitting element mount 35a by the conductive bonding material SD (not shown). Thus, the second electrode 68 is electrically connected to the light emitting element mount 35a. The transparent member 90 encapsulates the semiconductor light emitting element 60 in the same manner as the first embodiment. The transparent side surface 93, which is the transparent surface of the transparent member 90, is flush with the resin side surface 103 (not shown) of the encapsulation resin 100 and the substrate side surface 23. The transparent side surface 93 is exposed from the semiconductor light emitting device 10.

The switching element mount 35b is disposed on the substrate main surface 21 at a position closer to the substrate side surface 24 than the substrate side surface 23. As viewed in the z-direction, the switching element mount 35b is rectangular so that the short sides extend in the x-direction and the long sides extend in the y-direction.

The switching element 70 is bonded to the switching element mount 35b by the conductive bonding material SD. Thus, the first drive electrode 73 (not shown) of the switching element 70 is electrically connected to the switching element mount 35b. In the illustrated example, which differs from the embodiments described above, the second electrode 68 of the semiconductor light emitting element 60 is electrically connected to the first drive electrode 73 of the switching element 70 via the first drive wiring line 35.

The switching element 70 is disposed so that the short sides extend in the x-direction and the long sides extend in the y-direction, which differs from that of the embodiments. Hence, two second drive electrodes 74 are spaced apart in the x-direction. The control electrode 75 is located at one of the four corners of the switching element main surface 71 that is located close to the substrate side surface 24 and the substrate side surface 26.

The two second drive wiring lines 36A and 36B, which are configured to electrically connect the capacitors 80 and the semiconductor light emitting element 60, are aligned with each other in the y-direction and spaced apart from each other in the x-direction. The two second drive wiring lines 36A and 36B are separately disposed at opposite sides of the light emitting element mount 35a in the x-direction. In the illustrated example, the second drive wiring lines 36A and 36B extend in the x-direction. The two second drive wiring lines 36A and 36B are disposed at one of the two ends of the substrate main surface 21 in the y-direction located closer to the substrate side surface 23. Of the two ends of each of the second drive wiring lines 36A and 36B in the x-direction, the end located closer to the light emitting element mount 35a is disposed to overlap the switching element mount 35b as viewed in the y-direction. More specifically, a portion of each of the second drive wiring lines 36A and 36B is received in a recess formed by the switching element mount 35b and the light emitting element mount 35a.

The two third drive wiring lines 37A and 37B, which are configured to electrically connect the capacitors 80 to the switching element 70, are aligned with each other in the y-direction and spaced apart from each other in the x-direction. The two third drive wiring lines 37A and 37B are separately disposed at opposite sides of the switching element mount 35b in the x-direction. In the illustrated example, the third drive wiring lines 37A and 37B extend in the y-direction. More specifically, the third drive wiring line 37A is disposed between the switching element mount 35b and the substrate side surface 25 in the x-direction. As viewed in the y-direction, the third drive wiring line 37A is disposed to overlap the second drive wiring line 36A. The third drive wiring line 37B is disposed between the switching element mount 35b and the substrate side surface 26 in the x-direction. As viewed in the y-direction, the third drive wiring line 37B is disposed to overlap the second drive wiring line 36B.

In the illustrated example, the capacitors 80 are disposed on the substrate main surface 21 at a position closer to the substrate side surface 23 than the switching element 70. The capacitors 80 are separately disposed at opposite sides of the switching element 70 in the x-direction.

One of the capacitors 80 is disposed to extend over the second drive wiring line 36A and the third drive wiring line 37A in the y-direction. More specifically, the first terminal 81 of the capacitor 80 is bonded to the second drive wiring line 36A by the conductive bonding material SD, and the second terminal 82 of the capacitor 80 is bonded to the third drive wiring line 37A by the conductive bonding material SD.

Another one of the capacitors 80 is disposed to extend over the second drive wiring line 36B and the third drive wiring line 37B in the y-direction. More specifically, the first terminal 81 of the capacitor 80 is bonded to the second drive wiring line 36B by the conductive bonding material SD, and the second terminal 82 of the capacitor 80 is bonded to the third drive wiring line 37B by the conductive bonding material SD.

The first electrode 67 of the semiconductor light emitting element 60 is connected to the second drive wiring line 36A by one or more wires W4 and connected to the second drive wiring line 36B by one or more wires W5. The wires W4 and W5 are connected to the first electrode 67 through the opening 99 in the transparent member 90 in the same manner as the first wires W1 of the first embodiment. Thus, the wires W4 and W5 are configured to avoid interference with the transparent member 90. The wires W4 and W5 are entirely encapsulated by the encapsulation resin 100.

The second drive electrodes 74 of the switching element 70 are connected to the third drive wiring line 37A by one or more wires W6 and is connected to the third drive wiring line 37B by one or more wires W7. The wires W6 and W7 are entirely encapsulated by the encapsulation resin 100.

The control electrode 75 of the switching element 70 is electrically connected to the control wiring line 38 by a wire W8. The control wiring line 38 is disposed at one of the four corners of the substrate main surface 21 formed by the substrate side surface 24 and the substrate side surface 26. As viewed in the z-direction, the control wiring line 38 is disposed adjacent to the control electrode 75 in the x-direction. The wire W8 is entirely encapsulated by the encapsulation resin 100.

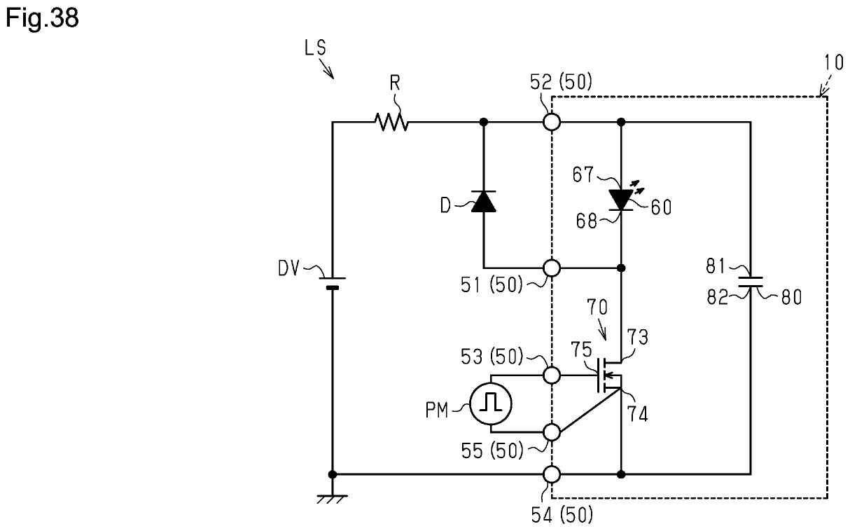

The circuit configuration of the semiconductor light emitting device 10 in the modified example shown in FIG. 37 will now be described with reference to FIG. 38. FIG. 38 shows an example of the circuit configuration of the laser system LS in which the semiconductor light emitting device 10 is used.

As shown in FIG. 38, in the semiconductor light emitting device 10, the capacitor 80 is connected in parallel to the semiconductor light emitting element 60 and the switching element 70 that are connected in series. More specifically, the second electrode 68, serving as a cathode electrode of the semiconductor light emitting element 60, is connected to the first drive electrode 73, serving as a drain electrode of the switching element 70. The first electrode 67, serving as an anode electrode of the semiconductor light emitting element 60, is connected to the first terminal 81 of the capacitor 80. The second drive electrode 74, serving as a source electrode of the switching element 70, is connected to the second terminal 82 of the capacitor 80.

The semiconductor light emitting device 10 includes, as the external electrodes 50, the connection electrode 51, the power supply electrode 52, the control electrode 53, the ground electrode 54, and a source connection electrode 55.

The connection electrode 51 is connected to the second electrode 68 of the semiconductor light emitting element 60 and the first drive electrode 73 of the switching element 70. The power supply electrode 52 is connected to the first terminal 81 of the capacitor 80 and the first electrode 67 of the semiconductor light emitting element 60. The ground electrode 54 is connected to the second terminal 82 of the capacitor 80 and the second drive electrode 74 of the switching element 70. The source connection electrode 55 is connected to the second drive electrode 74 of the switching element 70. The control electrode 53 is connected to the control electrode 75, serving as a gate electrode of the switching element 70.

The positive terminal of the drive power supply DV is connected to the power supply electrode 52 through the current limiting resistor R. The negative terminal of the drive power supply DV is connected to the ground electrode 54.

The driver circuit PM is connected to the control electrode 53 and the source connection electrode 55.

The diode D is connected in antiparallel to the semiconductor light emitting element 60. The cathode electrode of the diode D is connected between the current limiting resistor R and the power supply electrode 52. The anode electrode of the diode D is connected to the connection electrode 51.

The laser system LS having the above configuration operates as follows. When the switching element 70 is switched off by a control signal of the driver circuit PM, the drive power supply DV stores power in the capacitor 80. When the switching element 70 is switched on by a control signal of the driver circuit PM, the capacitor 80 is discharged so that a current flows to the semiconductor light emitting element 60. As a result, the semiconductor light emitting element 60 outputs a pulse laser beam.

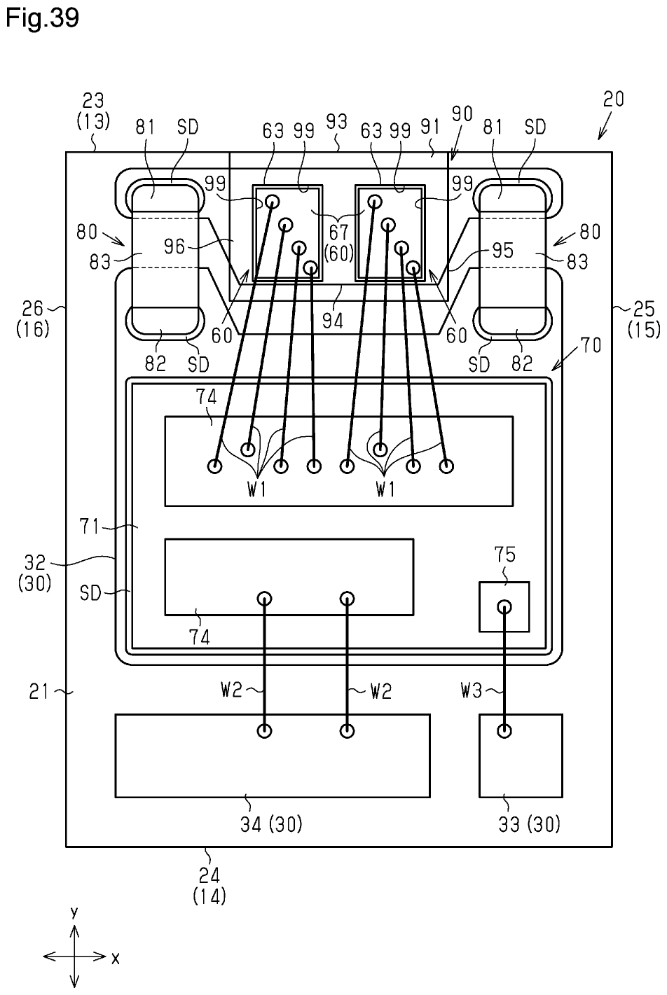

In the embodiments, the semiconductor light emitting device 10 includes one semiconductor light emitting element 60. Alternatively, the semiconductor light emitting device 10 may include multiple semiconductor light emitting elements 60. In an example, as shown in FIG. 39, two semiconductor light emitting elements 60 are aligned with each other in the y-direction and spaced apart from each other in the x-direction. In the x-direction, the two semiconductor light emitting elements 60 are disposed between the two capacitors 80, which are spaced apart in the x-direction. Each semiconductor light emitting element 60 is spaced apart from the capacitors 80 in the x-direction. The semiconductor light emitting element 60 is mounted on the first main surface wiring line 31. More specifically, the light emitting element back surface 62 of the semiconductor light emitting element 60 is bonded to the first main surface wiring line 31 by a conductive bonding material. Since the second electrode 68 is formed on the light emitting element back surface 62, the second electrode 68 of the semiconductor light emitting element 60 is electrically connected to the first main surface wiring line 31.

The transparent member 90 encapsulates the two semiconductor light emitting elements 60. The transparent member 90 of the modified example and the transparent member 90 of the first embodiment are formed from the same material. The transparent member 90 is spaced apart from each capacitor 80 in the x-direction.

The transparent member 90 includes two openings 99 that are separately open to the light emitting element main surfaces 61 of the two semiconductor light emitting elements 60 in the z-direction. Each opening 99 is open to the first electrode 67 of the light emitting element main surface 61 in the z-direction.

The first electrode 67 of each semiconductor light emitting element 60 is connected to the second drive electrode 74 of the switching element 70 by multiple first wires W1. The first wires W1 are connected to the first electrode 67 of the semiconductor light emitting element 60 through the opening 99 in the transparent member 90.

Although not shown, the encapsulation resin 100 encapsulates the transparent member 90 together with the switching element 70, the capacitors 80, and the wires W1 to W3. That is, the encapsulation resin 100 encapsulates the two semiconductor light emitting elements 60. The encapsulation resin 100 fills the openings 99 in the transparent member 90.

The transparent member 90 may be separately provided for each of the two semiconductor light emitting elements 60. The transparent member 90 provided for one of the semiconductor light emitting elements 60 and the transparent member 90 provided for the other semiconductor light emitting element 60 may be spaced apart from each other in the x-direction or may be in contact with each other in the x-direction.

When multiple semiconductor light emitting elements 60 are arranged, semiconductor light emitting elements 60 that are adjacent in the arrangement direction may be in contact with each other. In this case, the transparent member 90 is not disposed between the semiconductor light emitting elements 60 located adjacent in the arrangement direction of the semiconductor light emitting elements 60.

In the illustrated example, the two openings 99 are formed in the transparent member 90 in accordance with the two semiconductor light emitting elements 60. Alternatively, the transparent member 90 may include a single opening 99 that is open to the first electrode 67 of each semiconductor light emitting element 60.

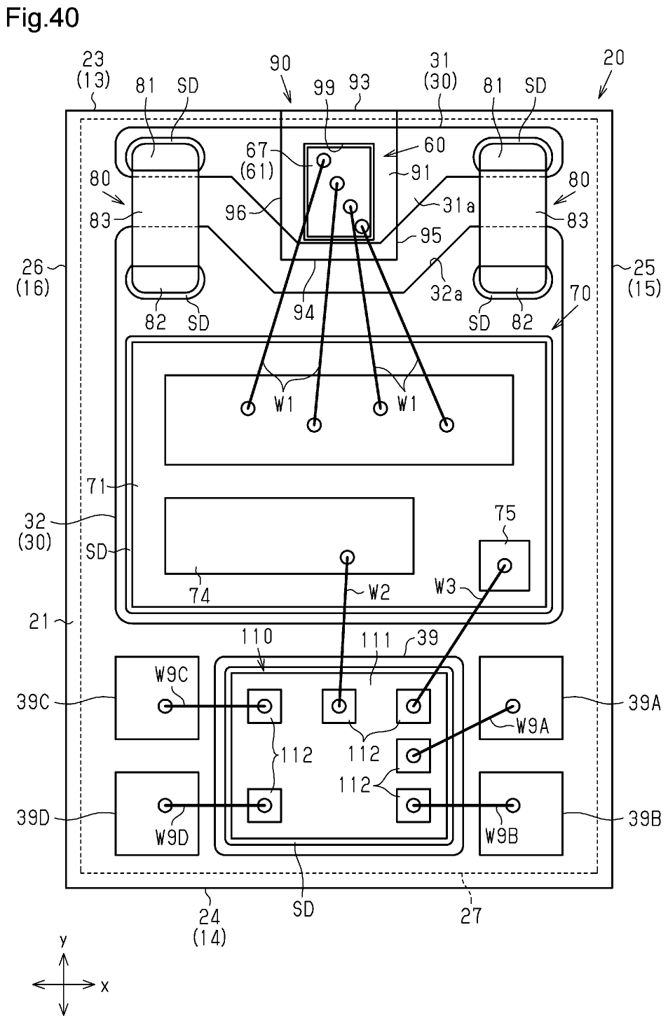

In each embodiment, the semiconductor light emitting device 10 may further include a driver circuit 110 configured to drive the switching element 70. In an example, as shown in FIG. 40, the driver circuit 110 and the semiconductor light emitting element 60 are disposed at opposite sides of the switching element 70 in the y-direction. The driver circuit 110 transmits a control signal for controlling the switching element 70 to the control electrode 75 of the switching element 70 and includes a substrate on which a control signal generation circuit or the like is formed. The driver circuit 110 includes a driver main surface 111 facing the same direction as the substrate main surface in the z-direction. Multiple (in the illustrated example, six) driver electrodes 112 are formed on the driver main surface 111.

When the semiconductor light emitting device 10 includes the driver circuit 110, the main surface wiring lines 30 include a driver mount wiring line 39 and driver wiring lines 39A to 39D.

The driver mount wiring line 39 is a wiring line on which the driver circuit 110 is mounted. The driver circuit 110 is bonded to the driver mount wiring line 39 by a conductive bonding material. The driver circuit 110 includes a driver back surface facing a direction opposite to the driver main surface 111 and including a ground electrode. The ground electrode of the driver circuit 110 is electrically connected to the driver mount wiring line 39.

The driver wiring lines 39A to 39D are disposed at opposite sides of the driver mount wiring line 39 in the x-direction. More specifically, the driver wiring lines 39A and 39B are disposed on the substrate main surface 21 at a position closer to the substrate side surface 25 than the driver mount wiring line 39. The driver wiring lines 39C and 39D are disposed on the substrate main surface 21 at a position closer to the substrate side surface 26 than the driver mount wiring line 39.

The driver wiring lines 39A to 39D are separately connected to the driver electrodes 112 of the driver circuit 110 by fourth wires W9A to W9D.

The driver circuit 110 is electrically connected to the switching element 70. More specifically, the second drive electrode 74 of the switching element 70 is connected to one of the driver electrodes 112 of the driver circuit 110 by the second wire W2. The control electrode 75 of the switching element 70 is connected to another one of the driver electrodes 112 of the driver circuit 110 by the third wire W3.

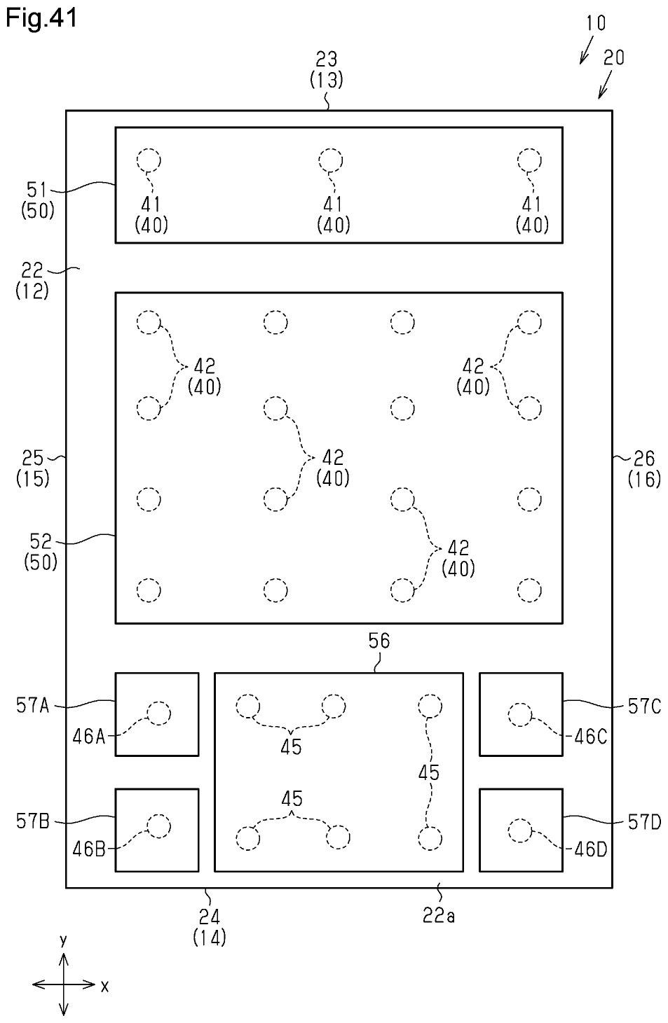

As shown in FIG. 41, the substrate back surface 22 includes, as the external electrodes 50, a driver ground electrode 56, which is electrically connected to the driver mount wiring line 39, and driver electrodes 57A to 57D, which are electrically connected to the driver wiring lines 39A to 39D, respectively. The control electrode 53 and the ground electrode 54 are omitted from the substrate back surface 22. The driver ground electrode 56 and the driver electrodes 57A to 57D are disposed on the substrate back surface 22 at a position located closer to the substrate side surface 24 than the connection electrode 51 and the power supply electrode 52. The driver electrodes 57A to 57D are disposed at opposite sides of the driver ground electrode 56 in the x-direction. More specifically, the driver electrodes 57A and 57B are disposed on the substrate back surface 22 at a position closer to the substrate side surface 25 than the driver ground electrode 56. The driver electrodes 57C and 57D are disposed on the substrate back surface 22 at a position closer to the substrate side surface 26 than the driver ground electrode 56.

As viewed in the z-direction, the driver ground electrode 56 is disposed to overlap the driver mount wiring line 39 and connected to the driver mount wiring line 39 by fifth connection wiring lines 45.

As viewed in the z-direction, the driver electrode 57A is disposed to overlap the driver wiring line 39A and connected to the driver wiring line 39A by a sixth connection wiring line 46A. As viewed in the z-direction, the driver electrode 57B is disposed to overlap the driver wiring line 39B and connected to the driver wiring line 39B by a sixth connection wiring line 46B. As viewed in the z-direction, the driver electrode 57C is disposed to overlap the driver wiring line 39C and connected to the driver wiring line 39C by a sixth connection wiring line 46C. As viewed in the z-direction, the driver electrode 57D is disposed to overlap the driver wiring line 39D and connected to the driver wiring line 39D by a sixth connection wiring line 46D.

Although not shown, the encapsulation resin 100 encapsulates the transparent member 90 together with the switching element 70, the capacitor 80, the driver circuit 110, and the wires W1 to W3 and W9A to W9D.

In the modified example shown in FIGS. 40 and 41, the semiconductor light emitting device 10 includes the driver circuit 110. With this structure, the conductive path between the driver circuit 110 and the switching element 70 is shorter than with a structure in which the driver circuit 110 is disposed outside the semiconductor light emitting device 10. Accordingly, inductance caused by the length of the conductive path is reduced.

In each embodiment, the semiconductor light emitting element 60 is disposed between the two capacitors 80 in the x-direction. The positional relationship of the capacitors 80 with the semiconductor light emitting element 60 is not limited to this. In an example, the semiconductor light emitting element 60 may be disposed on the substrate main surface 21 at a position closer to the substrate side surface 25 than the two capacitors 80 or at a position closer to the substrate side surface 26 than the two capacitors 80.

In each embodiment, the capacitor 80 may be configured to be attached to the outside of the semiconductor light emitting device 10.

In each embodiment, the structure of the external electrodes 50 may be changed in any manner. Thus, the semiconductor light emitting device 10 is not limited to the package structure of a front surface mount type.

In each embodiment, the back surface insulation layer 22a may be omitted from the substrate back surface 22 of the substrate 20.

In each embodiment, the connection wiring lines 40 are disposed in the substrate 20. Instead, the connection wiring lines 40 may be disposed on the substrate side surfaces 23 to 26 to connect the main surface wiring lines 30 and the external electrodes 50.

In the second and third embodiments, the metal layer 27 of the intermediate layer 20C may be connected to the ground electrode 54. In an example, when the metal layer 27 is connected to the fourth connection wiring line 44, the metal layer 27 is connected to the ground electrode 54. Also, in the first embodiment, when the substrate 20 includes a multilayer substrate as in the second and third embodiments, the metal layer 27 of the intermediate layer 20C may be connected to the ground electrode 54.

In the first embodiment, both the switching element 70 and the capacitor 80 may be configured to be attached to the outside of the semiconductor light emitting device 10. In other words, the semiconductor light emitting device 10 may be configured to include the substrate 20, the semiconductor light emitting element 60 mounted on the substrate main surface 21, the wires electrically connected to the semiconductor light emitting element 60, the transparent member 90, and the encapsulation resin 100.

In each embodiment, at least one of the switching element 70 and the capacitor 80 may be mounted on the substrate back surface 22 of the substrate 20. In this case, in the z-direction, the external electrodes 50 are disposed at a position further from the substrate back surface 22 than the switching element 70 and the capacitor 80, which are mounted on the substrate back surface 22, in a direction away from the substrate main surface 21. In an example, when the switching element 70 and the capacitor 80, mounted on the substrate back surface 22, are mounted on the substrate back surface 22, the substrate back surface 22 includes a frame-shaped insulation layer (not shown) surrounding the switching element 70 and the capacitor 80. The external electrodes 50 are formed on a surface of the insulation layer facing the same direction as the substrate back surface 22. The connection wiring lines 40 extend through the insulation layer and are connected to the external electrodes 50.

In the second and third embodiments, at least one of the switching element 70 and the capacitor 80 may be mounted on a surface of the main surface layer 20A of the substrate 20 facing the same direction as the substrate back surface 22. At least one of the switching element 70 and the capacitor 80 may be mounted on a surface of the intermediate layer 20C of the substrate 20 facing the same direction as the substrate back surface 22. At least one of the switching element 70 and the capacitor 80 may be mounted on a surface of the back surface layer 20B of the substrate 20 facing the same direction as the substrate main surface 21. More specifically, at least one of the switching element 70 and the capacitor 80 may be disposed in the substrate 20.

In the first embodiment, where the substrate 20 includes a multilayer substrate as in the second and third embodiments, at least one of the switching element 70 and the capacitor 80 may be disposed in the substrate 20.

In the first embodiment, while the transparent side surface 93 of the transparent member 90 is mirror-finished, the resin side surface 103 and the substrate side surface 23 may be configured not to be mirror-finished. In this case, for example, blast polishing may be used to propel polishing material toward only the transparent side surface 93 so that the transparent side surface 93 is mirror-finished. As described above, the transparent side surface 93 may be a mirror-finished smooth surface.

In the first embodiment, the transparent side surface 93 of the transparent member 90 and the resin side surface 103 of the encapsulation resin 100 do not necessarily have to be mirror-finished.

In each embodiment, the semiconductor light emitting device 10 may include a diode D connected in antiparallel to the semiconductor light emitting element 60.

In each embodiment, the capacitor 80 is connected in series to the semiconductor light emitting element 60. Alternatively, the capacitor 80 may be connected in parallel to the semiconductor light emitting element 60.

### CLAUSES

The technical aspects that are understood from the embodiments and the modified examples will be described below.
A1. A semiconductor light emitting device, comprising:
a substrate including a substrate main surface;
a semiconductor light emitting element mounted on the substrate main surface, the semiconductor light emitting element including a light emitting element main surface facing the same direction as the substrate main surface and a light emitting surface facing a direction intersecting the light emitting element main surface;
a drive element mounted on the substrate main surface and used to drive the semiconductor light emitting element;
a transparent member covering the light emitting surface, the transparent member being formed from a material having a greater linear expansion coefficient than a material of the substrate and being transmissive to light emitted from the light emitting surface; and
an encapsulation resin encapsulating the semiconductor light emitting element and the drive element, the encapsulation resin being formed of a material having a smaller linear expansion coefficient than the material of the transparent member.
A2. The semiconductor light emitting device according to clause A1, wherein
the drive element includes a switching element and a capacitor,
a first main surface wiring line and a second main surface wiring line are separately disposed on the substrate main surface,
the semiconductor light emitting element is mounted on the first main surface wiring line,
the switching element is mounted on the second main surface wiring line, and
the capacitor is mounted on the first main surface wiring line and the second main surface wiring line so as to extend over the first main surface wiring line and the second main surface wiring line.
A3. The semiconductor light emitting device according to clause A1, wherein
the drive element includes a switching element,
a first main surface wiring line and a second main surface wiring line are disposed on the substrate main surface,
the semiconductor light emitting element is mounted on the first main surface wiring line,
the switching element is mounted on the second main surface wiring line,
the switching element includes a first drive electrode electrically connected to the first main surface wiring line, a second drive electrode electrically connected to the semiconductor light emitting element, and a control electrode,
a third main surface wiring line and a fourth main surface wiring line are further disposed on the substrate main surface,
the third main surface wiring line is electrically connected to the control electrode, and
the fourth main surface wiring line is electrically connected to the second drive electrode.
A4. The semiconductor light emitting device according to clause A1, wherein
the drive element includes a switching element including a switching element main surface facing the same direction as the substrate main surface,
a main surface electrode is disposed on the light emitting element main surface of the semiconductor light emitting element,
a drive electrode is disposed on the switching element main surface of the switching element, and
the main surface electrode and the drive electrode are connected by a wire.
A5. The semiconductor light emitting device according to any one of clauses A1 to A4, wherein
the drive element includes a capacitor,
the capacitor is entirely covered by the encapsulation resin,
the transparent member is disposed on and around the semiconductor light emitting element and covers the light emitting surface,
the capacitor is spaced apart from the transparent member, and
the encapsulation resin is disposed between the capacitor and the transparent member.
A6. The semiconductor light emitting device according to any one of clauses A1 to A4, wherein
the drive element includes a switching element,
the switching element is entirely covered by the encapsulation resin,
the transparent member is disposed on and around the semiconductor light emitting element and covers the light emitting surface,
the switching element is spaced apart from the transparent member, and
the encapsulation resin is disposed between the switching element and the transparent member.
A7. The semiconductor light emitting device according to any one of clauses A1 to A6, wherein
the semiconductor light emitting element includes a light emitting element back surface facing a direction opposite to the substrate main surface,
the transparent member includes a transparent back surface facing a direction opposite to the substrate main surface, and
the light emitting element back surface is flush with the transparent back surface.
A8. The semiconductor light emitting device according to clause A1, wherein
the drive element includes a switching element including a switching element main surface facing the same direction as the substrate main surface,
the transparent member includes a transparent main surface facing the same direction as the substrate main surface, and
a distance between the substrate main surface and the transparent main surface is shorter in a thickness-wise direction of the substrate than a distance between the substrate main surface and the switching main surface.
A9. The semiconductor light emitting device according to clause A1, wherein
the drive element includes a capacitor including a capacitor main surface facing the same direction as the substrate main surface,
the transparent member includes a transparent main surface facing the same direction as the substrate main surface,
a distance between the substrate main surface and the transparent main surface is shorter in a thickness-wise direction of the substrate than a distance between the substrate main surface and the capacitor main surface.
A10. A semiconductor light emitting device, comprising:
a substrate including a substrate main surface;
a semiconductor light emitting element mounted on the substrate main surface, the semiconductor light emitting element including a light emitting element main surface facing the same direction as the substrate main surface and a light emitting surface facing a direction intersecting the light emitting element main surface;
a wire electrically connected to the semiconductor light emitting element;
a transparent member covering the light emitting surface and being formed from a material having a greater linear expansion coefficient than a material of the substrate; and
an encapsulation resin encapsulating the wire and being formed from a material having a smaller linear expansion coefficient than the material of the transparent member.

With the structure described in clause A10, the encapsulation resin, which encapsulates the wire, has a smaller linear expansion coefficient than the transparent member. Therefore, the difference in linear expansion coefficient between the encapsulation resin and the substrate is less than the difference in linear expansion coefficient between the transparent member and the substrate. Accordingly, when the temperature of the semiconductor light emitting device is changed, the differences in thermal expansion amount and thermal contraction amount between the encapsulation resin and the substrate are less than those between the transparent member and the substrate. This reduces the load on the wire caused by changes in the temperature of the semiconductor light emitting device.
B1. A method for manufacturing a semiconductor light emitting device, the method comprising:
a step of encapsulating a semiconductor light emitting element with a transparent layer;
a step of mounting the semiconductor light emitting element encapsulated by the transparent layer and a drive element on a substrate main surface of a substrate; and
a step of forming a resin layer that encapsulates the semiconductor light emitting element and the drive element, wherein
the transparent layer is greater in linear expansion coefficient than the substrate, and
the resin layer is smaller in linear expansion coefficient than the transparent layer.
B2. The method according to clause B1, wherein the resin layer encapsulates the transparent layer together with the semiconductor light emitting element and the drive element.
B3. The method according to clause B2, wherein
the semiconductor light emitting element includes a light emitting element main surface and a main surface electrode formed on the light emitting element main surface,
the method further comprising:
   a step of forming an opening in the transparent layer to expose the main surface electrode of the semiconductor light emitting element; and
   a step of connecting the first wire to the main surface electrode through the opening, and
the resin layer fills the opening and encapsulates the first wire together with the semiconductor light emitting element and the drive element.
B4. The semiconductor light emitting device according to clause B3, wherein
the drive element includes a switching element including a switching element main surface facing the same direction as the substrate main surface and a drive electrode disposed on the switching element main surface, and
the first wire connects the main surface electrode and the drive electrode.
B5. The method according to clause B4, further comprising:
a step of connecting a second wire to the drive electrode,
wherein the resin layer encapsulates the second wire together with the semiconductor light emitting element and the drive element.
B6. The method according to clause B4 or B5, wherein
the switching element includes a control electrode,
the method further comprising:
   a step of connecting the third wire to the control electrode, and
the resin layer encapsulates the third wire together with the semiconductor light emitting element and the drive element.
B7. The method according to clause B1, wherein
the semiconductor light emitting element includes a light emitting element main surface facing the same direction as the substrate main surface and a light emitting surface facing a direction intersecting the light emitting element main surface, and
the method further comprises:
a step of cutting the resin layer, the substrate, and the transparent layer; and
a step of mirror-finishing a side surface of the transparent layer, the side surface facing the same direction as the light emitting surface of the semiconductor light emitting element.
B8. The method according to clause B1, wherein
the semiconductor light emitting element includes a light emitting element main surface facing the same direction as the substrate main surface and a light emitting surface facing a direction intersecting the light emitting element main surface, and
the method further comprising:
   a step of cutting the resin layer, the substrate, and the transparent layer; and
   a step of mirror-finishing a side surface of each of the resin layer, the substrate, and the transparent layer, the side surface facing the same direction as the light emitting surface of the semiconductor light emitting element.
C1. A semiconductor light emitting device, comprising:
a substrate including a substrate main surface;
a semiconductor light emitting element mounted on the substrate main surface and including a light emitting surface facing a direction intersecting the substrate main surface; and
a transparent member encapsulating the semiconductor light emitting element and being light-transmissive, wherein
the substrate includes a light emitting-side substrate side surface facing the same direction as the light emitting surface,
the transparent member includes a light emitting-side cover covering the light emitting-side substrate side surface,
the light emitting-side cover includes a transparent surface facing the same direction as the light emitting surface, and
the transparent surface includes a mirror-finished smooth surface.
C2. The semiconductor light emitting device according to clause C1, wherein
the substrate includes a substrate side surface intersecting the light emitting-side substrate side surface as viewed in a thickness-wise direction of the substrate,
the transparent member includes a side surface cover covering the substrate side surface, and
the side surface cover includes a diced side surface having a cut mark, and
the transparent surface is flatter than the diced side surface.
C3. The semiconductor light emitting device according to clause C2, wherein
as viewed in the thickness-wise direction of the substrate, a distance between the light emitting-side substrate side surface and the transparent surface is shorter than a distance between the substrate side surface and the diced side surface.
C4. The semiconductor light emitting device according to any one of clauses C1 to C3, wherein
the substrate includes a multilayer substrate including a main surface layer, a back surface layer, and an intermediate layer,
the main surface layer includes the substrate main surface,
the back surface layer includes a substrate back surface that faces a direction opposite to the substrate main surface,
the intermediate layer is disposed between the main surface layer and the back surface layer in the thickness-wise direction of the substrate, and
the intermediate layer includes a metal layer.
C5. The semiconductor light emitting device according to clause C4, wherein
as viewed in the thickness-wise direction of the substrate, the metal layer is disposed to overlap at least the semiconductor light emitting element.
C6. The semiconductor light emitting device according to clause C4 or C5,
wherein the metal layer is disposed inward from the light emitting-side substrate side surface and the substrate side surface as viewed in the thickness-wise direction of the substrate.
C7. The semiconductor light emitting device according to any one of clauses C4 to C6, wherein an external electrode is disposed on the substrate back surface and is electrically connected to the semiconductor light emitting element.
C8. The semiconductor light emitting device according to clause C7, wherein
a main surface wiring line is disposed on the substrate main surface and is electrically connected to the semiconductor light emitting element,
the substrate includes a connection wiring line extending through the substrate in the thickness-wise direction of the substrate, the connection wiring line connecting the main surface wiring line and the external electrode,
the metal layer includes an inner surface defining a through hole that separates the metal layer from the connection wiring line,
an insulation layer is disposed between the connection wiring line and the inner surface.
C9. The semiconductor light emitting device according to any one of clauses C4 to C8, wherein the substrate back surface is covered by a back surface insulation layer.
C10. The semiconductor light emitting device according to any one of clauses C4 to C9, wherein the light emitting-side cover covers at least the main surface layer and the intermediate layer in the light emitting-side substrate side surface.
C11. The semiconductor light emitting device according to clause C1, wherein
the light emitting-side cover entirely covers the light emitting-side substrate side surface.
C12. The semiconductor light emitting device according to any one of clauses C1 to C11, further comprising:
a drive element mounted on the substrate main surface and used to drive the semiconductor light emitting element.
C13. The semiconductor light emitting device according to clause C12, wherein the transparent member encapsulates the drive element.
C14. The semiconductor light emitting device according to clause C12 or C13, wherein the drive element includes at least one of a switching element and a capacitor.
C15. The semiconductor light emitting device according to clause C1, wherein the transparent member includes
a first transparent member disposed on the substrate main surface and encapsulating the semiconductor light emitting element, and
a second transparent member encapsulating the first transparent member and including the light emitting-side cover.
C16. The semiconductor light emitting device according to clause C15, further comprising:
a drive element mounted on the substrate main surface and used to drive the semiconductor light emitting element,
wherein the first transparent member encapsulates the drive element.
C17. The semiconductor light emitting device according to clause C15 or C16, wherein the second transparent member entirely covers the first transparent member.
C18. The semiconductor light emitting device according to any one of clauses C15 to C17, wherein
the first transparent member includes a first transparent main surface facing the same direction as the substrate main surface, a first light emitting side surface facing the same direction as the light emitting surface, and a first transparent side surface intersecting the light emitting surface as viewed in the thickness-wise direction of the substrate,
the second transparent member includes a main surface cover covering the first transparent main surface, a light emitting-side cover covering the first light emitting side surface, and a side surface cover covering the first transparent side surface,
the main surface cover includes a second transparent main surface facing the same direction as the first transparent main surface,
the light emitting-side cover includes the transparent surface,
the side surface cover includes a diced side surface having a cut mark, and
a distance between the first light emitting side surface and the transparent surface is shorter than a distance between the first transparent side surface and the diced side surface.
C19. The semiconductor light emitting device according to clause C18, wherein a distance between the first transparent main surface and the second transparent main surface is shorter than a distance between the first transparent side surface and the diced side surface.
C20. The semiconductor light emitting device according to clause C1, wherein
the substrate includes a substrate back surface facing a direction opposite to the substrate main surface,
the light emitting-side substrate side surface includes a first side surface located toward the substrate main surface and a second side surface located closer to the substrate back surface than the first side surface,
the light emitting-side substrate side surface is stepped so that the first side surface is located inward from the second side surface,
the transparent member covers the first side surface, and
the transparent surface is flush with the second side surface.
D1. A method for manufacturing a semiconductor light emitting device, the method comprising:
a step of preparing semiconductor light emitting assemblies including a substrate including a substrate main surface and a substrate side surface intersecting the substrate main surface, a semiconductor light emitting element mounted on the substrate main surface and including a light emitting surface facing a direction intersecting the substrate main surface, and a first transparent layer encapsulating the semiconductor light emitting element and transmitting light;
a step of forming a second transparent layer encapsulating the first transparent layer and the substrate side surface of the substrate in the semiconductor light emitting assemblies;
a step of singulating the semiconductor light emitting assemblies by cutting the second transparent layer; and
a step of polishing a transparent surface of the second transparent layer, the transparent surface facing the same direction as the light emitting surface.
D2. A method for manufacturing a semiconductor light emitting device, the method comprising:
a step of preparing a substrate including a substrate main surface;
a step of mounting semiconductor light emitting elements on the substrate main surface, each of the semiconductor light emitting elements including a light emitting surface facing a direction intersecting the substrate main surface;
a step of forming a slit in the substrate so as to define and singulate the semiconductor light emitting elements;
a step of forming a transparent layer encapsulating the semiconductor light emitting elements and filling the slit;
a step of cutting the transparent layer and the substrate along the slit; and
a step of mirror-finishing a transparent surface of the transparent layer, the transparent surface facing the same direction as the light emitting surface, and a light emitting-side substrate side surface of the substrate, the light emitting-side substrate side surface facing the same direction as the light emitting surface.
D3. The method according to clause D2, wherein
the substrate has a multilayer structure including a main surface layer, a back surface layer, and an intermediate layer,
the main surface layer includes the substrate main surface,
the back surface layer includes a substrate back surface that faces a direction opposite to the substrate main surface,
the intermediate layer is disposed between the main surface layer and the back surface layer in the thickness-wise direction of the substrate, and
the slit includes a bottom located closer to the substrate back surface than a border between the intermediate layer and the back surface layer.

### Background Art Related to Clauses C and D

A conventional semiconductor light emitting device of a side surface light emitting type includes, for example, a substrate such as a glass epoxy substrate or a ceramic substrate, a semiconductor light emitting element of a side surface light emitting type mounted on the substrate, and a transparent member encapsulating the semiconductor light emitting element (refer to, for example, Japanese National Phase Laid-Open Patent Publication No. 2015-510277). Light from the semiconductor light emitting element is emitted through the transparent member.

### Technical Problem Solved by Clauses C and D

Such a conventional semiconductor light emitting device is singulated by cutting the substrate and the transparent member with a dicing blade. Thus, the substrate includes a substrate side surface facing the same direction as a light emitting surface of the semiconductor light emitting element. The transparent member includes a transparent side surface facing the same direction as the light emitting surface. The substrate side surface is flush with the transparent side surface. The transparent side surface is mirror-polished to limit decreases in the output of light emitted from the semiconductor light emitting device. In this case, the substrate side surface is also mirror-finished.

When the transparent side surface and the substrate side surface are simultaneously mirror-finished, dust may be produced from the substrate side surface during the mirror-finishing and collect on a mirror-finishing machine. This may form processing marks (polish marks) on the transparent side surface. As a result, when light from the semiconductor light emitting element transmits through the transparent side surface, the light diffuses on the processing marks of the transparent side surface. This reduces optical output.

### REFERENCE SIGNS LIST

10) semiconductor light emitting device
20) substrate
20A) main surface layer
20B) back surface layer
20C) intermediate layer
27) metal layer
27a) through hole
28) insulation layer
21) substrate main surface
22) substrate back surface
23) substrate side surface (light emitting-side substrate side surface)
24 to 26) substrate side surface
30) main surface wiring line
31) first main surface wiring line
32) second main surface wiring line
33) third main surface wiring line (main surface control wiring line)
34) fourth main surface wiring line (main surface drive wiring line)
40) connection wiring line
50) external electrode
53) control electrode
60) semiconductor light emitting element
61) light emitting element main surface
62) light emitting element back surface
63) light emitting element side surface (light emitting surface)
67) first electrode (main surface electrode)
70) switching element (drive element)
71) switching element main surface
73) first drive electrode
74) second drive electrode (drive electrode)
75) control electrode
80) capacitor (drive element)
83) capacitor main surface
90) transparent member
91) transparent main surface
92) transparent back surface
93) transparent side surface (transparent surface)
94 to 96) transparent side surface (diced side surface)
97) transparent portion (light emitting-side cover)
98) cover
99) opening
100) encapsulation resin
103) resin side surface
200) transparent member
210) first transparent member
211) first transparent main surface
213) first transparent side surface (first light emitting side surface)
214 to 216) first transparent side surface
220) second transparent member
221) second transparent main surface
223) second transparent side surface (transparent surface)
224 to 226) second transparent side surface (diced surface)
227) main surface cover
228) light emitting-side cover
229A to 229C) side surface cover
300) transparent member
301) transparent main surface
302) transparent back surface
303) transparent side surface (transparent surface)
304 to 306) transparent side surface (diced surface)
307) light emitting-side cover
308A to 308C) side surface cover
820) substrate
821) substrate main surface
822) substrate back surface
890) transparent layer
893) transparent side surface (transparent surface)
899) opening
900) resin layer
920) substrate
920A) main surface layer
920B) back surface layer
920C) intermediate layer
921) substrate main surface
922) substrate back surface
927) slit
930) first transparent layer
940) second transparent layer
943) second transparent side surface (transparent surface)
960) transparent layer
W1) first wire (wire)
W2) second wire (wire)
W3) third wire (wire)
AS) assembly (semiconductor light emitting assembly)
HA to HC) distance

1. A semiconductor light emitting device, comprising:
a substrate including a substrate main surface;
a semiconductor light emitting element mounted on the substrate main surface, the semiconductor light emitting element including a light emitting element main surface facing the same direction as the substrate main surface and a light emitting surface facing a direction intersecting the light emitting element main surface;
a drive element mounted on the substrate main surface and used to drive the semiconductor light emitting element;
a transparent member covering the light emitting surface, the transparent member being formed from a material having a greater linear expansion coefficient than a material of the substrate and being transmissive to light emitted from the light emitting surface; and
an encapsulation resin encapsulating the semiconductor light emitting element and the drive element, the encapsulation resin being formed of a material having a smaller linear expansion coefficient than the material of the transparent member.

2. The semiconductor light emitting device according to claim 1, wherein
the encapsulation resin encapsulates the transparent member together with the semiconductor light emitting element and the drive element, and
the transparent member includes a transparent surface exposed from the encapsulation resin and facing the same direction as the light emitting surface.

3. The semiconductor light emitting device according to claim 2, wherein the transparent surface includes a mirror-finished smooth surface.

4. The semiconductor light emitting device according to claim 2, wherein
the substrate includes a substrate side surface facing the same direction as the transparent surface,
the encapsulation resin includes a resin side surface facing the same direction as the light emitting surface, and
the transparent surface, the resin side surface, and the substrate side surface are flush with each other.

5. The semiconductor light emitting device according to claim 4, wherein each of the transparent surface, the resin side surface, and the substrate side surface includes a mirror-finished smooth surface.

6. The semiconductor light emitting device according to claim 1, wherein
the drive element includes a switching element including a switching element main surface facing the same direction as the substrate main surface,
the semiconductor light emitting device further comprises a wire connected to the switching element, and
the encapsulation resin encapsulates the wire together with the semiconductor light emitting element and the drive element.

7. The semiconductor light emitting device according to claim 6, wherein
the wire includes a first wire configured to connect the switching element and the semiconductor light emitting element,
a main surface electrode is disposed on the light emitting element main surface, the main surface electrode being configured to be connected to the first wire, and
the transparent member is configured to cover the semiconductor light emitting element and includes an opening from which the main surface electrode is exposed, and
the encapsulation resin fills the opening.

8. The semiconductor light emitting device according to claim 6, wherein
a control electrode is disposed on the switching element main surface,
a main surface control wiring line is disposed on the substrate main surface, the main surface control wiring line being configured to be electrically connected to the control electrode, and
the wire includes a third wire configured to connect the control electrode and the main surface control wiring line.

9. The semiconductor light emitting device according to claim 6, wherein
a drive electrode is disposed on the switching element main surface,
a main surface drive wiring line is disposed on the substrate main surface, the main surface drive wiring line being configured to be electrically connected to the drive electrode, and
the wire includes a second wire configured to connect the drive electrode and the main surface drive wiring line.

10. The semiconductor light emitting device according to claim 6, wherein
the substrate includes a substrate back surface facing a direction opposite to the substrate main surface, and
external electrodes are disposed on the substrate back surface and separately electrically connected to the semiconductor light emitting element and the switching element.

11. The semiconductor light emitting device according to claim 10, wherein
the substrate includes a connection wiring line extending through the substrate in a thickness-wise direction of the substrate, and
the connection wiring line connects the semiconductor light emitting element and the drive element to the external electrodes.

12. The semiconductor light emitting device according to claim 1, wherein the drive element includes a capacitor electrically connected to the semiconductor light emitting element.

13. The semiconductor light emitting device according to claim 1, wherein the encapsulation resin is configured to have a higher glass-transition temperature than the transparent member.
